(19) United States
(12) Patent Application Publication
(10) Pub. No.: US 2022/0255016 A1
(43) Pub. Date: Aug. 11, 2022

(54) ORGANIC ELECTROLUMINESCENCE DEVICE AND ELECTRONIC APPARATUS

(71) Applicant: IDEMITSU KOSAN CO.,LTD., Tokyo (JP)

(72) Inventors: Yoshinori AOYAMA, Sodegaura-shi (JP); Kazuki NISHIMURA, Sodegaura-shi (JP)

(73) Assignee: IDEMITSU KOSAN CO.,LTD., Tokyo (JP)

(21) Appl. No.: 17/592,173

(22) Filed: Feb. 3, 2022

(30) Foreign Application Priority Data
Feb. 8, 2021 (JP) 2021-018197

(51) Int. Cl. H01L 51/00

(52) U.S. Cl. CPC H01L 51/0072; H01L 51/0067; H01L 51/508; H01L 51/0058; H01L 51/0055

(57) ABSTRACT

An organic electroluminescence device having an anode; an emitting layer containing a host material; a first electron-transporting layer containing a first compound; a second electron-transporting layer containing a second compound; and a cathode in this order, wherein the absolute value of the difference between the affinity value of the host material and the affinity value of the first compound is 0.20 or less, the absolute value of the difference between the affinity value of the first compound and the affinity value of the second compound is 0.20 or less, the first compound and the second compound are different compounds, the electron mobility of the second electron-transporting layer is less than 1.00×10⁻⁴ cm²/Vs, the second electron-transporting layer does not contain Li, and the second electron-transporting layer does not contain a quinolate complex of Li.

### TECHNICAL FIELD

Embodiments described herein relate generally to an organic electroluminescence device and an electronic apparatus.

### BACKGROUND ART

When voltage is applied to an organic electroluminescence device (hereinafter, referred to as an organic EL device), holes and electrons are injected into an emitting layer from an anode and a cathode, respectively. Then, thus injected holes and electrons are recombined in the emitting layer, and excitons are formed therein.

Patent Documents 1 to 6 disclose organic EL device having an electron-transporting layer.

### RELATED ART DOCUMENTS

### Patent Documents

[Patent Document 1] WO 2018/174293 A1
[Patent Document 2] WO 2010/134350 A1
[Patent Document 3] WO 2020/050372 A1
[Patent Document 4] WO 2016/068585 A1
[Patent Document 5] WO 2014/097711 A1
[Patent Document 6] US 2015/0325801 A1

### SUMMARY OF THE INVENTION

It is an object of the present invention to provide an organic electroluminescence device capable of achieving both efficiency and lifetime, and an electronic apparatus.

According to the present invention, the following organic electroluminescence device is provided.

1. An organic electroluminescence device, comprising: an anode;

an emitting layer comprising a host material;

a first electron-transporting layer comprising a first compound;

a second electron-transporting layer comprising a second compound; and

a cathode

in this order, wherein

the absolute value of the difference between the affinity value of the host material and the affinity value of the first compound is 0.20 or less,

the absolute value of the difference between the affinity value of the first compound and the affinity value of the second compound is 0.20 or less,

the first compound and the second compound are different compounds, the electronic mobility of the second electron-transporting layer is less than 1.00×10⁻⁴ cm²/Vs, and

the second electron-transporting layer does not comprise Li, and the second electron-transporting layer does not comprise a quinolate complex of Li.

2. An organic electroluminescence device, comprising: an anode;

an emitting layer comprising a host material;

a first electron-transporting layer comprising a first compound;

a second electron-transporting layer comprising a second compound and a third compound,

a cathode

in this order, wherein

the absolute value of the difference between the affinity value of the host material and the affinity value of the first compound is 0.20 or less,

the absolute value of the difference between the affinity value of the first compound and the affinity value of the second compound is 0.20 or less,

the affinity value of the third compound is larger than the affinity value of the second compound,

the first compound and the second compound are different compounds,

the second compound and the third compound are different compounds, and

the second electron-transporting layer does not comprise Li, and the second electron-transporting layer does not comprise a quinolate complex of Li.

3. An electronic apparatus, comprising the organic electroluminescence device according to 1 or 2.

According to the present invention, it is possible to provide an organic electroluminescence device capable of achieving both efficiency and lifetime, and an electronic apparatus.

### MODE FOR CARRYING OUT THE INVENTION

### Definition

In this specification, a hydrogen atom includes its isotopes different in the number of neutrons, namely, a protium, a deuterium and a tritium.

In this specification, at a bondable position in a chemical formula where a symbol such as “R”, or “D” representing a deuterium atom is not indicated, a hydrogen atom, that is, a protium atom, a deuterium atom or a tritium atom is bonded.

In this specification, the number of ring carbon atoms represents the number of carbon atoms forming a subject ring itself among the carbon atoms of a compound having a structure in which atoms are bonded in a ring form (for example, a monocyclic compound, a fused ring compound, a cross-linked compound, a carbocyclic compound, or a heterocyclic compound). When the subject ring is substituted by a substituent, the carbon contained in the substituent is not included in the number of ring carbon atoms. The same shall apply to “the number of ring carbon atoms” described below, unless otherwise specified. For example, a benzene ring has 6 ring carbon atoms, a naphthalene ring includes 10 ring carbon atoms, a pyridine ring includes 5 ring carbon atoms, and a furan ring includes 4 ring carbon atoms. Further, for example, a 9,9-diphenylfluorenyl group includes 13 ring carbon atoms, and a 9,9′-spirobifluorenyl group includes 25 ring carbon atoms.

When a benzene ring is substituted by, for example, an alkyl group as a substituent, the number of carbon atoms of the alkyl group is not included in the number of ring carbon atoms of the benzene ring. Therefore, the number of ring carbon atoms of the benzene ring substituted by the alkyl group is 6. When a naphthalene ring is substituted by, for example, an alkyl group as a substituent, the number of carbon atoms of the alkyl group is not included in the number of ring carbon atoms of the naphthalene ring. Therefore, the number of ring carbon atoms of the naphthalene ring substituted by the alkyl group is 10.

In this specification, the number of ring atoms represents the number of atoms forming a subject ring itself among the atoms of a compound having a structure in which atoms are bonded in a ring form (for example, the structure includes a monocyclic ring, a fused ring and a ring assembly) (for example, a monocyclic compound, a fused ring compound, a cross-linked compound, a carbocyclic compound and a heterocyclic compound). The number of ring atoms does not include atoms which do not form the ring (for example, a hydrogen atom which terminates a bond of the atoms forming the ring), or atoms contained in a substituent when the ring is substituted by the substituent. The same shall apply to “the number of ring atoms” described below, unless otherwise specified. For example, the number of atoms of a pyridine ring is 6, the number of atoms of a quinazoline ring is 10, and the number of a furan ring is 5. For example, hydrogen atoms bonded to a pyridine ring and atoms constituting a substituent substituted on the pyridine ring are not included in the number of ring atoms of the pyridine ring. Therefore, the number of ring atoms of a pyridine ring with which a hydrogen atom or a substituent is bonded is 6. For example, hydrogen atoms and atoms constituting a substituent which are bonded with a quinazoline ring is not included in the number of ring atoms of the quinazoline ring. Therefore, the number of ring atoms of a quinazoline ring with which a hydrogen atom or a substituent is bonded is 10.

In this specification, “XX to YY carbon atoms” in the expression “a substituted or unsubstituted ZZ group including XX to YY carbon atoms” represents the number of carbon atoms in the case where the ZZ group is unsubstituted by a substituent, and does not include the number of carbon atoms of a substituent in the case where the ZZ group is substituted by the substituent. Here, “YY” is larger than “XX”, and “XX” means an integer of 1 or more and “YY” means an integer of 2 or more.

In this specification, “XX to YY atoms” in the expression “a substituted or unsubstituted ZZ group including XX to YY atoms” represents the number of atoms in the case where the ZZ group is unsubstituted by a substituent, and does not include the number of atoms of a substituent in the case where the ZZ group is substituted by the substituent. Here, “YY” is larger than “XX”, and “XX” means an integer of 1 or more and “YY” means an integer of 2 or more.

In this specification, the unsubstituted ZZ group represents the case where the “substituted or unsubstituted ZZ group” is a “ZZ group unsubstituted by a substituent”, and the substituted ZZ group represents the case where the “substituted or unsubstituted ZZ group“is a” ZZ group substituted by a substituent”.

In this specification, a term “unsubstituted” in the case of “a substituted or unsubstituted ZZ group” means that hydrogen atoms in the ZZ group are not substituted by a substituent. Hydrogen atoms in a term “unsubstituted ZZ group” are a protium atom, a deuterium atom, or a tritium atom.

In this specification, a term “substituted” in the case of “a substituted or unsubstituted ZZ group” means that one or more hydrogen atoms in the ZZ group are substituted by a substituent. Similarly, a term “substituted” in the case of “a BB group substituted by an AA group” means that one or more hydrogen atoms in the BB group are substituted by the AA group.

“Substituent as Described in this Specification”

Hereinafter, the substituent described in this specification will be explained.

The number of ring carbon atoms of the “unsubstituted aryl group” described in this specification is 6 to 50, preferably 6 to 30, and more preferably 6 to 18, unless otherwise specified.

The number of ring atoms of the “unsubstituted heterocyclic group” described in this specification is 5 to 50, preferably 5 to 30, and more preferably 5 to 18, unless otherwise specified.

The number of carbon atoms of the “unsubstituted alkyl group” described in this specification is 1 to 50, preferably 1 to 20, and more preferably 1 to 6, unless otherwise specified.

The number of carbon atoms of the “unsubstituted alkenyl group” described in this specification is 2 to 50, preferably 2 to 20, and more preferably 2 to 6, unless otherwise specified.

The number of carbon atoms of the “unsubstituted alkynyl group” described in this specification is 2 to 50, preferably 2 to 20, and more preferably 2 to 6, unless otherwise specified.

The number of ring carbon atoms of the “unsubstituted cycloalkyl group” described in this specification is 3 to 50, preferably 3 to 20, and more preferably 3 to 6, unless otherwise specified.

The number of ring carbon atoms of the “unsubstituted arylene group” described in this specification is 6 to 50, preferably 6 to 30, and more preferably 6 to 18, unless otherwise specified.

The number of ring atoms of the “unsubstituted divalent heterocyclic group” described in this specification is 5 to 50, preferably 5 to 30, and more preferably 5 to 18, unless otherwise specified.

The number of carbon atoms of the “unsubstituted alkylene group” described in this specification is 1 to 50, preferably 1 to 20, and more preferably 1 to 6, unless otherwise specified.

“Substituted or Unsubstituted Aryl Group”

Specific examples of the “substituted or unsubstituted aryl group” described in this specification (specific example group G1) include the following unsubstituted aryl groups (specific example group G1A), substituted aryl groups (specific example group G1B), and the like. (Here, the unsubstituted aryl group refers to the case where the “substituted or unsubstituted aryl group” is an “aryl group unsubstituted by a substituent”, and the substituted aryl group refers to the case where the “substituted or unsubstituted aryl group” is an “aryl group substituted by a substituent”.). In this specification, in the case where simply referred as an “aryl group”, it includes both a “unsubstituted aryl group” and a “substituted aryl group.”

The “substituted aryl group” means a group in which one or more hydrogen atoms of the “unsubstituted aryl group” are substituted by a substituent. Specific examples of the “substituted aryl group” include, for example, groups in which one or more hydrogen atoms of the “unsubstituted aryl group” of the following specific example group G1A are substituted by a substituent, the substituted aryl groups of the following specific example group G1B, and the like. It should be noted that the examples of the “unsubstituted aryl group” and the examples of the “substituted aryl group” enumerated in this specification are mere examples, and the “substituted aryl group” described in this specification also includes a group in which a hydrogen atom bonded with a carbon atom of the aryl group itself in the “substituted aryl group” of the following specific group G1B is further substituted by a substituent, and a group in which a hydrogen atom of a substituent in the “substituted aryl group” of the following specific group G1B is further substituted by a substituent.

Unsubstituted aryl group (specific example group G1A):

a phenyl group,

a p-biphenyl group,

a m-biphenyl group,

an o-biphenyl group,

a p-terphenyl-4-yl group,

a p-terphenyl-3-yl group,

a p-terphenyl-2-yl group,

a m-terphenyl-4-yl group,

a m-terphenyl-3-yl group,

a m-terphenyl-2-yl group,

an o-terphenyl-4-yl group,

an o-terphenyl-3-yl group,

an o-terphenyl-2-yl group,

a 1-naphthyl group,

a 2-naphthyl group,

an anthryl group,

a benzanthryl group,

a phenanthryl group,

a benzophenanthryl group,

a phenalenyl group,

a pyrenyl group,

a chrysenyl group,

a benzochrysenyl group,

a triphenylenyl group,

a benzotriphenylenyl group,

a tetracenyl group,

a pentacenyl group,

a fluorenyl group,

a 9,9′-spirobifluorenyl group,

a benzofluorenyl group,

a dibenzofluorenyl group,

a fluoranthenyl group,

a benzofluoranthenyl group,

a perylenyl group, and

a monovalent aryl group derived by removing one hydrogen atom from the ring structures represented by any of the following general formulas (TEMP-1) to (TEMP-15).

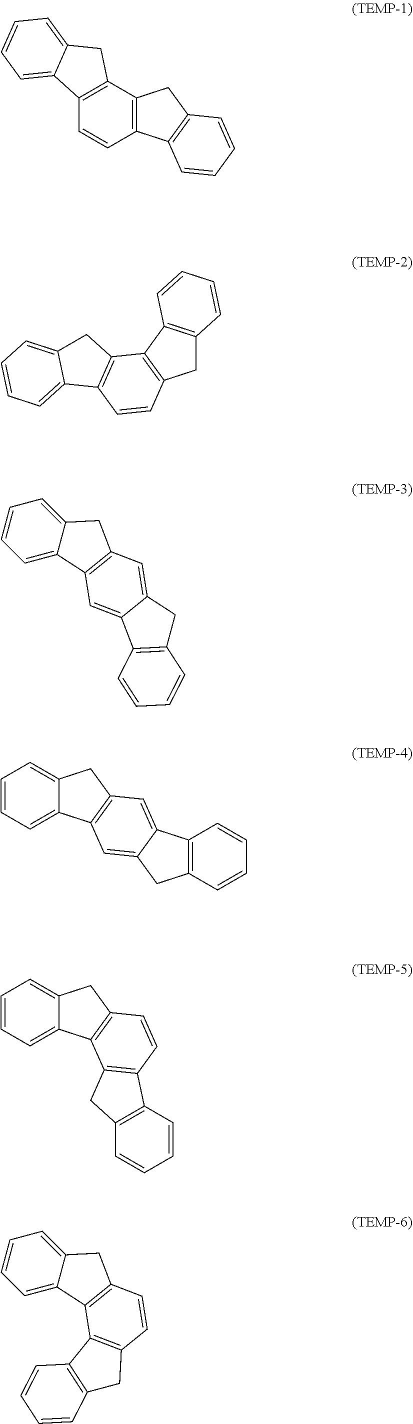

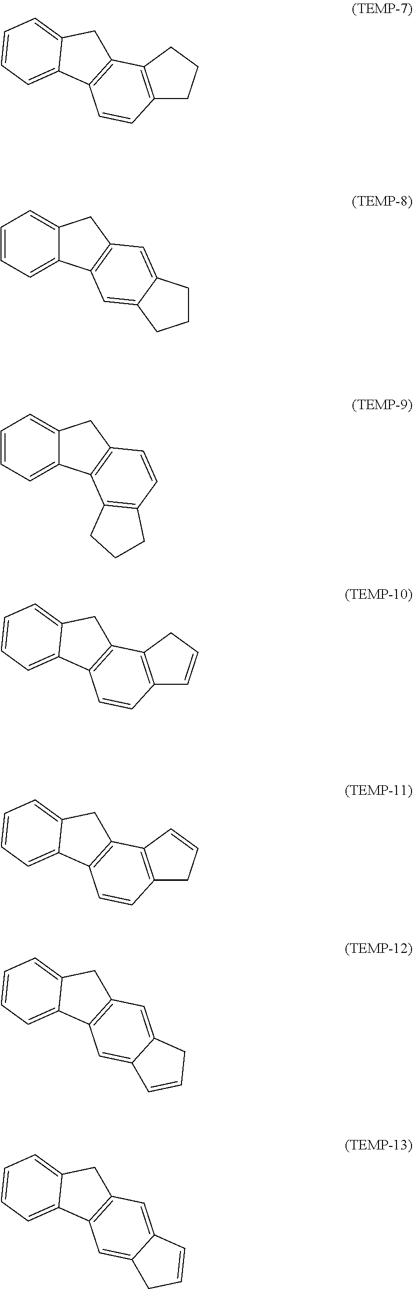

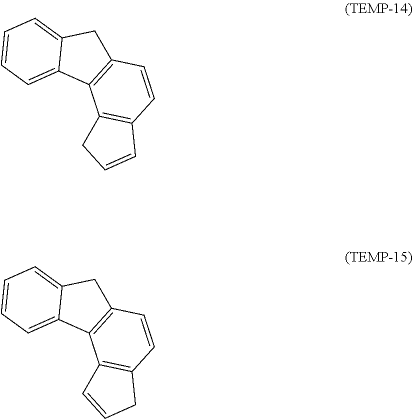

Substituted aryl group (specific example group G1B):

an o-tolyl group,

a m-tolyl group,

a p-tolyl group,

a p-xylyl group,

a m-xylyl group,

an o-xylyl group,

a p-isopropylphenyl group,

a m-isopropylphenyl group,

an o-isopropylphenyl group,

a p-t-butylphenyl group,

a m-t-butylphenyl group,

an o-t-butylphenyl group,

a 3,4,5-trimethylphenyl group,

a 9,9-dimethylfluorenyl group,

a 9,9-diphenylfluorenyl group,

a 9,9-bis(4-methylphenyl)fluorenyl group,

a 9,9-bis(4-isopropylphenyl)fluorenyl group,

a 9,9-bis(4-t-butylphenyl)fluorenyl group,

a cyanophenyl group,

a triphenylsilylphenyl group,

a trimethylsilylphenyl group,

a phenylnaphthyl group,

a naphthylphenyl group, and

a group in which one or more hydrogen atoms of a monovalent group derived from the ring structures represented by any of the general formulas (TEMP-1) to (TEMP-15) are substituted by a substituent.

“Substituted or Unsubstituted Heterocyclic Group”

The “heterocyclic group” described in this specification is a ring group having at least one hetero atom in the ring atom. Specific examples of the hetero atom include a nitrogen atom, an oxygen atom, a sulfur atom, a silicon atom, a phosphorus atom, and a boron atom.

The “heterocyclic group” in this specification is a monocyclic group or a fused ring group.

The “heterocyclic group” in this specification is an aromatic heterocyclic group or a non-aromatic heterocyclic group.

Specific examples of the “substituted or unsubstituted heterocyclic group” (specific example group G2) described in this specification include the following unsubstituted heterocyclic group (specific example group G2A), the following substituted heterocyclic group (specific example group G2B), and the like. (Here, the unsubstituted heterocyclic group refers to the case where the “substituted or unsubstituted heterocyclic group“is a” heterocyclic group unsubstituted by a substituent”, and the substituted heterocyclic group refers to the case where the “substituted or unsubstituted heterocyclic group“is a” heterocyclic group substituted by a substituent”.). In this specification, in the case where simply referred as a “heterocyclic group”, it includes both the “unsubstituted heterocyclic group” and the “substituted heterocyclic group.”

The “substituted heterocyclic group” means a group in which one or more hydrogen atom of the “unsubstituted heterocyclic group” are substituted by a substituent. Specific examples of the “substituted heterocyclic group” include a group in which a hydrogen atom of “unsubstituted heterocyclic group” of the following specific example group G2A is substituted by a substituent, the substituted heterocyclic groups of the following specific example group G2B, and the like. It should be noted that the examples of the “unsubstituted heterocyclic group” and the examples of the “substituted heterocyclic group” enumerated in this specification are mere examples, and the “substituted heterocyclic group” described in this specification includes groups in which hydrogen atom bonded with a ring atom of the heterocyclic group itself in the “substituted heterocyclic group” of the specific example group G2B is further substituted by a substituent, and a group in which hydrogen atom of a substituent in the “substituted heterocyclic group” of the specific example group G2B is further substituted by a substituent.

Specific example group G2A includes, for example, the following unsubstituted heterocyclic group containing a nitrogen atom (specific example group G2A1), the following unsubstituted heterocyclic group containing an oxygen atom (specific example group G2A2), the following unsubstituted heterocyclic group containing a sulfur atom (specific example group G2A3), and the monovalent heterocyclic group derived by removing one hydrogen atom from the ring structures represented by any of the following general formulas (TEMP-16) to (TEMP-33) (specific example group G2A4).

Specific example group G2B includes, for example, the following substituted heterocyclic group containing a nitrogen atom (specific example group G2B1), the following substituted heterocyclic group containing an oxygen atom (specific example group G2B2), the following substituted heterocyclic group containing a sulfur atom (specific example group G2B3), and the following group in which one or more hydrogen atoms of the monovalent heterocyclic group derived from the ring structures represented by any of the following general formulas (TEMP-16) to (TEMP-33) are substituted by a substituent (specific example group G2B4).

Unsubstituted heterocyclic group containing a nitrogen atom (specific example group G2A1):

a pyrrolyl group,

an imidazolyl group,

a pyrazolyl group,

a triazolyl group,

a tetrazolyl group,

an oxazolyl group,

an isoxazolyl group,

an oxadiazolyl group,

a thiazolyl group,

an isothiazolyl group,

a thiadiazolyl group,

a pyridyl group,

a pyridazinyl group,

a pyrimidinyl group,

a pyrazinyl group,

a triazinyl group,

an indolyl group,

an isoindolyl group,

an indolizinyl group,

a quinolizinyl group,

a quinolyl group,

an isoquinolyl group,

a cinnolyl group,

a phthalazinyl group,

a quinazolinyl group,

a quinoxalinyl group,

a benzimidazolyl group,

an indazolyl group,

a phenanthrolinyl group,

a phenanthridinyl group,

an acridinyl group,

a phenazinyl group,

a carbazolyl group,

a benzocarbazolyl group,

a morpholino group,

a phenoxazinyl group,

a phenothiazinyl group,

an azacarbazolyl group, and

a diazacarbazolyl group.

Unsubstituted heterocyclic group containing an oxygen atom (specific example group G2A2):

a furyl group,

an oxazolyl group,

an isoxazolyl group,

an oxadiazolyl group,

a xanthenyl group,

a benzofuranyl group,

an isobenzofuranyl group,

a dibenzofuranyl group,

a naphthobenzofuranyl group,

a benzoxazolyl group,

a benzisoxazolyl group,

a phenoxazinyl group,

a morpholino group,

a dinaphthofuranyl group,

an azadibenzofuranyl group,

a diazadibenzofuranyl group,

an azanaphthobenzofuranyl group, and

a diazanaphthobenzofuranyl group.

Unsubstituted heterocyclic group containing a sulfur atom (specific example group G2A3):

a thienyl group,

a thiazolyl group,

an isothiazolyl group,

a thiadiazolyl group,

a benzothiophenyl group (benzothienyl group),

an isobenzothiophenyl group (isobenzothienyl group),

a dibenzothiophenyl group (dibenzothienyl group),

a naphthobenzothiophenyl group (naphthobenzothienyl group),

a benzothiazolyl group,

a benzisothiazolyl group,

a phenothiazinyl group,

a dinaphthothiophenyl group (dinaphthothienyl group),

an azadibenzothiophenyl group (azadibenzothienyl group),

a diazadibenzothiophenyl group (diazadibenzothienyl group),

an azanaphthobenzothiophenyl group (azanaphthobenzothienyl group), and

a diazanaphthobenzothiophenyl group (diazanaphthobenzothienyl group).

Monovalent heterocyclic group derived by removing one hydrogen atom from the ring structures represented by any of the following general formulas (TEMP-16) to (TEMP-33) (specific example group G2A4):

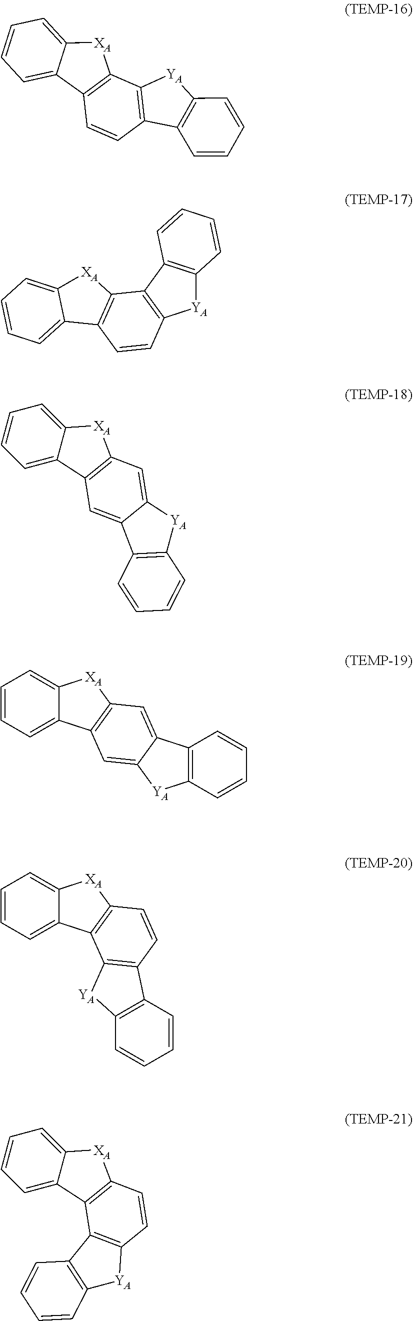

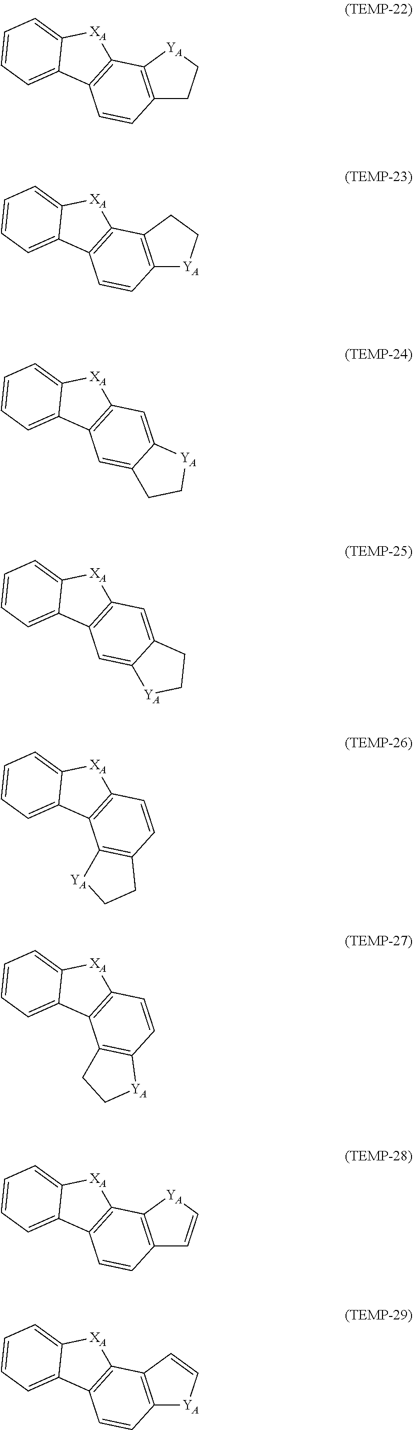

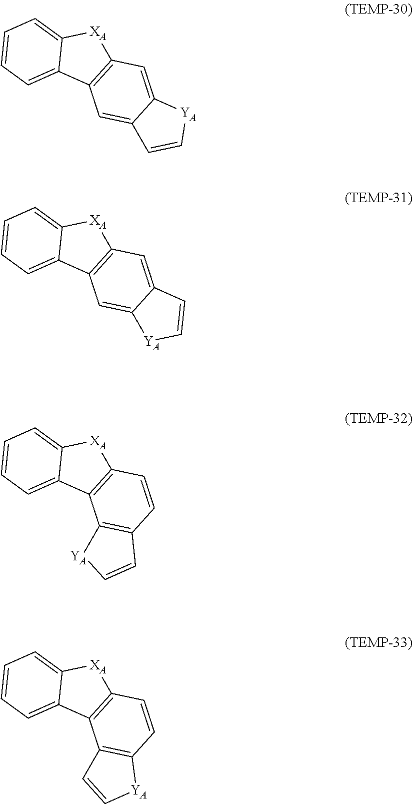

In the general formulas (TEMP-16) to (TEMP-33), X_{A} and Y_{A} are independently an oxygen atom, a sulfur atom, NH, or CH₂. Provided that at least one of X_{A} and Y_{A} is an oxygen atom, a sulfur atom, or NH.

In the general formulas (TEMP-16) to (TEMP-33), when at least one of X_{A} and Y_{A} is NH or CH₂, the monovalent heterocyclic group derived from the ring structures represented by any of the general formulas (TEMP-16) to (TEMP-33) includes a monovalent group derived by removing one hydrogen atom from these NH or CH₂.

Substituted heterocyclic group containing a nitrogen atom (specific example group G2B1):

a (9-phenyl)carbazolyl group,

a (9-biphenylyl)carbazolyl group,

a (9-phenyl)phenylcarbazolyl group,

a (9-naphthyl)carbazolyl group,

a diphenylcarbazol-9-yl group,

a phenylcarbazol-9-yl group,

a methylbenzimidazolyl group,

an ethylbenzimidazolyl group,

a phenyltriazinyl group,

a biphenylyltriazinyl group,

a diphenyltriazinyl group,

a phenylquinazolinyl group, and

a biphenylylquinazolinyl group.

Substituted heterocyclic group containing an oxygen atom (specific example group G2B2):

a phenyldibenzofuranyl group,

a methyldibenzofuranyl group,

a t-butyldibenzofuranyl group, and

a monovalent residue of spiro[9H-xanthene-9,9′-[9H]fluorene].

Substituted heterocyclic group containing a sulfur atom (specific example group G2B3):

a phenyldibenzothiophenyl group,

a methyldibenzothiophenyl group,

a t-butyldibenzothiophenyl group, and

a monovalent residue of spiro[9H-thioxanthene-9,9′-[9H]fluorene].

Group in which one or more hydrogen atoms of the monovalent heterocyclic group derived from the ring structures represented by any of the following general formulas (TEMP-16) to (TEMP-33) are substituted by a substituent (specific example group G2B4):

The “one or more hydrogen atoms of the monovalent heterocyclic group” means one or more hydrogen atoms selected from hydrogen atoms bonded with ring carbon atoms of the monovalent heterocyclic group, a hydrogen atom bonded with a nitrogen atom when at least one of X_{A} and Y_{A} is NH, and hydrogen atoms of a methylene group when one of X_{A} and Y_{A} is CH₂.

“Substituted or Unsubstituted Alkyl Group”

Specific examples of the “substituted or unsubstituted alkyl group” (specific example group G3) described in this specification include the following unsubstituted alkyl groups (specific example group G3A) and the following substituted alkyl groups (specific example group G3B). (Here, the unsubstituted alkyl group refers to the case where the “substituted or unsubstituted alkyl group” is an “alkyl group unsubstituted by a substituent”, and the substituted alkyl group refers to the case where the “substituted or unsubstituted alkyl group” is an “alkyl group substituted by a substituent”.). In this specification, in the case where simply referred as an “alkyl group” includes both the “unsubstituted alkyl group” and the “substituted alkyl group.”

The “substituted alkyl group” means a group in which one or more hydrogen atoms in the “unsubstituted alkyl group” are substituted by a substituent. Specific examples of the “substituted alkyl group” include groups in which one or more hydrogen atoms in the following “unsubstituted alkyl group” (specific example group G3A) are substituted by a substituent, the following substituted alkyl group (specific example group G3B), and the like. In this specification, the alkyl group in the “unsubstituted alkyl group” means a linear alkyl group. Thus, the “unsubstituted alkyl group” includes a straight-chain “unsubstituted alkyl group” and a branched-chain “unsubstituted alkyl group”. It should be noted that the examples of the “unsubstituted alkyl group” and the examples of the “substituted alkyl group” enumerated in this specification are mere examples, and the “substituted alkyl group” described in this specification includes a group in which hydrogen atom of the alkyl group itself in the “substituted alkyl group” of the specific example group G3B is further substituted by a substituent, and a group in which hydrogen atom of a substituent in the “substituted alkyl group” of the specific example group G3B is further substituted by a substituent.

Unsubstituted alkyl group (specific example group G3A):

a methyl group,

an ethyl group,

a n-propyl group,

an isopropyl group,

a n-butyl group,

an isobutyl group,

a s-butyl group, and

a t-butyl group.

Substituted alkyl group (specific example group G3B):

a heptafluoropropyl group (including isomers),

a pentafluoroethyl group,

a 2,2,2-trifluoroethyl group, and

a trifluoromethyl group.

“Substituted or Unsubstituted Alkenyl Group”

Specific examples of the “substituted or unsubstituted alkenyl group” described in this specification (specific example group G4) include the following unsubstituted alkenyl group (specific example group G4A), the following substituted alkenyl group (specific example group G4B), and the like. (Here, the unsubstituted alkenyl group refers to the case where the “substituted or unsubstituted alkenyl group“is a” alkenyl group unsubstituted by a substituent”, and the “substituted alkenyl group” refers to the case where the “substituted or unsubstituted alkenyl group” is a “alkenyl group substituted by a substituent.”). In this specification, in the case where simply referred as an “alkenyl group” includes both the “unsubstituted alkenyl group” and the “substituted alkenyl group.”

The “substituted alkenyl group” means a group in which one or more hydrogen atoms in the “unsubstituted alkenyl group” are substituted by a substituent. Specific examples of the “substituted alkenyl group” include a group in which the following “unsubstituted alkenyl group” (specific example group G4A) has a substituent, the following substituted alkenyl group (specific example group G4B), and the like. It should be noted that the examples of the “unsubstituted alkenyl group” and the examples of the “substituted alkenyl group” enumerated in this specification are mere examples, and the “substituted alkenyl group” described in this specification includes a group in which a hydrogen atom of the alkenyl group itself in the “substituted alkenyl group” of the specific example group G4B is further substituted by a substituent, and a group in which a hydrogen atom of a substituent in the “substituted alkenyl group” of the specific example group G4B is further substituted by a substituent.

Unsubstituted alkenyl group (specific example group G4A):

a vinyl group,

an allyl group,

a 1-butenyl group,

a 2-butenyl group, and

a 3-butenyl group.

Substituted alkenyl group (specific example group G4B):

a 1,3-butanedienyl group,

a 1-methylvinyl group,

a 1-methylallyl group,

a 1,1-dimethylallyl group,

a 2-methylallyl group, and

a 1,2-dimethylallyl group.

“Substituted or Unsubstituted Alkynyl Group”

Specific examples of the “substituted or unsubstituted alkynyl group” described in this specification (specific example group G5) include the following unsubstituted alkynyl group (specific example group G5A) and the like. (Here, the unsubstituted alkynyl group refers to the case where the “substituted or unsubstituted alkynyl group” is an “alkynyl group unsubstituted by a substituent”.). In this specification, in the case where simply referred as an “alkynyl group” includes both the “unsubstituted alkynyl group” and the “substituted alkynyl group.”

The “substituted alkynyl group” means a group in which one or more hydrogen atoms in the “unsubstituted alkynyl group” are substituted by a substituent. Specific examples of the “substituted alkynyl group” include a group in which one or more hydrogen atoms in the following “unsubstituted alkynyl group” (specific example group G5A) are substituted by a substituent, and the like.

Unsubstituted alkynyl group (specific example group G5A):

an ethynyl group.

“Substituted or Unsubstituted Cycloalkyl Group”

Specific examples of the “substituted or unsubstituted cycloalkyl group” described in this specification (specific example group G6) include the following unsubstituted cycloalkyl group (specific example group G6A), the following substituted cycloalkyl group (specific example group G6B), and the like. (Here, the unsubstituted cycloalkyl group refers to the case where the “substituted or unsubstituted cycloalkyl group“is a” cycloalkyl group unsubstituted by a substituent”, and the substituted cycloalkyl group refers to the case where the “substituted or unsubstituted cycloalkyl group” is a “cycloalkyl group substituted by a substituent”.). In this specification, in the case where simply referred as a “cycloalkyl group” includes both the “unsubstituted cycloalkyl group” and the “substituted cycloalkyl group.”

The “substituted cycloalkyl group” means a group in which one or more hydrogen atoms in the “unsubstituted cycloalkyl group” are substituted by a substituent. Specific examples of the “substituted cycloalkyl group” include a group in which one or more hydrogen atoms in the following “unsubstituted cycloalkyl group” (specific example group G6A) are substituted by a substituent, and examples of the following substituted cycloalkyl group (specific example group G6B), and the like. It should be noted that the examples of the “unsubstituted cycloalkyl group” and the examples of the “substituted cycloalkyl group” enumerated in this specification are mere examples, and the “substituted cycloalkyl group” in this specification includes a group in which one or more hydrogen atoms bonded with the carbon atom of the cycloalkyl group itself in the “substituted cycloalkyl group” of the specific example group G6B are substituted by a substituent, and a group in which a hydrogen atom of a substituent in the “substituted cycloalkyl group” of specific example group G6B is further substituted by a substituent.

Unsubstituted cycloalkyl group (specific example group G6A):

a cyclopropyl group,

a cyclobutyl group,

a cyclopentyl group,

a cyclohexyl group,

a 1-adamantyl group,

a 2-adamantyl group,

a 1-norbornyl group, and

a 2-norbornyl group.

Substituted cycloalkyl group (specific example group G6B):

a 4-methylcyclohexyl group.

“Group Represented by —Si(R₉₀₁)(R₉₀₂)(R₉₀₃)”

Specific examples of the group represented by —Si(R₉₀₁)(R₉₀₂)(R₉₀₃) described in this specification (specific example group G7) include:

—Si(G1)(G1)(G1),

—Si(G1)(G2)(G2),

—Si(G1)(G1)(G2),

—Si(G2)(G2)(G2),

—Si(G3)(G3)(G3), and

—Si(G6)(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —Si(G1)(G1)(G1) are the same or different.

Plural G2's in —Si(G1)(G2)(G2) are the same or different.

Plural G1's in —Si(G1)(G1)(G2) are the same or different.

Plural G2's in —Si(G2)(G2)(G2) are be the same or different.

Plural G3's in —Si(G3)(G3)(G3) are the same or different.

Plural G6's in —Si(G6)(G6)(G6) are be the same or different.

“Group Represented by —O—(R₉₀₄)”

Specific examples of the group represented by —O—(R₉₀₄) in this specification (specific example group G8) include:

—O(G1),

—O(G2),

—O(G3), and

—O(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group Represented by —S—(R₉₀₅)”

Specific examples of the group represented by —S—(R₉₀₅) in this specification (specific example group G9) include:

—S(G1),

—S(G2),

—S(G3), and

—S(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

“Group Represented by —N(R₉₀₆)(R₉₀₇)”

Specific examples of the group represented by —N(R₉₀₆)(R₉₀₇) in this specification (specific example group G10) include:

—N(G1)(G1),

—N(G2)(G2),

—N(G1)(G2),

—N(G3)(G3), and

—N(G6)(G6).

G1 is the “substituted or unsubstituted aryl group” described in the specific example group G1.

G2 is the “substituted or unsubstituted heterocyclic group” described in the specific example group G2.

G3 is the “substituted or unsubstituted alkyl group” described in the specific example group G3.

G6 is the “substituted or unsubstituted cycloalkyl group” described in the specific example group G6.

Plural G1's in —N(G1)(G1) are the same or different.

Plural G2's in —N(G2)(G2) are the same or different.

Plural G3's in —N(G3)(G3) are the same or different.

Plural G6's in —N(G6)(G6) are the same or different.

“Halogen Atom”

Specific examples of the “halogen atom” described in this specification (specific example group G11) include a fluorine atom, a chlorine atom, a bromine atom, an iodine atom, and the like.

“Substituted or Unsubstituted Fluoroalkyl Group”

The “substituted or unsubstituted fluoroalkyl group” described in this specification is a group in which at least one hydrogen atom bonded with a carbon atom constituting the alkyl group in the “substituted or unsubstituted alkyl group” is substituted by a fluorine atom, and includes a group in which all hydrogen atoms bonded with a carbon atom constituting the alkyl group in the “substituted or unsubstituted alkyl group” are substituted by a fluorine atom (a perfluoro group). The number of carbon atoms of the “unsubstituted fluoroalkyl group” is 1 to 50, preferably 1 to 30, more preferably 1 to 18, unless otherwise specified in this specification. The “substituted fluoroalkyl group” means a group in which one or more hydrogen atoms of the “fluoroalkyl group” are substituted by a substituent. The “substituted fluoroalkyl group” described in this specification also includes a group in which one or more hydrogen atoms bonded with a carbon atom of the alkyl chains in the “substituted fluoroalkyl group” are further substituted by a substituent, and a group in which one or more hydrogen atom of a substituent in the “substituted fluoroalkyl group” are further substituted by a substituent. Specific examples of the “unsubstituted fluoroalkyl group” include a group in which one or more hydrogen atoms in the “alkyl group” (specific group G3) are substituted by a fluorine atom, and the like.

“Substituted or Unsubstituted Haloalkyl Group”

The “substituted or unsubstituted haloalkyl group” described in this specification is a group in which at least one hydrogen atom bonded with a carbon atom constituting the alkyl group in the “substituted or unsubstituted alkyl group” is substituted by a halogen atom, and also includes a group in which all hydrogen atoms bonded with a carbon atom constituting the alkyl group in the “substituted or unsubstituted alkyl group” are substituted by a halogen atom. The number of carbon atoms of the “unsubstituted haloalkyl group” is 1 to 50, preferably 1 to 30, more preferably 1 to 18, unless otherwise specified in this specification. The “substituted haloalkyl group” means a group in which one or more hydrogen atoms of the “haloalkyl group” are substituted by a substituent. The “substituted haloalkyl group” described in this specification also includes a group in which one or more hydrogen atoms bonded with a carbon atom of the alkyl chain in the “substituted haloalkyl group” are further substituted by a substituent, and a group in which one or more hydrogen atoms of a substituent in the “substituted haloalkyl group” are further substituted by a substituent. Specific examples of the “unsubstituted haloalkyl group” include a group in which one or more hydrogen atoms in the “alkyl group” (specific example group G3) are substituted by a halogen atom, and the like. A haloalkyl group is sometimes referred to as an alkyl halide group.

“Substituted or Unsubstituted Alkoxy Group”

Specific examples of the “substituted or unsubstituted alkoxy group” described in this specification include a group represented by —O(G3), wherein G3 is the “substituted or unsubstituted alkyl group” described in the specific example group G3. The number of carbon atoms of the “unsubstituted alkoxy group” is 1 to 50, preferably 1 to 30, more preferably 1 to 18, unless otherwise specified in this specification.

“Substituted or Unsubstituted Alkylthio Group”

Specific examples of the “substituted or unsubstituted alkylthio group” described in this specification include a group represented by —S(G3), wherein G3 is the “substituted or unsubstituted alkyl group” described in the specific example group G3. The number of carbon atoms of the “unsubstituted alkylthio group” is 1 to 50, preferably 1 to 30, more preferably 1 to 18, unless otherwise specified in this specification.

“Substituted or Unsubstituted Aryloxy Group”

Specific examples of the “substituted or unsubstituted aryloxy group” described in this specification include a group represented by —O(G1), wherein G1 is the “substituted or unsubstituted aryl group” described in the specific example group G1. The number of ring carbon atoms of the “unsubstituted aryloxy group” is 6 to 50, preferably 6 to 30, more preferably 6 to 18, unless otherwise specified in this specification.

“Substituted or Unsubstituted Arylthio Group”

Specific examples of the “substituted or unsubstituted arylthio group” described in this specification include a group represented by —S(G1), wherein G1 is a “substituted or unsubstituted aryl group” described in the specific example group G1. The number of ring carbon atoms of the “unsubstituted arylthio group” is 6 to 50, preferably 6 to 30, more preferably 6 to 18, unless otherwise specified in this specification.

“Substituted or Unsubstituted Trialkylsilyl Group”

Specific examples of the “trialkylsilyl group” described in this specification include a group represented by —Si(G3)(G3)(G3), where G3 is the “substituted or unsubstituted alkyl group” described in the specific example group G3. Plural G3's in —Si(G3)(G3)(G3) are the same or different. The number of carbon atoms in each alkyl group of the “trialkylsilyl group” is 1 to 50, preferably 1 to 20, more preferably 1 to 6, unless otherwise specified in this specification.

“Substituted or Unsubstituted Aralkyl Group”

Specific examples of the “substituted or unsubstituted aralkyl group” described in this specification is a group represented by -(G3)-(G1), wherein G3 is the “substituted or unsubstituted alkyl group” described in the specific example group G3, and G1 is the “substituted or unsubstituted aryl group” described in the specific example group G1. Therefore, the “aralkyl group” is a group in which a hydrogen atom of the “alkyl group” is substituted by an “aryl group” as a substituent, and is one form of the “substituted alkyl group.” The “unsubstituted aralkyl group” is the “unsubstituted alkyl group” substituted by the “unsubstituted aryl group”, and the number of carbon atoms of the “unsubstituted aralkyl group” is 7 to 50, preferably 7 to 30, more preferably 7 to 18, unless otherwise specified in this specification.

Specific examples of the “substituted or unsubstituted aralkyl group” include a benzyl group, a 1-phenylethyl group, a 2-phenylethyl group, a 1-phenylisopropyl group, a 2-phenylisopropyl group, a phenyl-t-butyl group, an α-naphthylmethyl group, a 1-α-naphthylethyl group, a 2-α-naphthylethyl group, a 1-α-naphthylisopropyl group, a 2-α-naphthylisopropyl group, a p-naphthylmethyl group, a 1-p-naphthylethyl group, a 2-p-naphthylethyl group, a 1-p-naphthylisopropyl group, a 2-p-naphthylisopropyl group, and the like.

Unless otherwise specified in this specification, examples of the substituted or unsubstituted aryl group described in this specification preferably include a phenyl group, a p-biphenyl group, a m-biphenyl group, an o-biphenyl group, a p-terphenyl-4-yl group, a p-terphenyl-3-yl group, a p-terphenyl-2-yl group, a m-terphenyl-4-yl group, a m-terphenyl-3-yl group, a m-terphenyl-2-yl group, an o-terphenyl-4-yl group, an o-terphenyl-3-yl group, an o-terphenyl-2-yl group, a 1-naphthyl group, a 2-naphthyl group, an anthryl group, a phenanthryl group, a pyrenyl group, a chrysenyl group, a triphenylenyl group, a fluorenyl group, a 9,9′-spirobifluorenyl group, 9,9-dimethylfluorenyl group, 9,9-diphenylfluorenyl group, and the like.

Unless otherwise specified in this specification, examples of the substituted or unsubstituted heterocyclic groups described in this specification preferably include a pyridyl group, a pyrimidinyl group, a triazinyl group, a quinolyl group, an isoquinolyl group, a quinazolinyl group, a benzimidazolyl group, a phenanthrolinyl group, a carbazolyl group (a 1-carbazolyl group, a 2-carbazolyl group, a 3-carbazolyl group, a 4-carbazolyl group, or a 9-carbazolyl group), a benzocarbazolyl group, an azacarbazolyl group, a diazacarbazolyl group, a dibenzofuranyl group, a naphthobenzofuranyl group, an azadibenzofuranyl group, a diazadibenzofuranyl group, a dibenzothiophenyl group, a naphthobenzothiophenyl group, an azadibenzothiophenyl group, a diazadibenzothiophenyl group, a (9-phenyl)carbazolyl group (a (9-phenyl)carbazol-1-yl group, a (9-phenyl)carbazol-2-yl group, a (9-phenyl)carbazol-3-yl group, or a (9-phenyl)carbazol-4-yl group), a (9-biphenylyl)carbazolyl group, a (9-phenyl)phenylcarbazolyl group, a diphenylcarbazol-9-yl group, a phenylcarbazol-9-yl group, a phenyltriazinyl group, a biphenylyltriazinyl group, a diphenyltriazinyl group, a phenyldibenzofuranyl group, a phenyldibenzothiophenyl group, and the like.

In this specification, the carbazolyl group is specifically any of the following groups, unless otherwise specified in this specification.

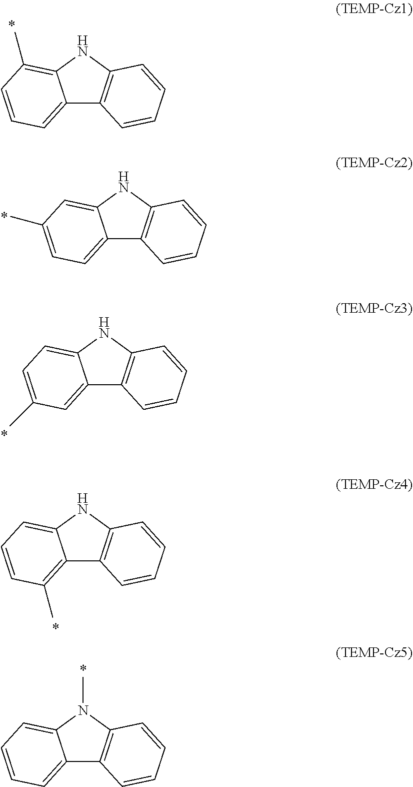

In this specification, the (9-phenyl)carbazolyl group is specifically any of the following groups, unless otherwise specified in this specification.

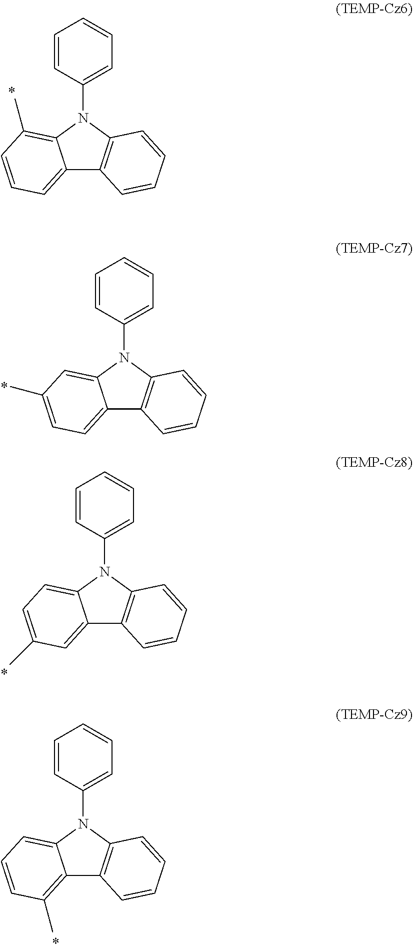

In the general formulas (TEMP-Cz1) to (TEMP-Cz9), * represents a bonding site.

In this specification, the dibenzofuranyl group and the dibenzothiophenyl group are specifically any of the following groups, unless otherwise specified in this specification.

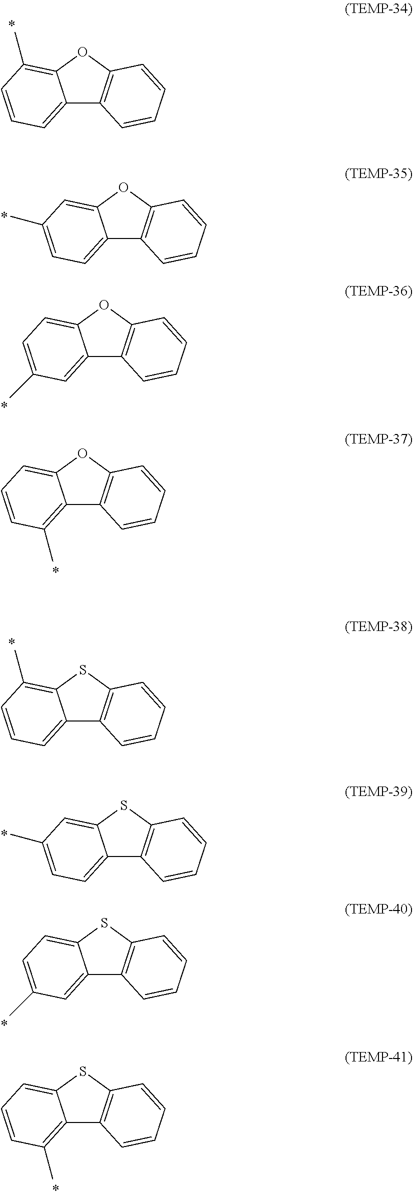

In the general formulas (TEMP-34) to (TEMP-41), * represents a bonding site.

The substituted or unsubstituted alkyl group described in this specification is preferably a methyl group, an ethyl group, a propyl group, an isopropyl group, a n-butyl group, an isobutyl group, a t-butyl group, or the like, unless otherwise specified in this specification.

“Substituted or Unsubstituted Arylene Group”

The “substituted or unsubstituted arylene group” described in this specification is a divalent group derived by removing one hydrogen atom on the aryl ring of the “substituted or unsubstituted aryl group”, unless otherwise specified. Specific examples of the “substituted or unsubstituted arylene group” (specific example group G12) include a divalent group derived by removing one hydrogen atom on the aryl ring of the “substituted or unsubstituted aryl group” described in the specific example group G1, and the like.

“Substituted or Unsubstituted Divalent Heterocyclic Group”

The “substituted or unsubstituted divalent heterocyclic group” described in this specification is a divalent group derived by removing one hydrogen atom on the heterocycle of the “substituted or unsubstituted heterocyclic group”, unless otherwise specified. Specific examples of the “substituted or unsubstituted divalent heterocyclic group” (specific example group G13) include a divalent group derived by removing one hydrogen atom on the heterocycle of the “substituted or unsubstituted heterocyclic group” described in the specific example group G2, and the like.

“Substituted or Unsubstituted Alkylene Group”

The “substituted or unsubstituted alkylene group” described in this specification is a divalent group derived by removing one hydrogen atom on the alkyl chain of the “substituted or unsubstituted alkyl group”, unless otherwise specified. Specific examples of the “substituted or unsubstituted alkylene group” (specific example group G14) include a divalent group derived by removing one hydrogen atom on the alkyl chain of the “substituted or unsubstituted alkyl group” described in the specific example group G3, and the like.

The substituted or unsubstituted arylene group described in this specification is preferably any group of the following general formulas (TEMP-42) to (TEMP-68), unless otherwise specified in this specification.

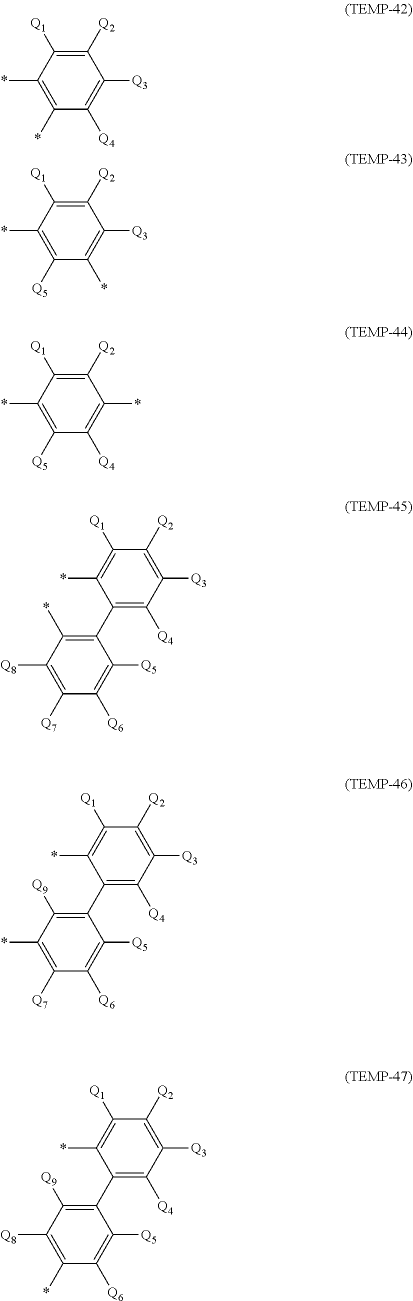

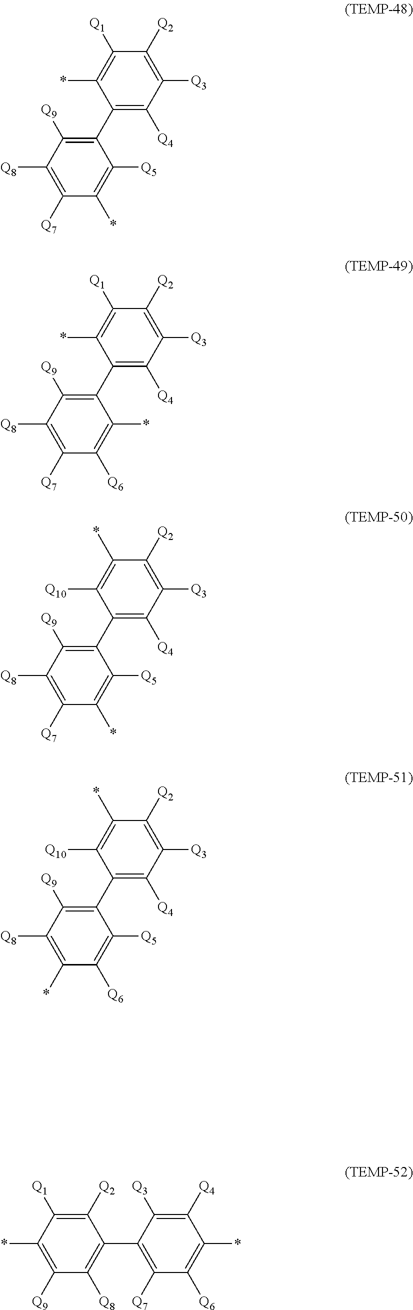

In the general formulas (TEMP-42) to (TEMP-52), Q₁ to Q₁₀ are independently a hydrogen atom or a substituent.

In the general formulas (TEMP-42) to (TEMP-52), * represents a bonding site.

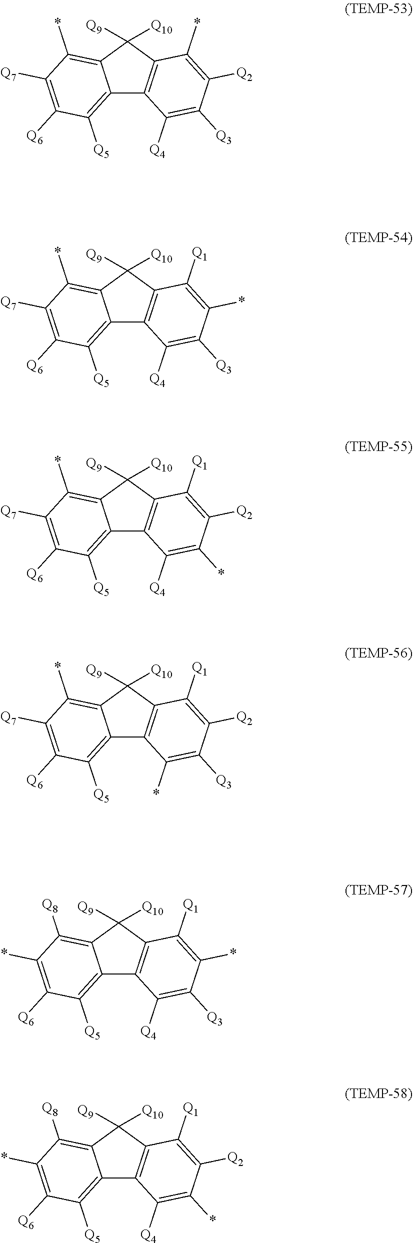

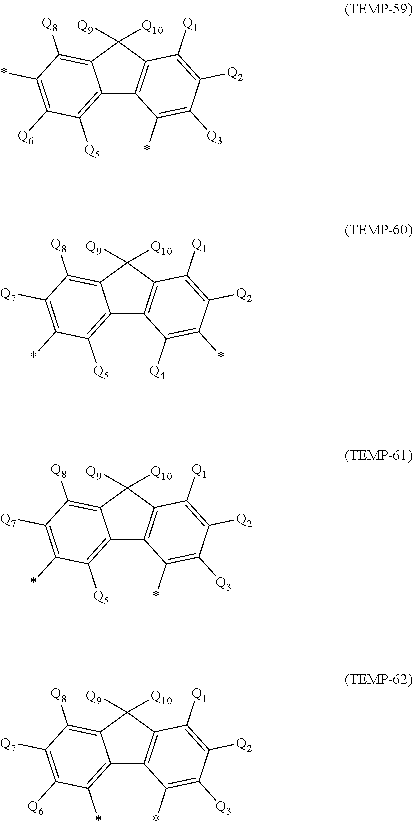

In the general formulas (TEMP-53) to (TEMP-62), Q₁ to Q₁₀ are independently a hydrogen atom or a substituent.

Q₉ and Q₁₀ may be bonded with each other via a single bond to form a ring.

In the general formulas (TEMP-53) to (TEMP-62), * represents a bonding site.

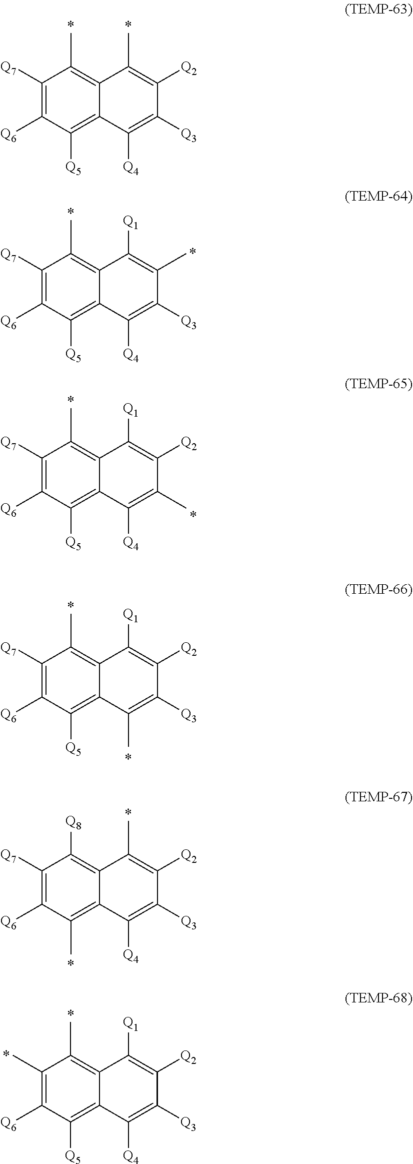

In the general formulas (TEMP-63) to (TEMP-68), Q₁ to Q₈ are independently a hydrogen atom or a substituent.

In the general formulas (TEMP-63) to (TEMP-68), * represents a bonding site.

The substituted or unsubstituted divalent heterocyclic group described in this specification is preferably any group of the following general formulas (TEMP-69) to (TEMP-102), unless otherwise specified in this specification.

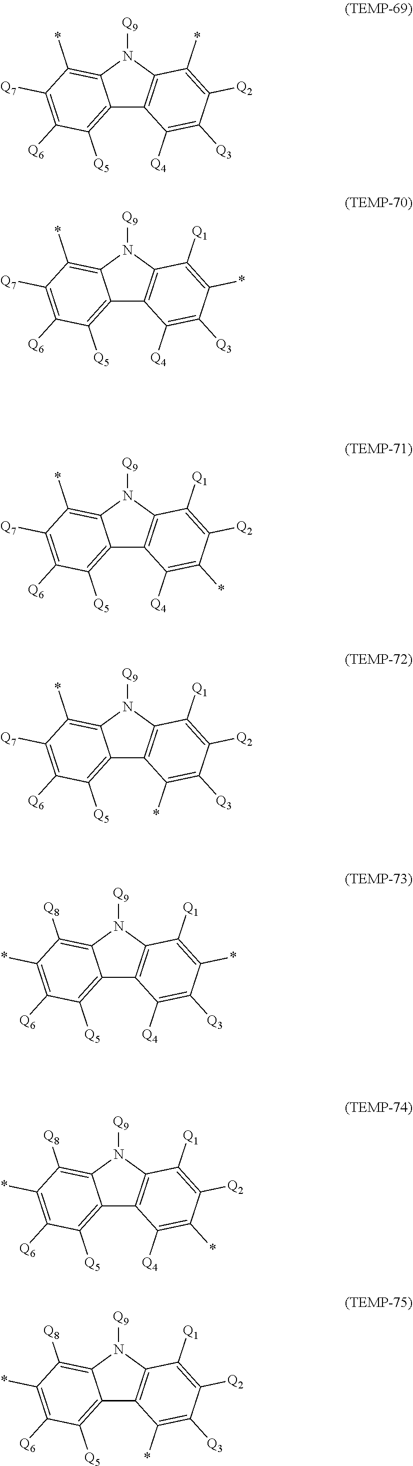

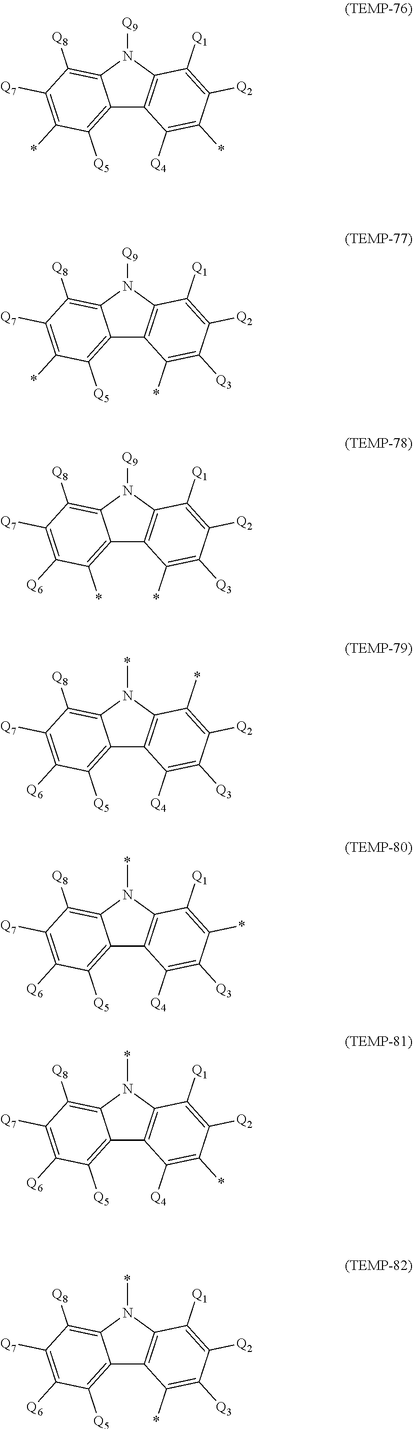

In the general formulas (TEMP-69) to (TEMP-82), Q₁ to Q₉ are independently a hydrogen atom or a substituent.

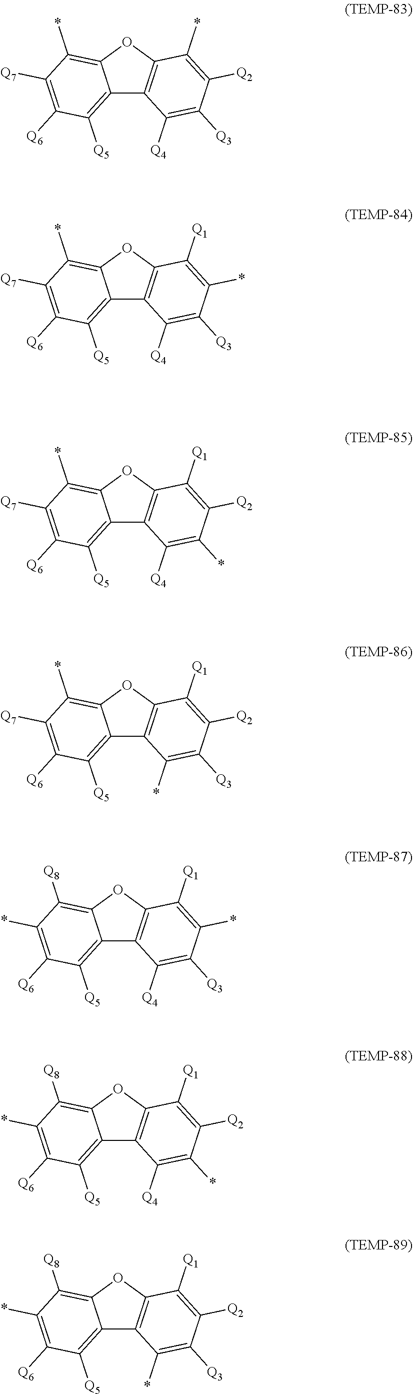

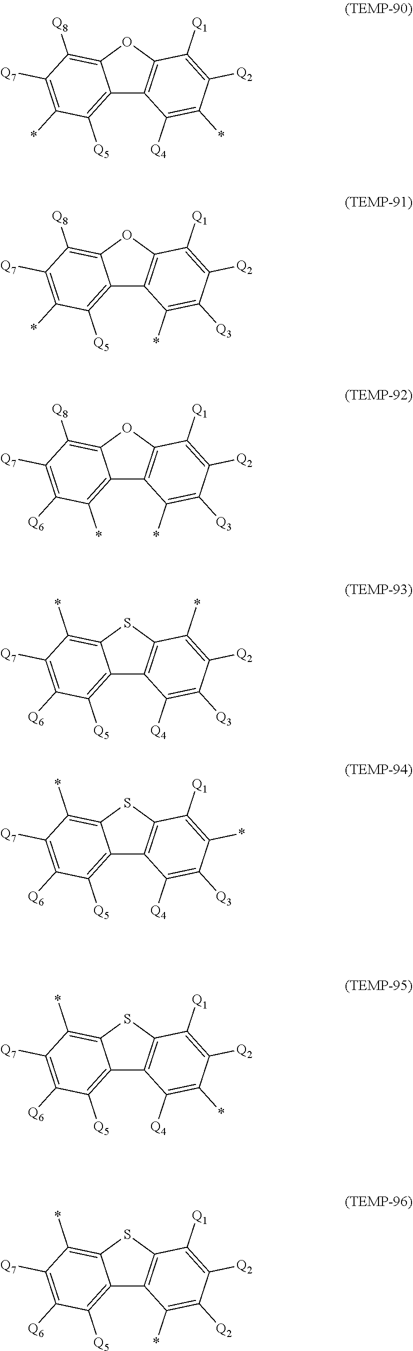

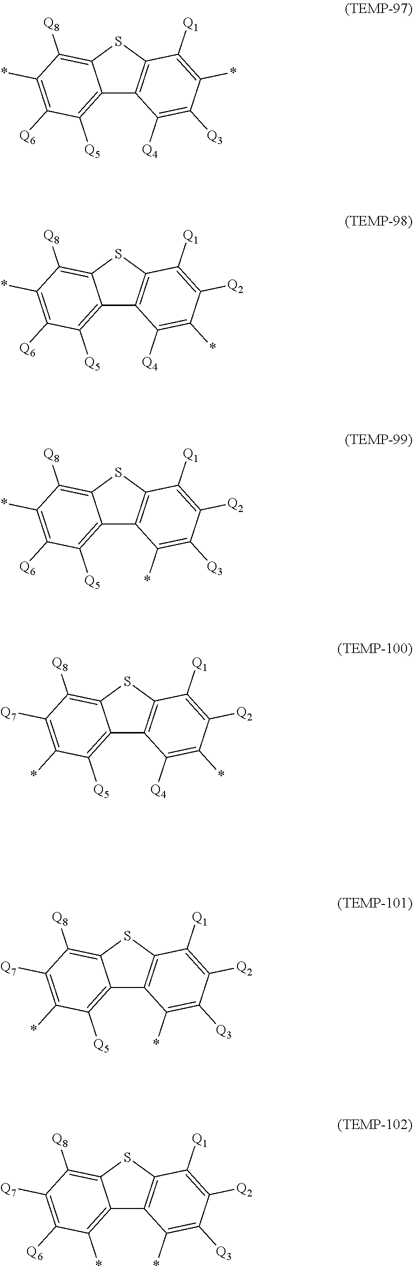

In the general formulas (TEMP-83) to (TEMP-102), Q₁ to Q₃ are independently a hydrogen atom or a substituent.

The above is the explanation of the “Substituent described in this specification.”

“The Case where Bonded with Each Other to Form a Ring”

In this specification, the case where “one or more sets of adjacent two or more form a substituted or unsubstituted monocycle by bonding with each other, form a substituted or unsubstituted fused ring by bonding with each other, or do not bond with each other” means the case where “one or more sets of adjacent two or more form a substituted or unsubstituted monocycle by bonding with each other”; the case where “one or more sets of adjacent two or more form a substituted or unsubstituted fused ring by bonding with each other”; and the case where “one or more sets of adjacent two or more do not bond with each other.”

The case where “one or more sets of adjacent two or more form a substituted or unsubstituted monocycle by bonding with each other” and the case where “one or more sets of adjacent two or more form a substituted or unsubstituted fused ring by bonding with each other” in this specification (these cases may be collectively referred to as “the case where forming a ring by bonding with each other”) will be described below. The case of an anthracene compound represented by the following general formula (TEMP-103) in which the mother skeleton is an anthracene ring will be described as an example.

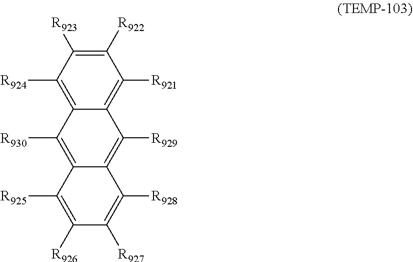

For example, in the case where “one or more sets of adjacent two or more among R₉₂₁ to R₉₃₀ form a ring by bonding with each other”, the one set of adjacent two includes a pair of R₉₂₁ and R₉₂₂, a pair of R₉₂₂ and R₉₂₃, a pair of R₉₂₃ and R₉₂₄, a pair of R₉₂₄ and R₉₃₀, a pair of R₉₃₀ and R₉₂₅, a pair of R₉₂₅ and R₉₂₆, a pair of R₉₂₆ and R₉₂₇, a pair of R₉₂₇ and R₉₂₈, a pair of R₉₂₈ and R₉₂₉, and a pair of R₉₂₉ and R₉₂₁.

The “one or more sets” means that two or more sets of the adjacent two or more sets may form a ring at the same time. For example, R₉₂₁ and R₉₂₂ form a ring Q_{A} by bonding with each other, and at the same, time R₉₂₅ and R₉₂₆ form a ring Q_{B} by bonding with each other, the anthracene compound represented by the general formula (TEMP-103) is represented by the following general formula (TEMP-104).

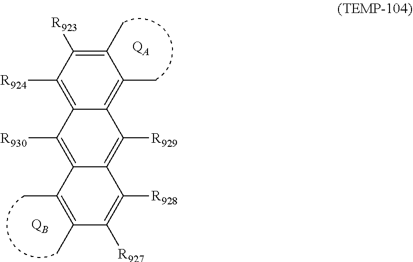

The case where the “set of adjacent two or more” form a ring includes not only the case where the set (pair) of adjacent “two” is bonded with as in the above-mentioned examples, but also the case where the set of adjacent “three or more” are bonded with each other. For example, it means the case where R₉₂₁ and R₉₂₂ form a ring Q_{A} by bonding with each other, and R₉₂₂ and R₉₂₃ form a ring Q_{C} by bonding with each other, and adjacent three (R₉₂₁, R₉₂₂ and R₉₂₃) form rings by bonding with each other and together fused to the anthracene mother skeleton. In this case, the anthracene compound represented by the general formula (TEMP-103) is represented by the following general formula (TEMP-105). In the following general formula (TEMP-105), the ring Q_{A} and the ring Q_{C} share R₉₂₂.

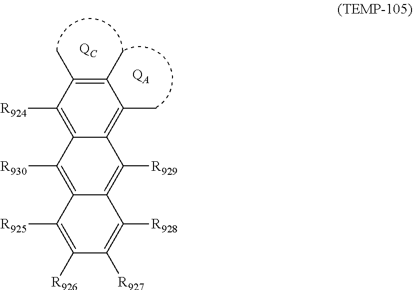

The “monocycle” or “fused ring” formed may be a saturated ring or an unsaturated ring, as a structure of the formed ring alone. Even when the “one pair of adjacent two” forms a “monocycle” or a “fused ring”, the “monocycle” or the “fused ring” may form a saturated ring or an unsaturated ring. For example, the ring Q_{A} and the ring Q_{B} formed in the general formula (TEMP-104) are independently a “monocycle” or a “fused ring.” The ring Q_{A} and the ring Q_{C} formed in the general formula (TEMP-105) are “fused ring.” The ring Q_{A} and ring Q_{C} of the general formula (TEMP-105) are fused ring by fusing the ring Q_{A} and the ring Q_{C} together. When the ring Q_{A} of the general formula (TMEP-104) is a benzene ring, the ring Q_{A} is a monocycle. When the ring Q_{A} of the general formula (TMEP-104) is a naphthalene ring, the ring Q_{A} is a fused ring.

The “unsaturated ring” includes, in addition to an aromatic hydrocarbon ring and an aromatic heterocycle, an aliphatic hydrocarbon ring with an unsaturated bond, i.e., double and/or triple bonds in the ring structure (e.g., cyclohexene, cyclohexadiene, etc.), and a non-aromatic heterocycle with an unsaturated bond (e.g., dihydropyran, imidazoline, pyrazoline, quinolizine, indoline, isoindoline, etc.). The “saturated ring” includes an aliphatic hydrocarbon ring without an unsaturated bond and a non-aromatic heterocycle without ab unsaturated bond.

Specific examples of the aromatic hydrocarbon ring include a structure in which the group listed as a specific example in the specific example group G1 is terminated by a hydrogen atom.

Specific examples of the aromatic heterocycle include a structure in which the aromatic heterocyclic group listed as a specific example in the example group G2 is terminated by a hydrogen atom.

Specific examples of the aliphatic hydrocarbon ring include a structure in which the group listed as a specific example in the specific example group G6 is terminated by a hydrogen atom.

The term “to form a ring” means forming a ring only with plural atoms of the mother skeleton, or with plural atoms of the mother skeleton and one or more arbitrary atoms in addition. For example, the ring Q_{A} shown in the general formula (TEMP-104), which is formed by bonding R₉₂₁ and R₉₂₂ with each other, is a ring formed from the carbon atom of the anthracene skeleton with which R₉₂₁ is bonded, the carbon atom of the anthracene skeleton with which R₉₂₂ is bonded, and one or more arbitrary atoms. For example, in the case where the ring Q_{A} is formed with R₉₂₁ and R₉₂₂, when a monocyclic unsaturated ring is formed with the carbon atom of the anthracene skeleton with which R₉₂₁ is bonded, the carbon atom of the anthracene skeleton with which R₉₂₂ is bonded, and four carbon atoms, the ring formed with R₉₂₁ and R₉₂₂ is a benzene ring.

Here, the “arbitrary atom” is preferably at least one atom selected from the group consisting of a carbon atom, a nitrogen atom, an oxygen atom, and a sulfur atom, unless otherwise specified in this specification. In the arbitrary atom (for example, a carbon atom or a nitrogen atom), a bond which does not form a ring may be terminated with a hydrogen atom or the like, or may be substituted with “arbitrary substituent” described below. When an arbitrary atom other than a carbon atom is contained, the ring formed is a heterocycle.

The number of “one or more arbitrary atom(s)” constituting a monocycle or a fused ring is preferably 2 or more and 15 or less, more preferably 3 or more and 12 or less, and still more preferably 3 or more and 5 or less, unless otherwise specified in this specification.

The “monocycle” is preferable among the “monocycle” and the “fused ring”, unless otherwise specified in this specification.

The “unsaturated ring” is preferable among the “saturated ring” and the “unsaturated ring”, unless otherwise specified in this specification.

Unless otherwise specified in this specification, the “monocycle” is preferably a benzene ring.

Unless otherwise specified in this specification, the “unsaturated ring” is preferably a benzene ring.

Unless otherwise specified in this specification, when “one or more sets of adjacent two or more” are “bonded with each other to form a substituted or unsubstituted monocycle” or “bonded with each other to form a substituted or unsubstituted fused ring”, this specification, one or more sets of adjacent two or more are preferably bonded with each other to form a substituted or unsubstituted “unsaturated ring” from plural atoms of the mother skeleton and one or more and 15 or less atoms which is at least one kind selected from a carbon atom, a nitrogen atom, an oxygen atom, and a sulfur atom.

The substituent in the case where the above-mentioned “monocycle” or “fused ring” has a substituent is, for example, an “arbitrary substituent” described below. Specific examples of the substituent which the above-mentioned “monocycle” or “fused ring” has include the substituent described above in the “Substituent described in this specification” section.

The substituent in the case where the above-mentioned “saturated ring” or “unsaturated ring” has a substituent is, for example, an “arbitrary substituent” described below. Specific examples of the substituent which the above-mentioned “monocycle” or “fused ring” has include the substituent described above in the “Substituent described in this specification” section.

The foregoing describes the case where “one or more sets of adjacent two or more form a substituted or unsubstituted monocycle by bonding with each other” and the case where “one or more sets of adjacent two or more form a substituted or unsubstituted fused ring by bonding with each other” (the case where “forming a ring by bonding with each other”).

Substituent in the Case of “Substituted or Unsubstituted”

In one embodiment in this specification, the substituent (in this specification, sometimes referred to as an “arbitrary substituent”) in the case of “substituted or unsubstituted” is, for example, a group selected from the group consisting of:

an unsubstituted alkyl group including 1 to 50 carbon atoms,

an unsubstituted alkenyl group including 2 to 50 carbon atoms,

an unsubstituted alkynyl group including 2 to 50 carbon atoms,

an unsubstituted cycloalkyl group including 3 to 50 ring carbon atoms,

—Si(R₉₀₁)(R₉₀₂)(R₉₀₃),

—O—(R₉₀₄),

—S—(R₉₀₅),

—N(R₉₀₆)(R₉₀₇),

a halogen atom, a cyano group, a nitro group,

an unsubstituted aryl group including 6 to 50 ring carbon atoms, and

an unsubstituted heterocyclic group including 5 to 50 ring atoms,

wherein, R₉₀₁ to R₉₀₇ are independently

a hydrogen atom,

a substituted or unsubstituted alkyl group including 1 to 50 carbon atoms,

a substituted or unsubstituted cycloalkyl group including 3 to 50 ring carbon atoms,

a substituted or unsubstituted aryl group including 6 to 50 ring carbon atoms, or

a substituted or unsubstituted heterocyclic group including 5 to 50 ring atoms.

When two or more R₉₀₁'s are present, the two or more R₉₀₁'s may be the same or different.

When two or more R₉₀₂'s are present, the two or more R₉₀₂'s may be the same or different.

When two or more R₉₀₃'s are present, the two or more R₉₀₃'s may be the same or different.

When two or more R₉₀₄'s are present, the two or more R₉₀₄'s may be the same or different.

When two or more R₉₀₅'s are present, the two or more R₉₀₅'s may be the same or different.

When two or more R₉₀₆'s are present, the two or more R₉₀₆'s may be the same or different.

When two or more R₉₀₇'s are present, the two or more R₉₀₇'s may be the same or different.

In one embodiment, the substituent in the case of “substituted or unsubstituted” is a group selected from the group consisting of:

an alkyl group including 1 to 50 carbon atoms,

an aryl group including 6 to 50 ring carbon atoms, and

a heterocyclic group including 5 to 50 ring atoms.

In one embodiment, the substituent in the case of “substituted or unsubstituted” is a group selected from the group consisting of:

an alkyl group including 1 to 18 carbon atoms,

an aryl group including 6 to 18 ring carbon atoms, and

a heterocyclic group including 5 to 18 ring atoms.

Specific examples of each of the arbitrary substituents include specific examples of substituent described in the section “Substituent described in this specification” above.

Unless otherwise specified in this specification, adjacent arbitrary substituents may form a “saturated ring” or an “unsaturated ring”, preferably form a substituted or unsubstituted saturated 5-membered ring, a substituted or unsubstituted saturated 6-membered ring, a substituted or unsubstituted unsaturated 5-membered ring, or a substituted or unsubstituted unsaturated 6-membered ring, more preferably form a benzene ring.

Unless otherwise specified in this specification, the arbitrary substituent may further have a substituent. The substituent which the arbitrary substituent further has is the same as that of the above-mentioned arbitrary substituent.

In this specification, the numerical range represented by “AA to BB” means the range including the numerical value AA described on the front side of “AA to BB” as the lower limit and the numerical value BB described on the rear side of “AA to BB” as the upper limit.

### <Organic Electroluminescence Device>

An organic electroluminescence device according to a first aspect of the present invention has an anode;

an emitting layer containing a host material;

a first electron-transporting layer containing a first compound;

a second electron-transporting layer containing a second compound; and

a cathode

in this order, wherein

the absolute value of the difference between the affinity value of the host material and the affinity value of the first compound is 0.20 or less,

the absolute value of the difference between the affinity value of the first compound and the affinity value of the second compound is 0.20 or less,

the first compound and the second compound are different compounds, the electronic mobility of the second electron-transporting layer is less than 1.00×10⁻⁴ cm²/Vs, and

the second electron-transporting layer does not contain Li and the second electron-transporting layer does not contain a quinolate complex of Li.

An organic electroluminescence device according to a second aspect of the present invention has an anode;

an emitting layer containing a host material;

a first electron-transporting layer containing a first compound;

a second electron-transporting layer containing a second compound and a third compound,

a cathode

in this order, wherein

the absolute value of the difference between the affinity value of the host material and the affinity value of the first compound is 0.20 or less,

the absolute value of the difference between the affinity value of the first compound and the affinity value of the second compound is 0.20 or less,

the affinity value of the third compound is larger than the affinity value of the second compound,

the first compound and the second compound are different compounds,

the second compound and the third compound are different compounds, and

the second electron-transporting layer does not contain Li, and the second electron-transporting layer does not contain a quinolate complex of Li.

The first aspect and the second aspect are collectively referred to as an aspect of the organic electroluminescence device of the present invention. Thus, both efficiency and lifetime can be achieved.

In the prior art, an organic substance having lower affinity value than a host material and large gap in affinity value with a host material has been generally used for a first electron-transporting layer and a second electron-transporting layer of an organic EL device in order to control an electron supply for optimizing a carrier balance between electrons and holes to achieve high characteristics, and in order to improve an electron-injecting property from an electrode using an alkaline metal or the like.

In the present invention, by reducing the gap between the affinity value of the host material and the affinity value of the first electron-transporting layer, and reducing the gap between the affinity value of the first electron-transporting layer and the affinity value of the second electron-transporting layer, it is possible to extend the lifetime while maintaining high luminous efficiency.

In one embodiment, the second electron-transporting layer further contains a third compound. In one embodiment, the affinity value of the third compound is larger than the affinity value of the second compound. In one example, the value obtained by subtracting the affinity value of the second compound from the affinity value of the third compound is 0.05 or larger and 0.40 or smaller, 0.15 or larger and 0.40 or smaller, 0.20 or larger and 0.40 or smaller, or 0.30 or larger and 0.40 or smaller.

In one embodiment, the second compound and the third compound are different compounds.

In one embodiment, the emitting layer containing a host material and the first electron-transporting layer containing a first compound are in direct contact with each other.

In one embodiment, the first electron-transporting layer containing a first compound and the second electron-transporting layer containing a second compound are in direct contact with each other. In addition, in one embodiment, the first electron-transporting layer containing a first compound and the second electron-transporting layer containing a second compound and a third compound are in direct contact with each other.

The absolute value of the difference between the affinity value of the host material and the affinity value of the first compound is 0.20 or smaller (in one embodiment, 0 or larger and 0.20 or smaller, 0 or larger and 0.15 or smaller, or 0 or larger and 0.10 or smaller).

The absolute value of the difference between the affinity value of the first compound and the affinity value of the second compound is 0.20 or smaller (in one embodiment, 0 or larger and 0.20 or smaller, 0 or larger and 0.15 or smaller, or 0 or larger and 0.10 or smaller).

In one embodiment, the value obtained by subtracting the affinity value of the second compound from the affinity value of the third compound is 0.05 or larger and 0.40 or smaller, 0.15 or larger and 0.40 or smaller, 0.20 or larger and 0.40 or smaller, or 0.30 or larger and 0.40 or smaller.

The affinity value of the host material, the affinity value of the first compound, the affinity value of the second compound, and the affinity value of the third compound are measured by a differential pulse voltammetry (DPV) method using an electrochemical analyzer.

In one embodiment, “the second electron-transporting layer does not contain Li” means that the content of Li in the second electron-transporting layer is 0 to 1000 ppm by mass (in one embodiment, 0 to 100 ppm by mass) relative to the entire second electron-transporting layer.

In one embodiment, “the second electron-transporting layer does not contain a quinolate complex of Li” means that the content of the quinolate complex of Li in the second electron-transporting layer is 0 to 1000 ppm by mass (in one embodiment, 0 to 100 ppm by mass) relative to the entire second electron-transporting layer.

In one embodiment of the second aspect, the electronic mobility of the second electron-transporting layer is smaller than 1.00×10−4 cm²/Vs.

In one embodiment, the electronic mobility of the second electron-transporting layer is 5.00×10⁻⁵ cm²/Vs or smaller, or 1.00×10⁻⁵ cm²/Vs or smaller.

The electron mobility of the second electron-transporting layer is measured using an impedance analyzer.

In one embodiment, the third compound is a compound represented by the following formula (800):

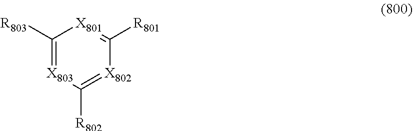

wherein in the formula (800),

X₈₀₁ to X₈₀₃ are independently CR₈₀₄ or N, wherein R₈₀₄ is a hydrogen atom or a substituent R; at least one (in one embodiment, two or three) of X₈₀₁ to X₈₀₃ are N; when two or more R₈₀₄'s are present, the two or more R₈₀₄'s may be the same as or different from each other;

R₈₀₁ to R₈₀₃ are independently

a hydrogen atom, or
a substituent R;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituents R are present, the two or more of the substituents R may be the same as or different from each other;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other.

In one embodiment, the third compound is a compound represented by the following formula (801) and formula (802):

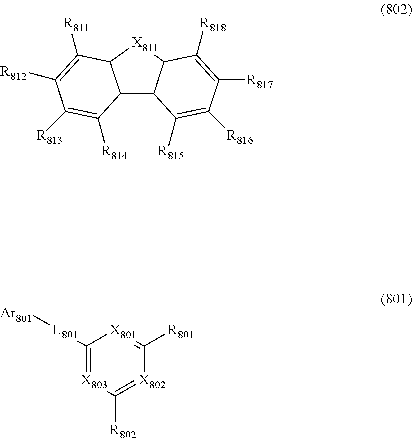

wherein in the formula (801),

X₈₀₁ to X₈₀₃, R₈₀₁ and R₈₀₂ are as defined in the formula (800);

L₈₀₁ is

a single bond,
a substituted or unsubstituted arylene group including 6 to 50 ring carbon atoms, or
a substituted or unsubstituted divalent heterocyclic group including 5 to 50 ring atoms; and

Ar₈₀₁ is a group represented by the formula (802);

wherein in the formula (802),

X₈₁₁ is O, S, N(R₈₂₁), or C(R₈₂₂)(R₈₂₃);

one of R₈₁₁ to R₈₁₈ and R₈₂₁ to R₈₂₃ is a single bond bonding with L₈₀₁;

one or more sets of adjacent two or more of R₈₁₁ to R₈₁₈ which are not single bonds bonding with L₈₀₁ form a substituted or unsubstituted, saturated or unsaturated ring by bonding with each other, or do not form the substituted or unsubstituted, saturated or unsaturated ring;

R₈₁₁ to R₈₁₈ which are not single bonds bonding with L₈₀₁ and which do not form the substituted or unsubstituted, saturated or unsaturated ring, and R₈₂₁ to R₈₂₃ which are not single bonds bonding with L₈₀₁ are independently

a hydrogen atom, or
a substituent R; and

the substituent R is as defined in the formula (800).

In one embodiment, the third compound is a compound represented by the following formula (811):

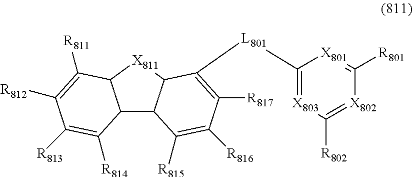

wherein in the formula (811), X₈₀₁ to X₈₀₃, R₈₀₁ and R₈₀₂ are as defined in the formula (800); L₈₀₁ is as defined in the formula (801); and X₈₁₁ and R₈₁₁ to R₈₁₇ are as defined in the formula (802).

The third compound can be synthesized by using known alternative reactions or raw materials tailored to the target product.

Specific examples of the third compound will be described below, but these are merely illustrative, and the third compound is not limited to the following specific examples. “Af” indicates the affinity value of the compound.

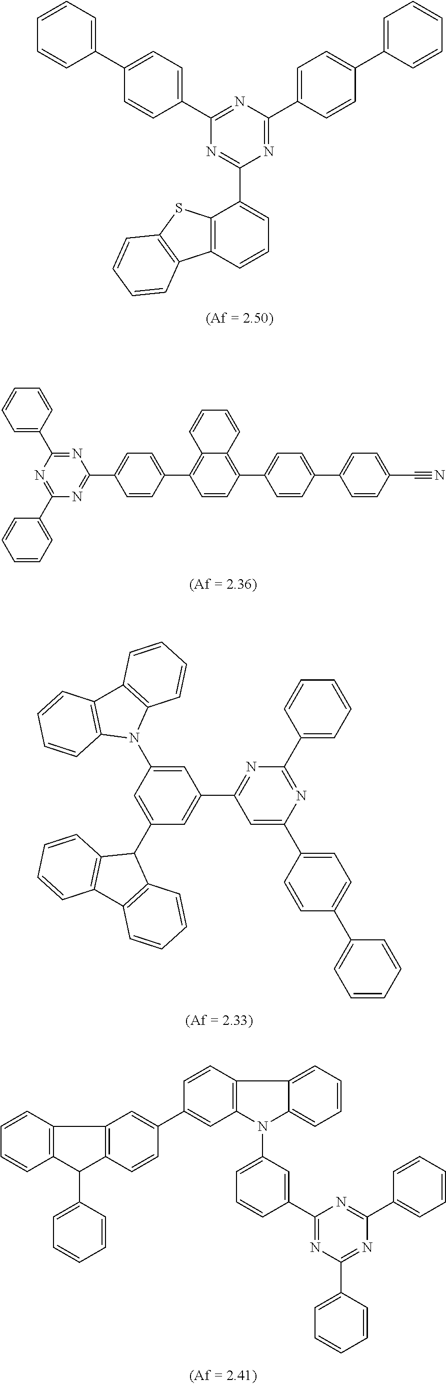 [SMILES: c1ccc(-c2ccc(-c3nc(-c4ccc(-c5ccccc5)cc4)nc(-c4cccc5c4sc4ccccc45)n3)cc2)cc1 ; N#Cc1ccc(-c2ccc(-c3ccc(-c4ccc(-c5nc(-c6ccccc6)nc(-c6ccccc6)n5)cc4)c4ccccc34)cc2)cc1 ; c1ccc(-c2ccc(-c3cc(-c4cc(C5c6ccccc6-c6ccccc65)cc(-n5c6ccccc6c6ccccc65)c4)nc(-c4ccccc4)n3)cc2)cc1 ; c1ccc(-c2nc(-c3ccccc3)nc(-c3cccc(-n4c5ccccc5c5ccc(-c6ccc7c(c6)-c6ccccc6C7c6ccccc6)cc54)c3)n2)cc1]

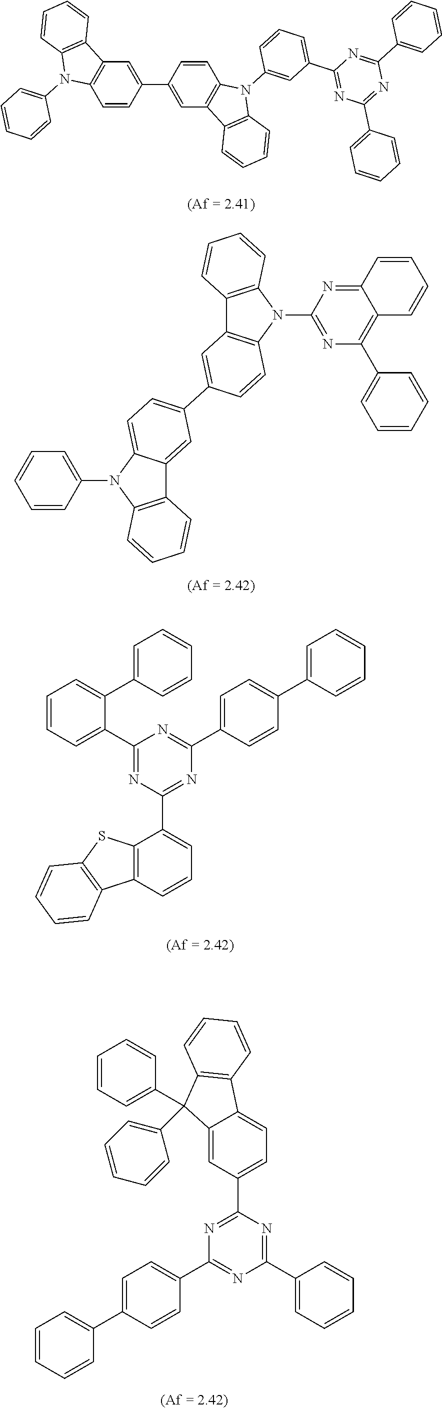 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-c2ccc(-c3nc(-c4ccccc4-c4ccccc4)nc(-c4cccc5c4sc4ccccc45)n3)cc2)cc1 ; c1ccc(-c2ccc(-c3nc(-c4ccccc4)nc(-c4ccc5c(c4)C(c4ccccc4)(c4ccccc4)c4ccccc4-5)n3)cc2)cc1]

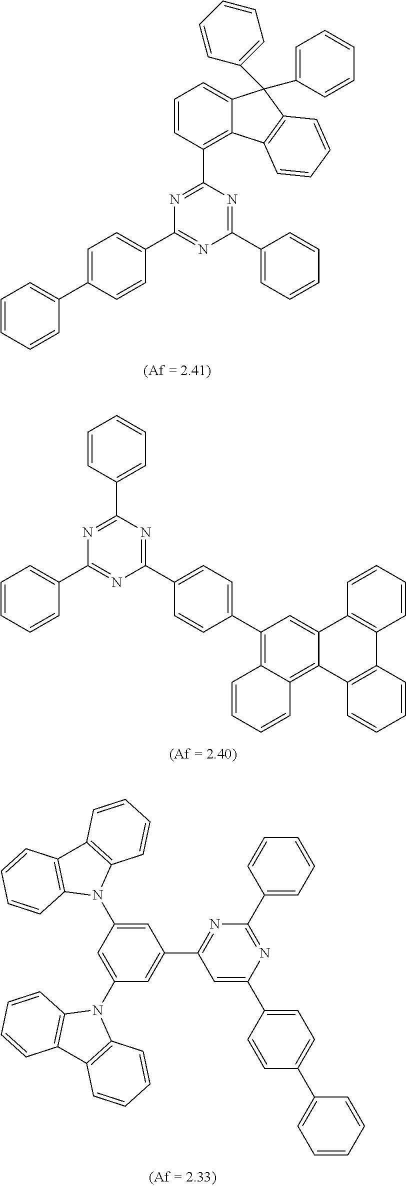 [SMILES: c1ccc(-c2ccc(-c3nc(-c4ccccc4)nc(-c4cccc5c4-c4ccccc4C5(c4ccccc4)c4ccccc4)n3)cc2)cc1 ; c1ccc(-c2nc(-c3ccccc3)nc(-c3ccc(-c4cc5c6ccccc6c6ccccc6c5c5ccccc45)cc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

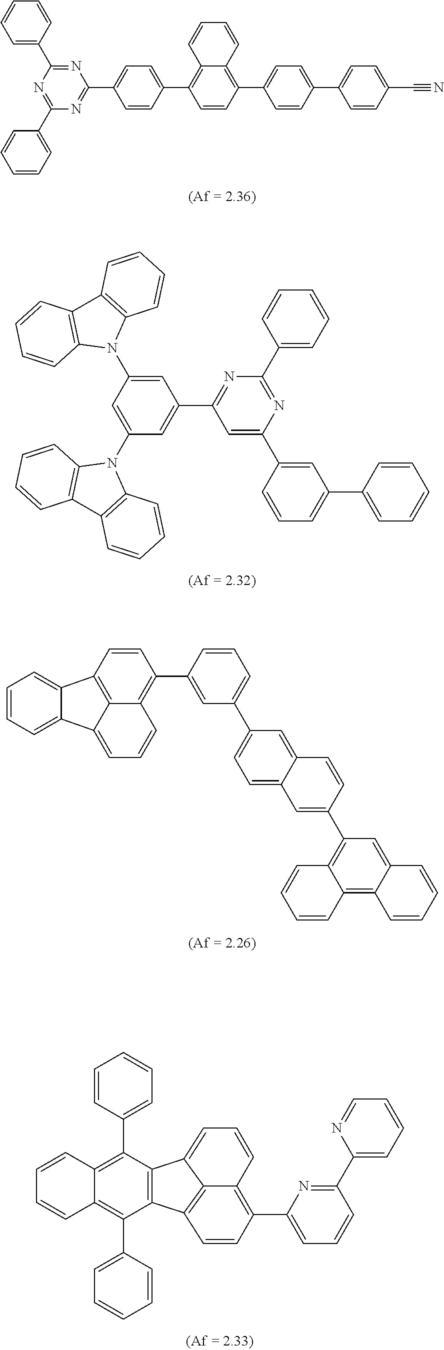

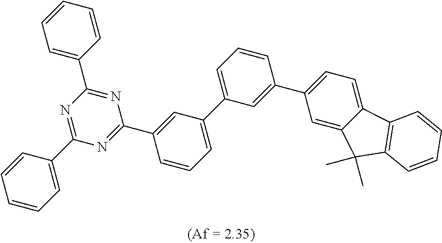 [SMILES: CC1(C)c2ccccc2-c2ccc(-c3cccc(-c4cccc(-c5nc(-c6ccccc6)nc(-c6ccccc6)n5)c4)c3)cc21]

In one embodiment, the organic EL device further has one or more emitting layers other than the emitting layer containing the host material between the anode and the emitting layer containing the host material.

In one embodiment, the host material is an anthracene derivative.

In one embodiment, the host material is a compound represented by the following formula (100):

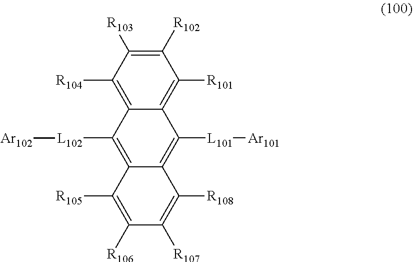

wherein in the formula (100),

one or more sets of the adjacent two or more of R₁₀₁ to R₁₀₈ form a substituted or unsubstituted, saturated or unsaturated ring by bonding with each other, or do not form the substituted or unsubstituted, saturated or unsaturated ring;

R₁₀₁ to R₁₀₈ which do not form the substituted or unsubstituted, saturated or unsaturated ring are independently

a hydrogen atom, or
a substituent R;

L₁₀₁ and L₁₀₂ are independently

a single bond,
a substituted or unsubstituted arylene group including 6 to 50 ring carbon atoms, or
a substituted or unsubstituted divalent heterocyclic group including 5 to 50 ring atoms;

Ar₁₀₁ and Ar₁₀₂ are independently

a substituted or unsubstituted aryl group including 6 to 50 ring carbon atoms, or
a substituted or unsubstituted monovalent heterocyclic group including 5 to 50 ring atoms;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituents R are present, the two or more of the substituents R may be the same as or different from each other;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other.

In one embodiment, one or more of

hydrogen atoms possessed by the substituted or unsubstituted, saturated or unsaturated ring formed by bonding one or more sets of adjacent two or more of R₁₀₁ to R₁₀₈,

R₁₀₁ to R₁₀₈ which are hydrogen atoms,

hydrogen atoms possessed by R₁₀₁ to R₁₀₈ which are substituents R,

hydrogen atoms possessed by L₁₀₁,

hydrogen atoms possessed by L₁₀₂,

hydrogen atoms possessed by Ar₁₀₁, and

hydrogen atoms possessed by Ar₁₀₂

are deuterium atoms.

In one embodiment, the host material is a compound represented by the following formula (101):

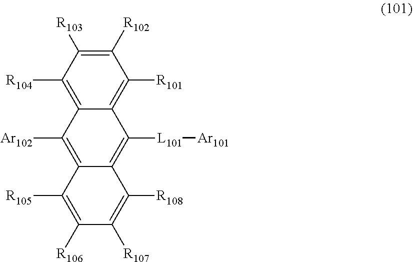

wherein in the formula (101), R₁₀₁ to R₁₀₈, L₁₀₁, Ar₁₀₁ and Ar₁₀₂ are as defined in the formula (100).

In one embodiment, the host material is a compound represented by the following formula (102):

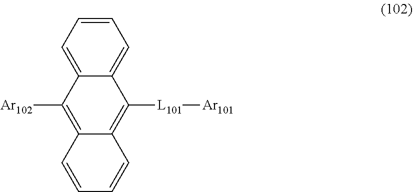

wherein in the formula (102), L₁₀₁, Ar₁₀₁, and Ar₁₀₂ are as defined in the formula (100).

The host material can be synthesized by using known alternative reactions or raw materials tailored to the target product.

Specific examples of the host material will be described below, but these are merely illustrative, and the host material is not limited to the following specific examples.

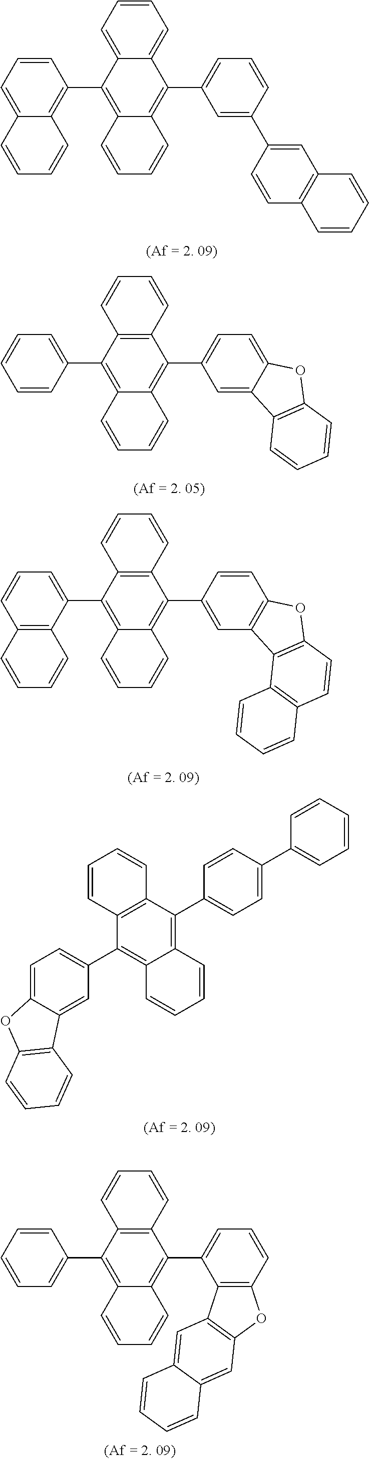

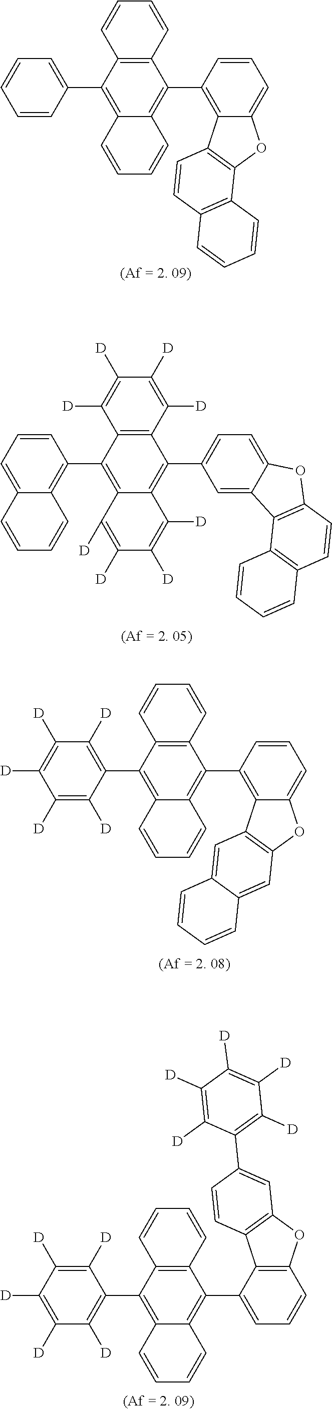 [SMILES: c1ccc(-c2c3ccccc3c(-c3cccc4oc5c6ccccc6ccc5c34)c3ccccc23)cc1 ; [2H]c1c([2H])c([2H])c2c(-c3cccc4ccccc34)c3c([2H])c([2H])c([2H])c([2H])c3c(-c3ccc4oc5ccc6ccccc6c5c4c3)c2c1[2H] ; [2H]c1c([2H])c([2H])c(-c2c3ccccc3c(-c3cccc4oc5cc6ccccc6cc5c34)c3ccccc23)c([2H])c1[2H] ; [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H]]

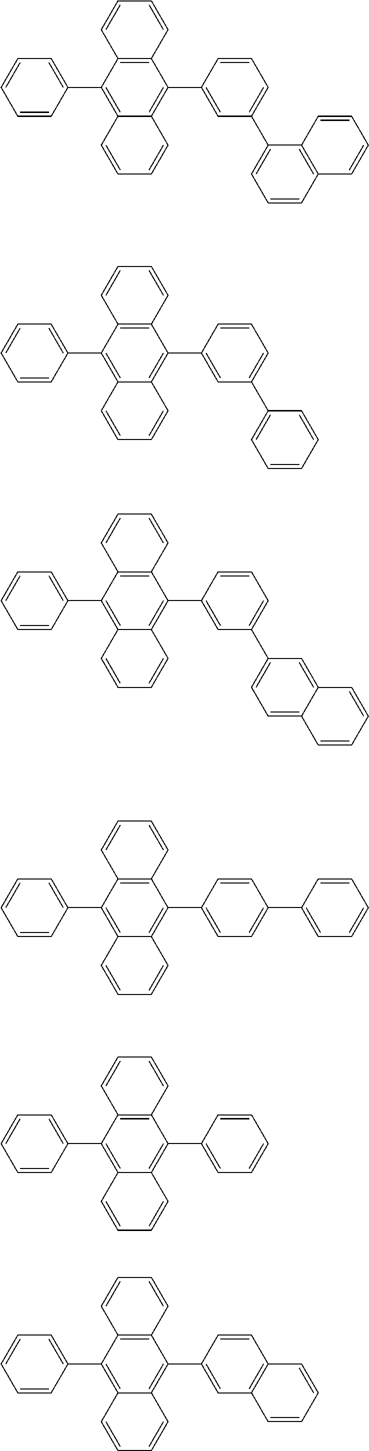

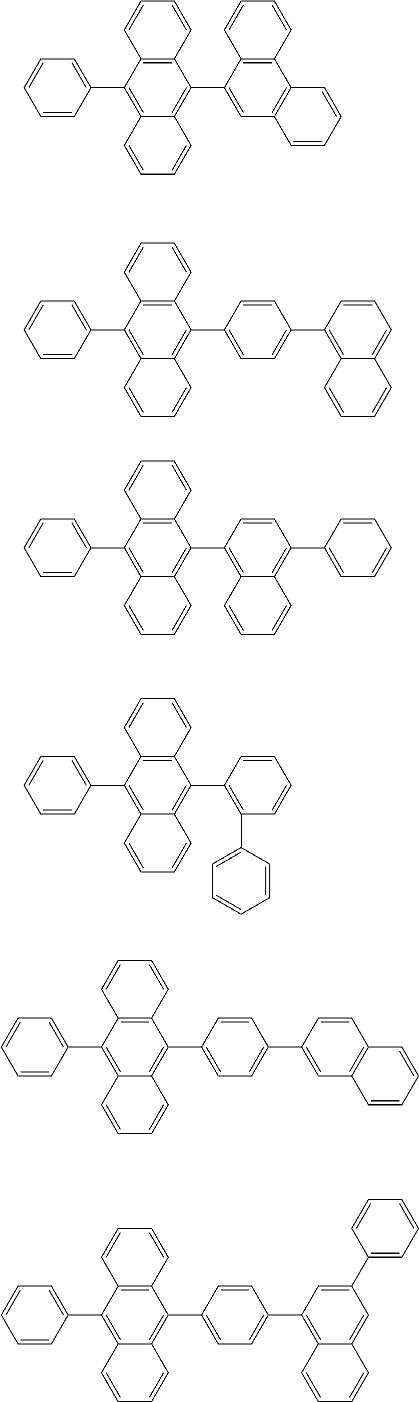

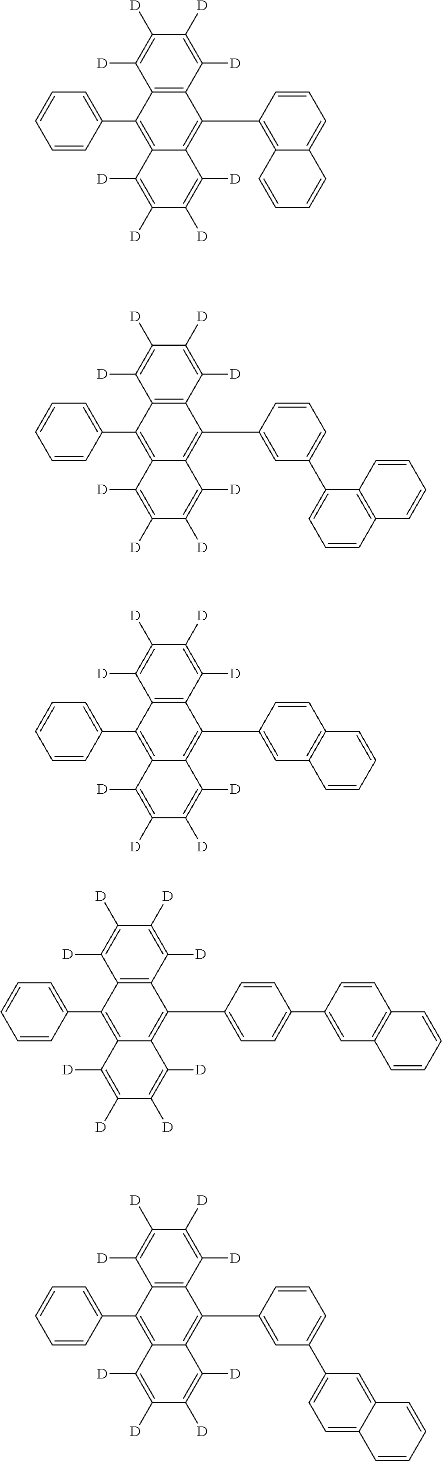

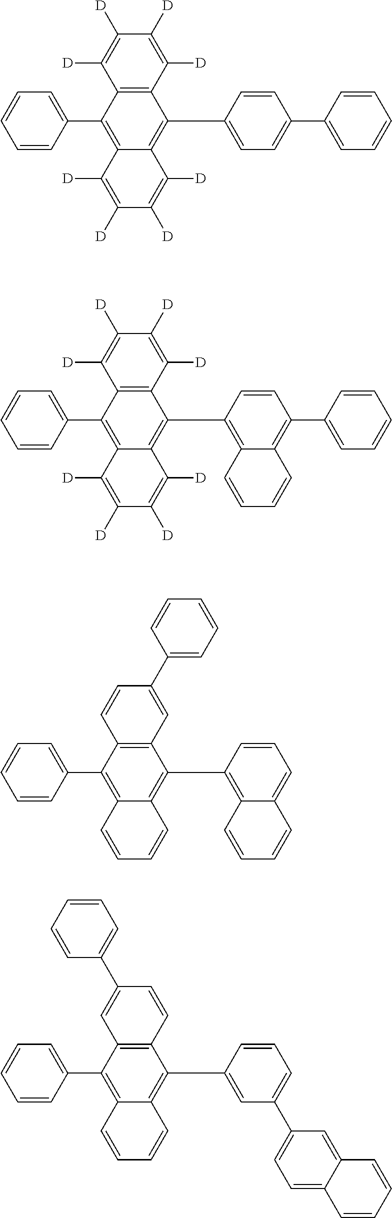

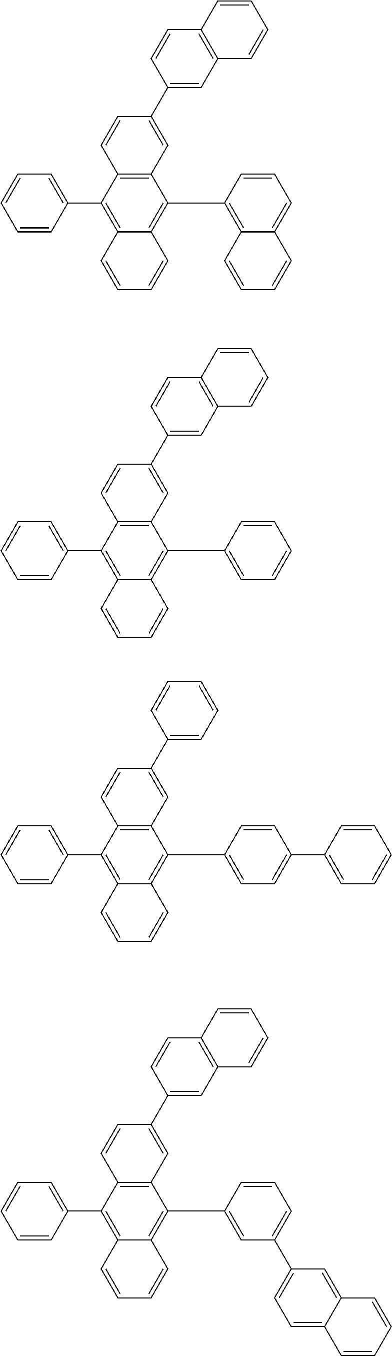

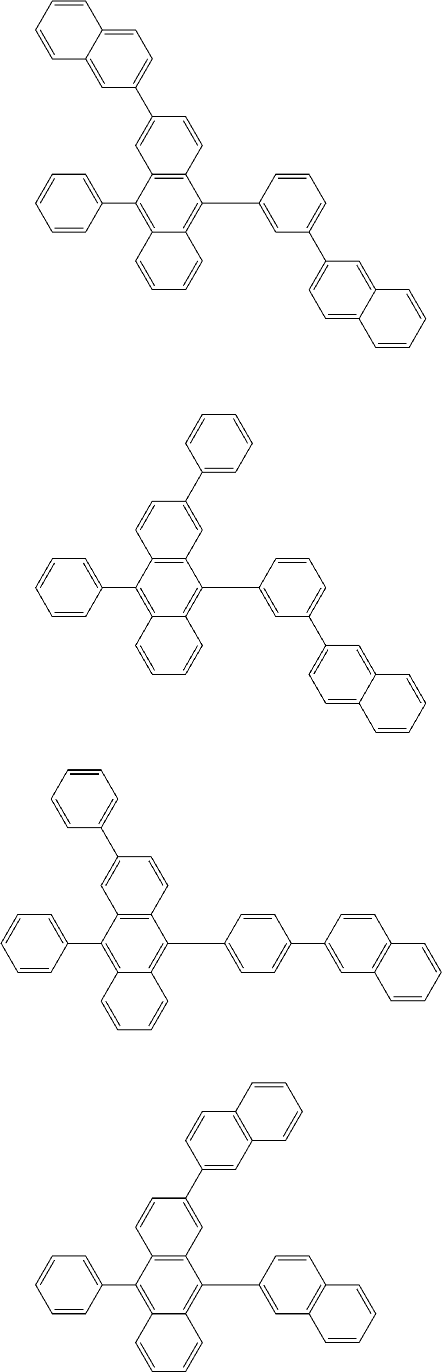

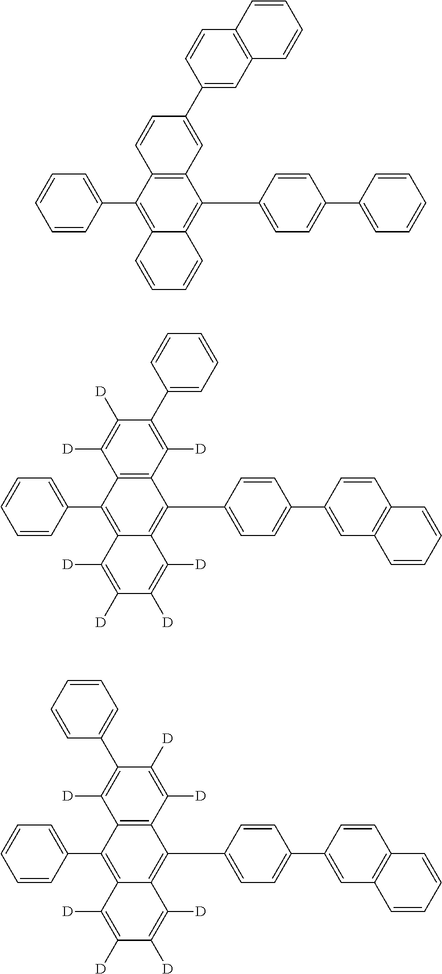

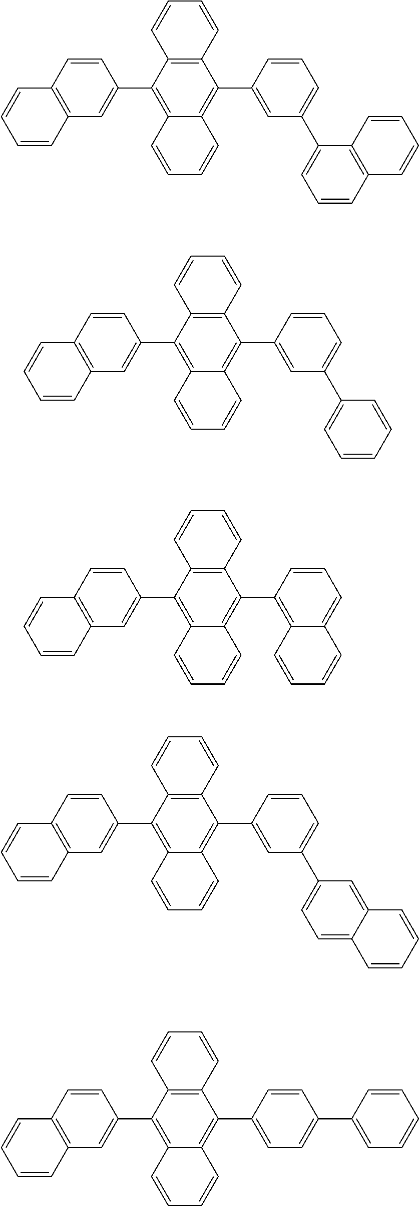

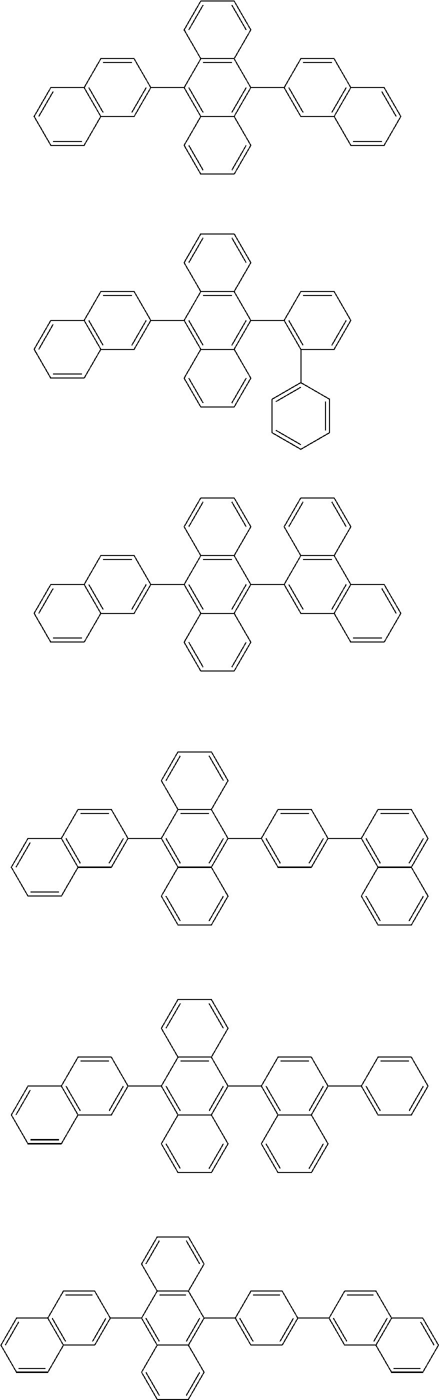

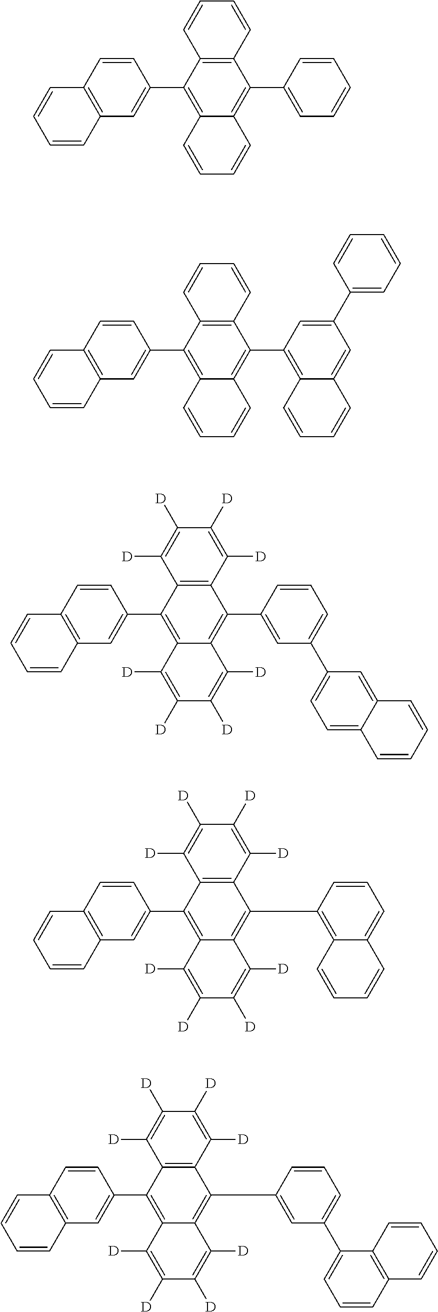

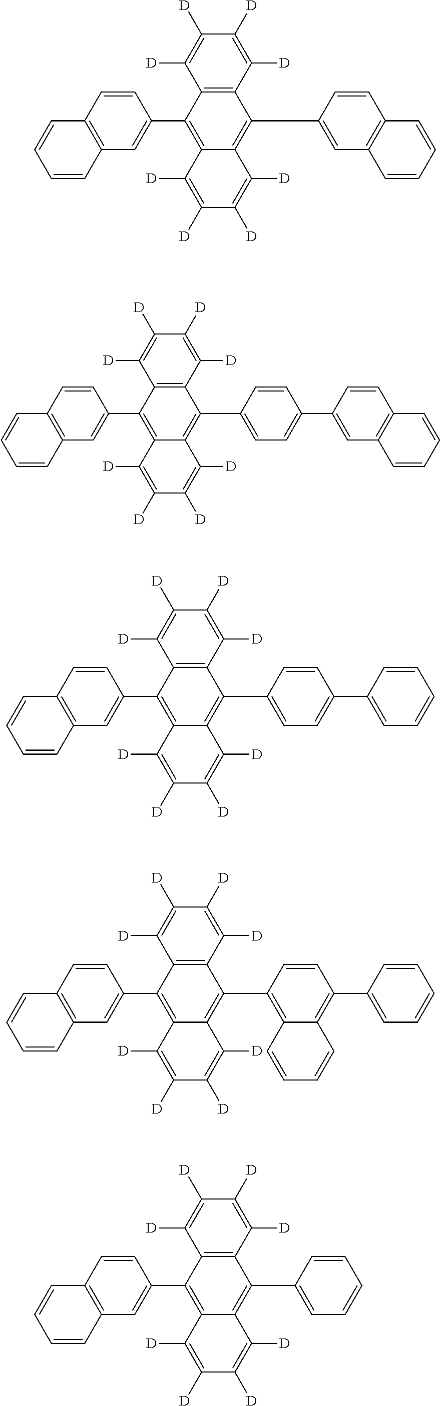

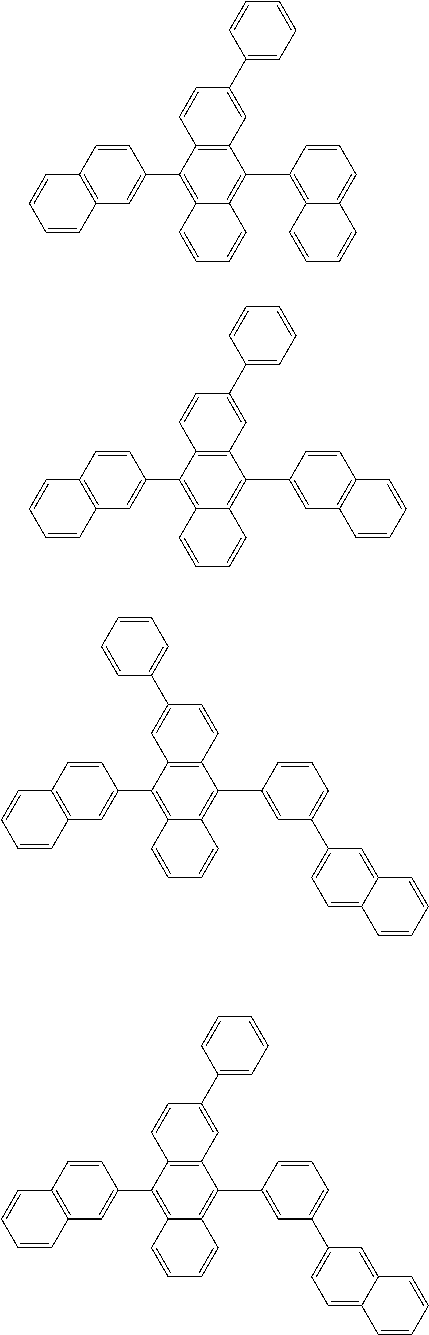

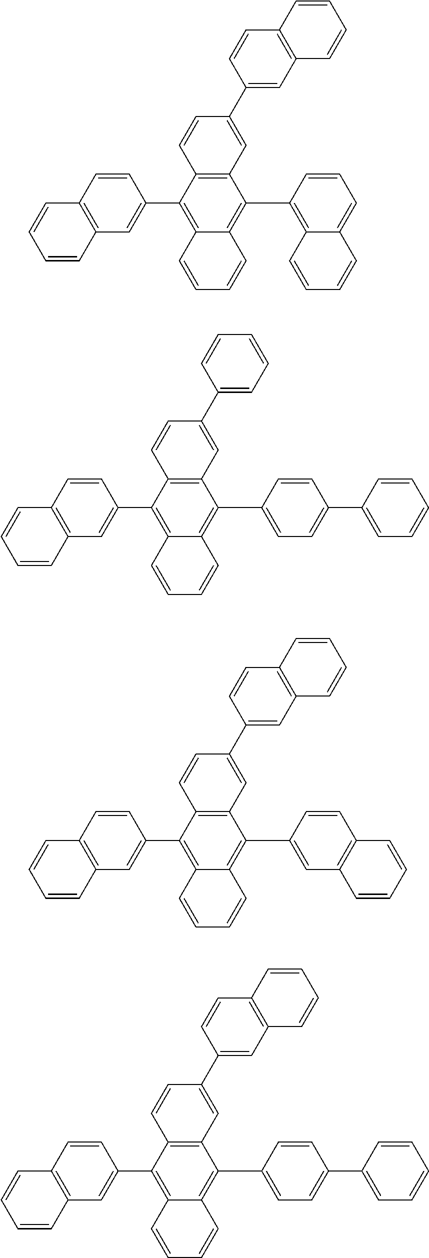

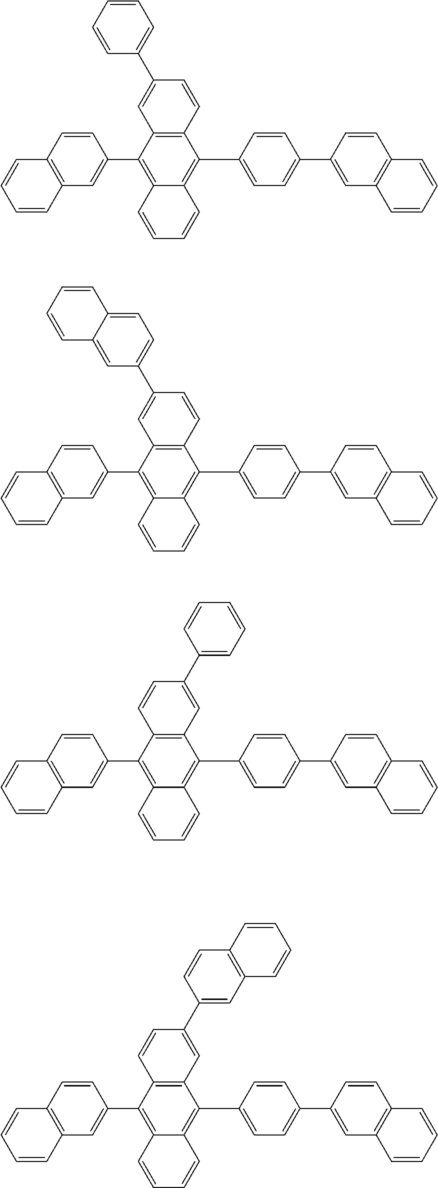

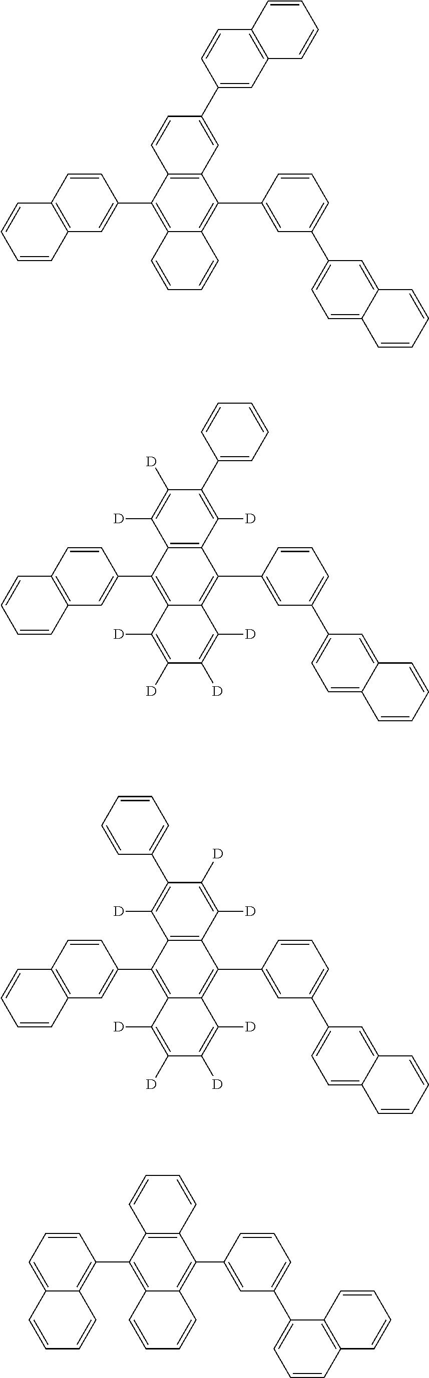

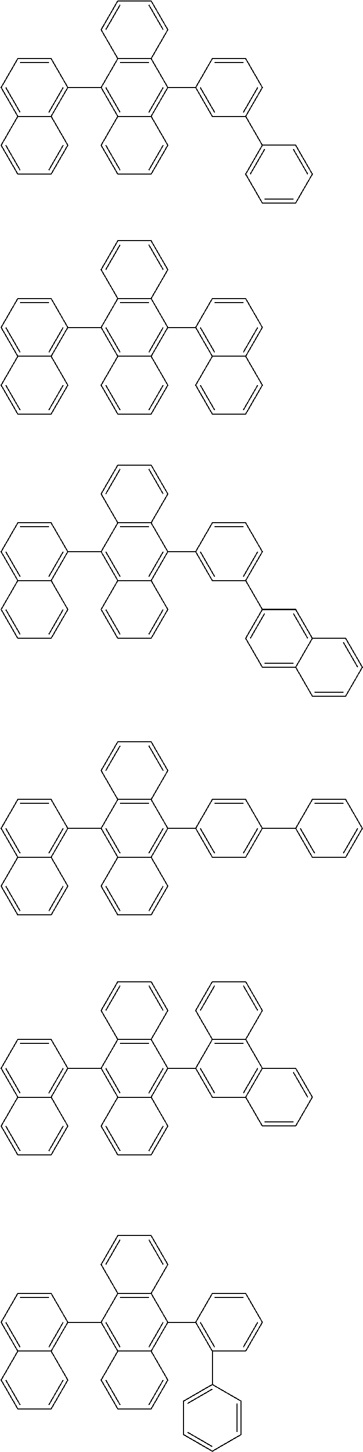

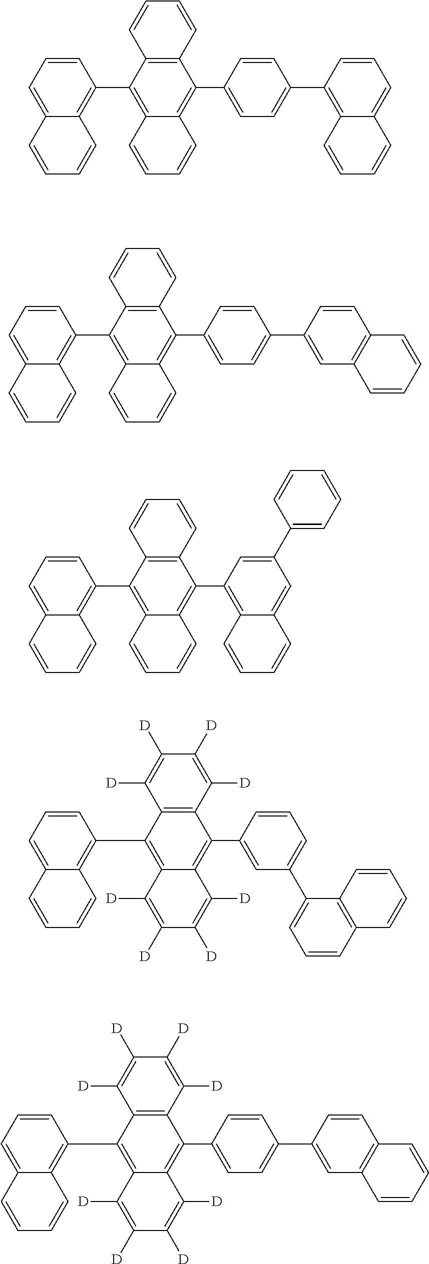

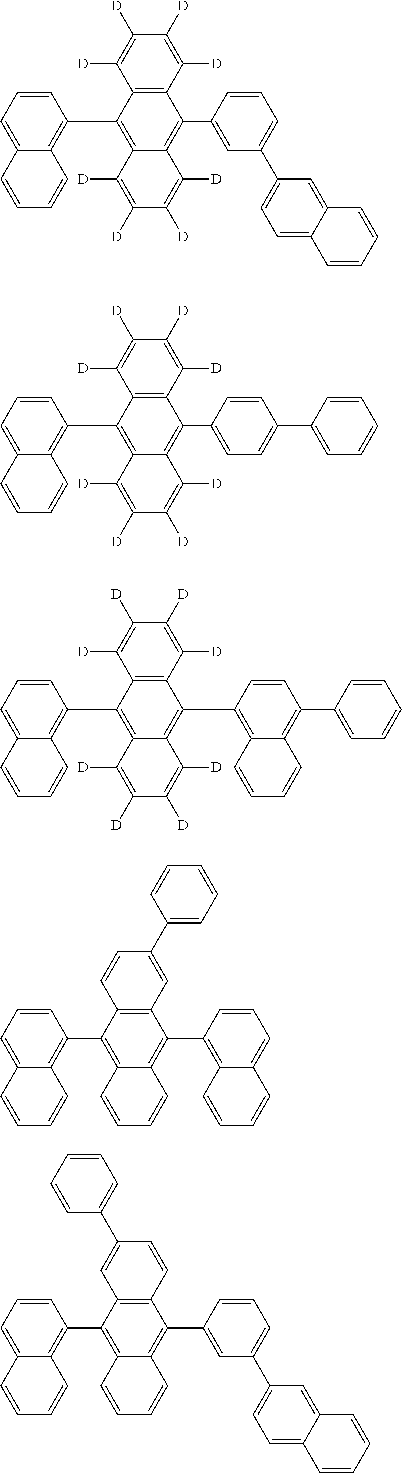

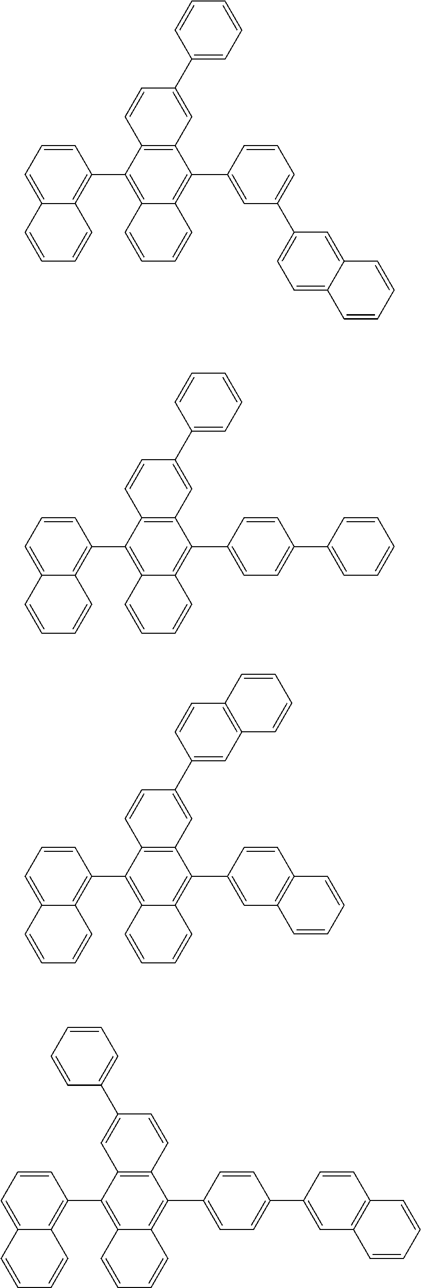

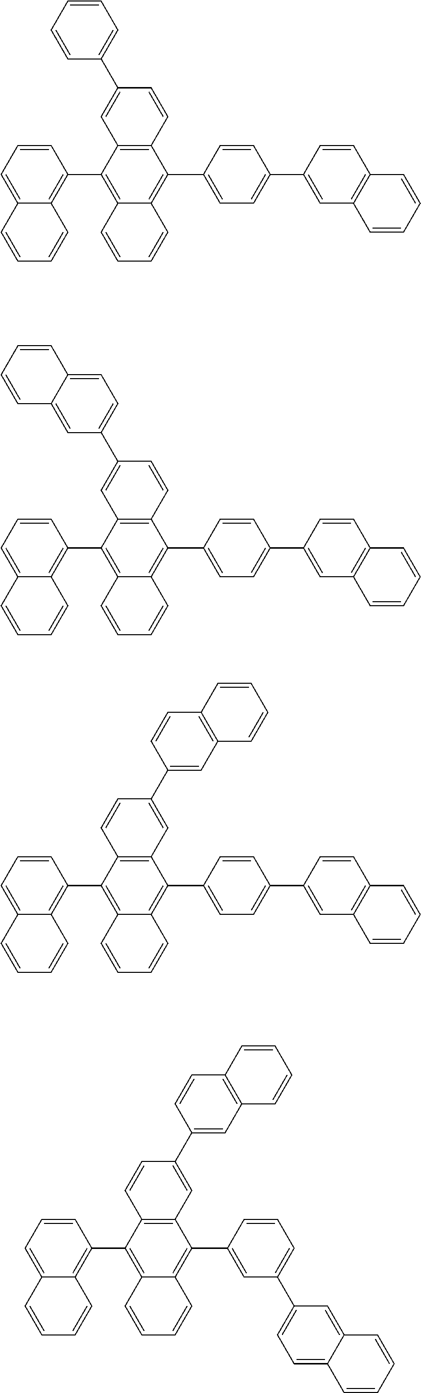

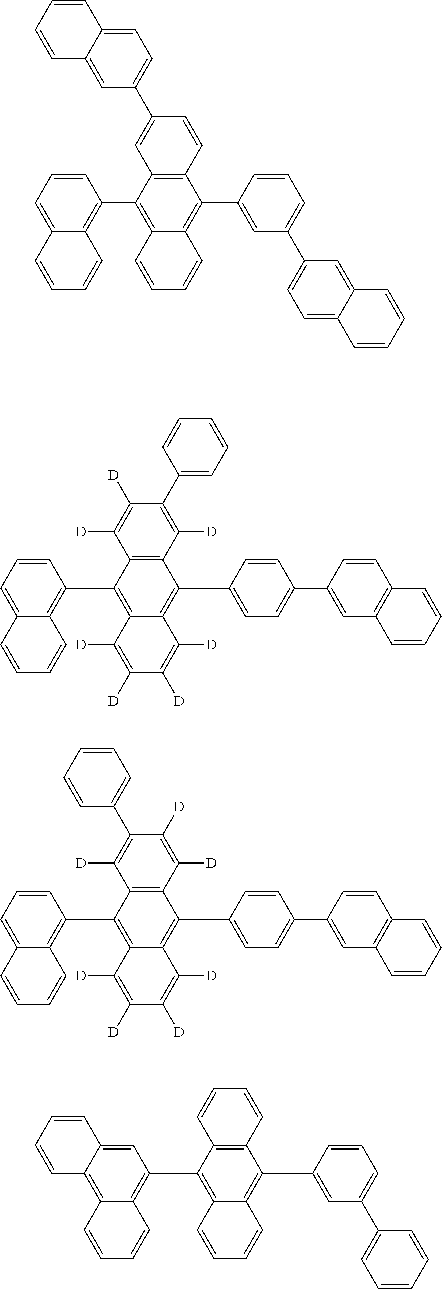

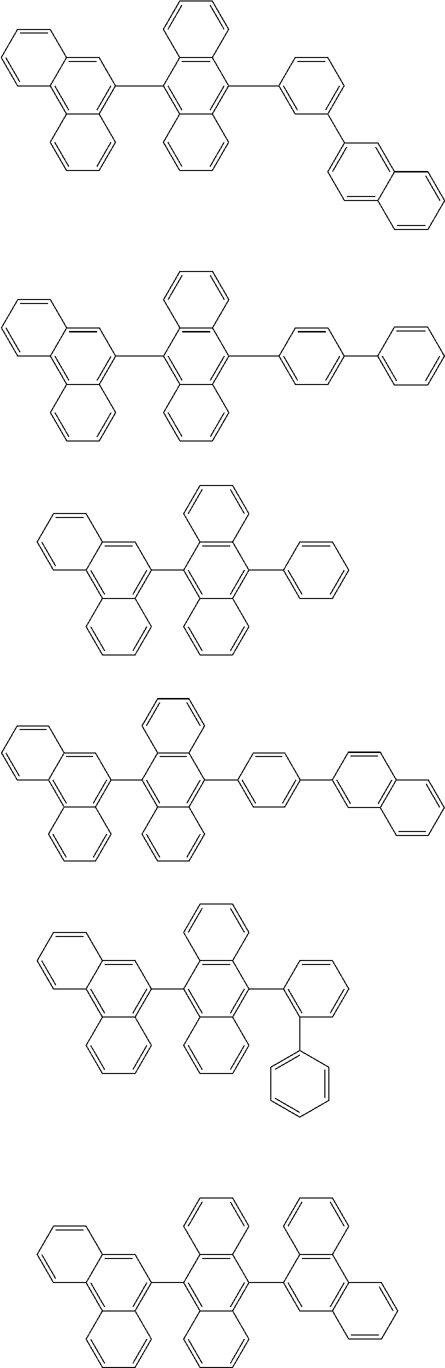

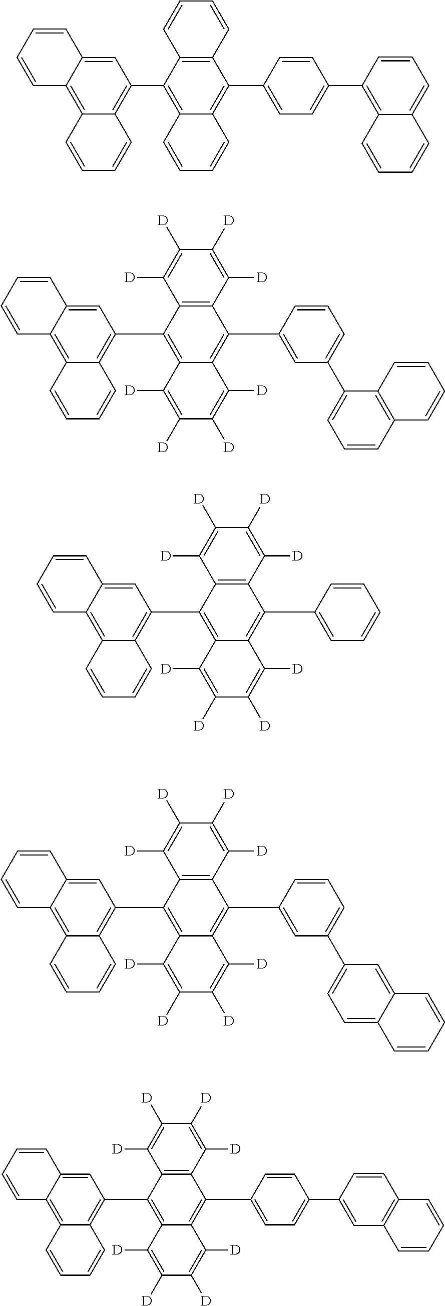

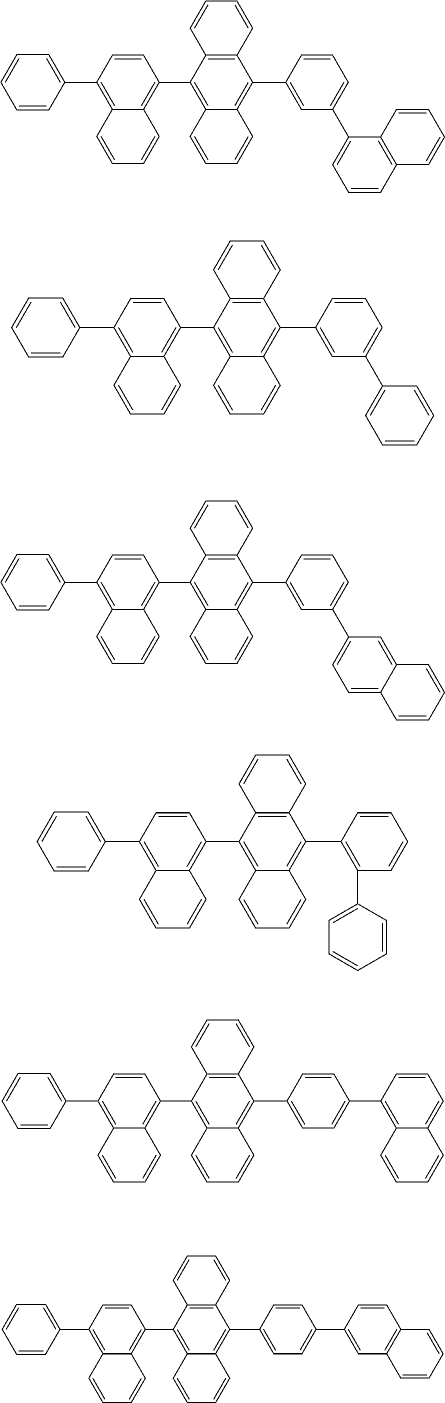

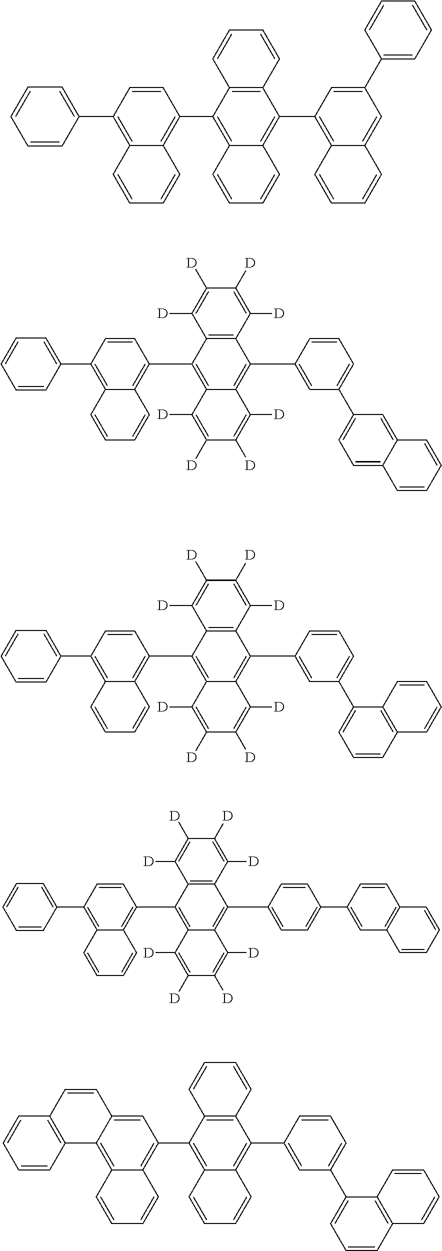

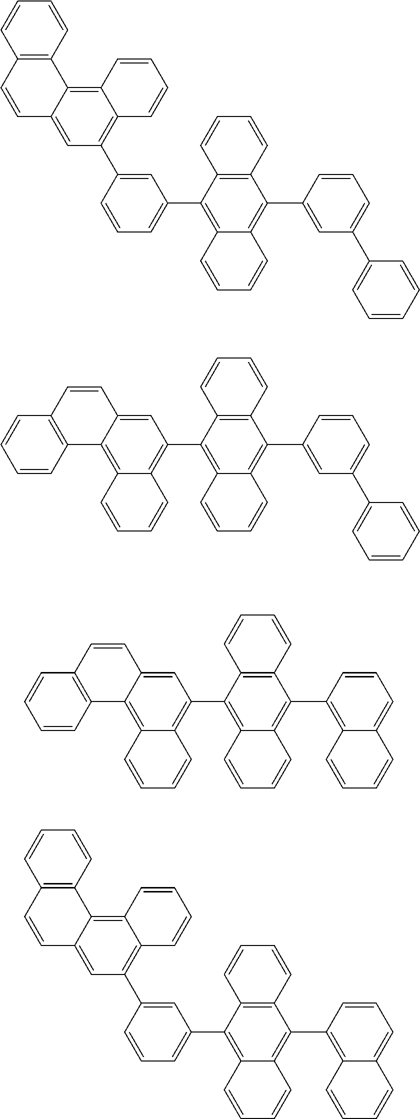

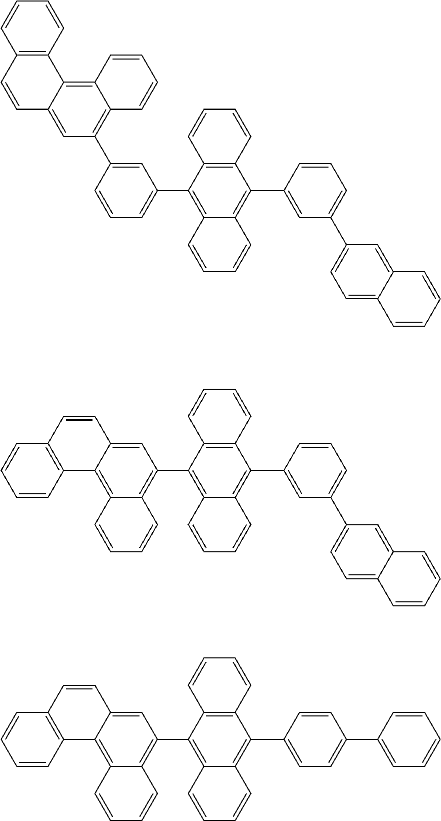

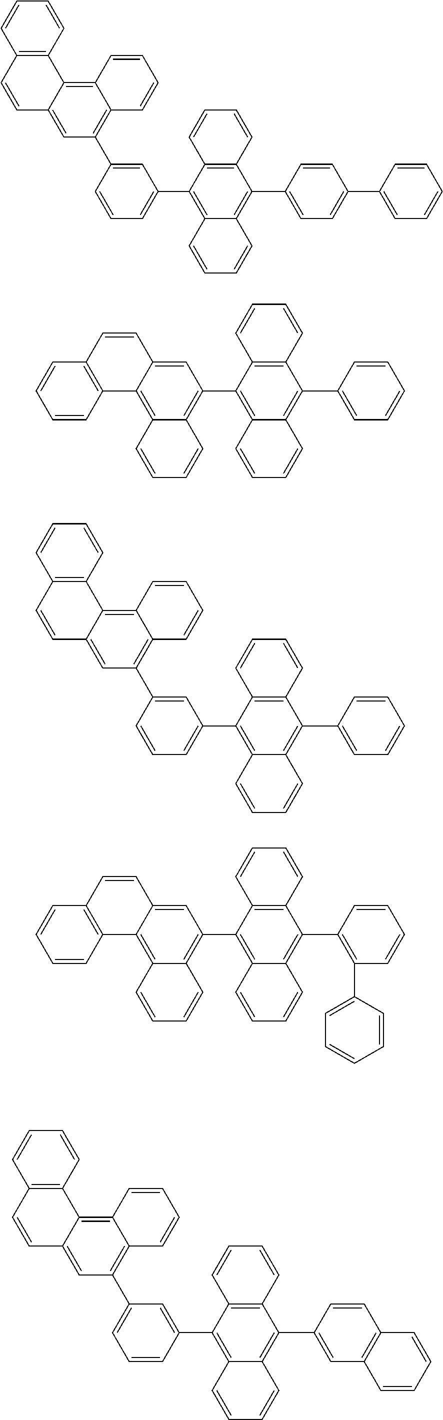

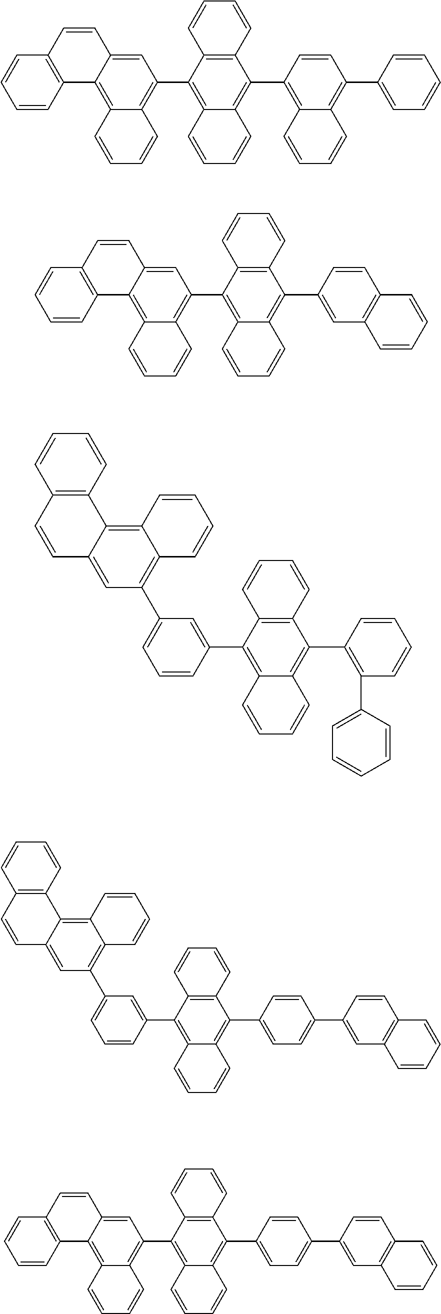

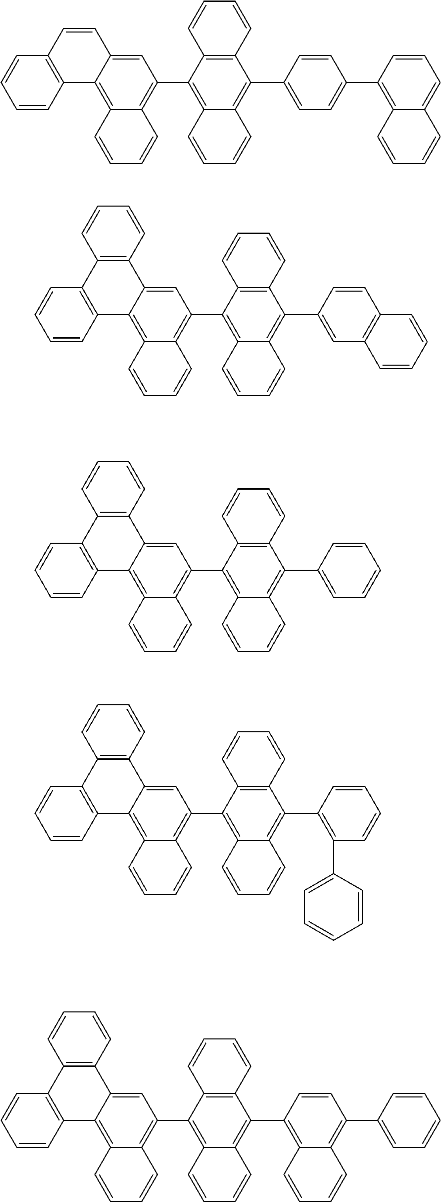

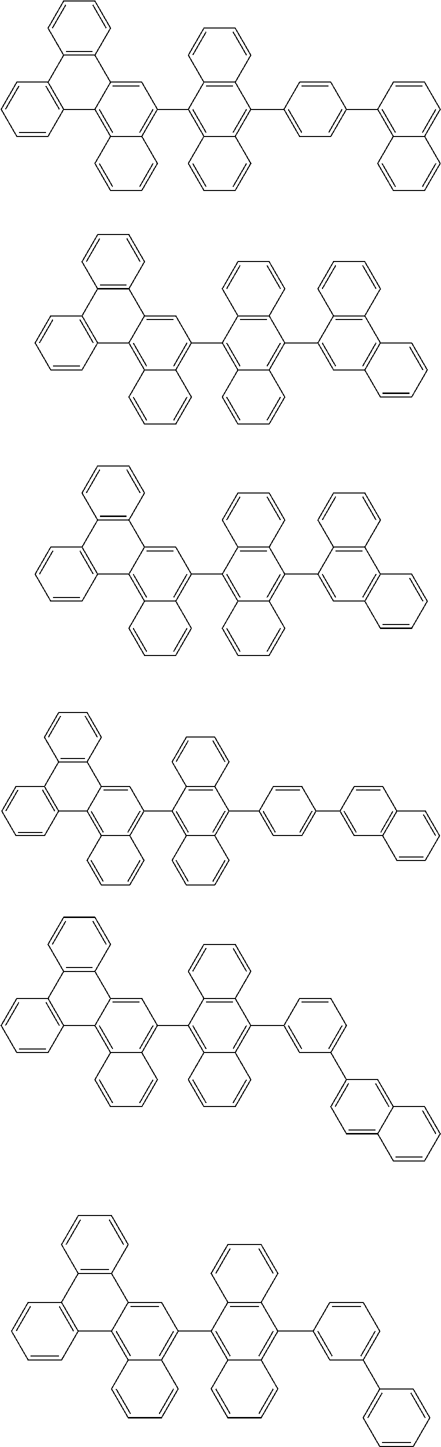

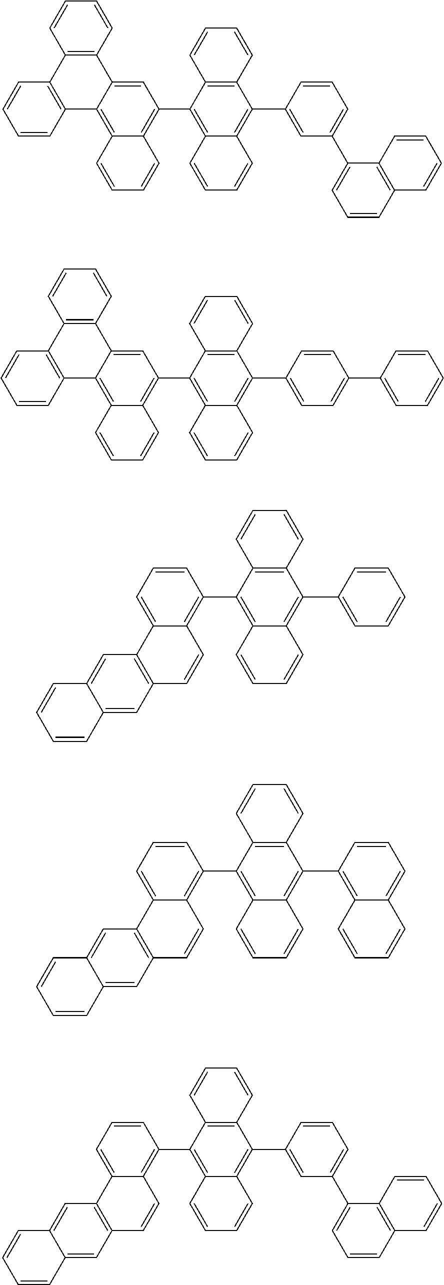

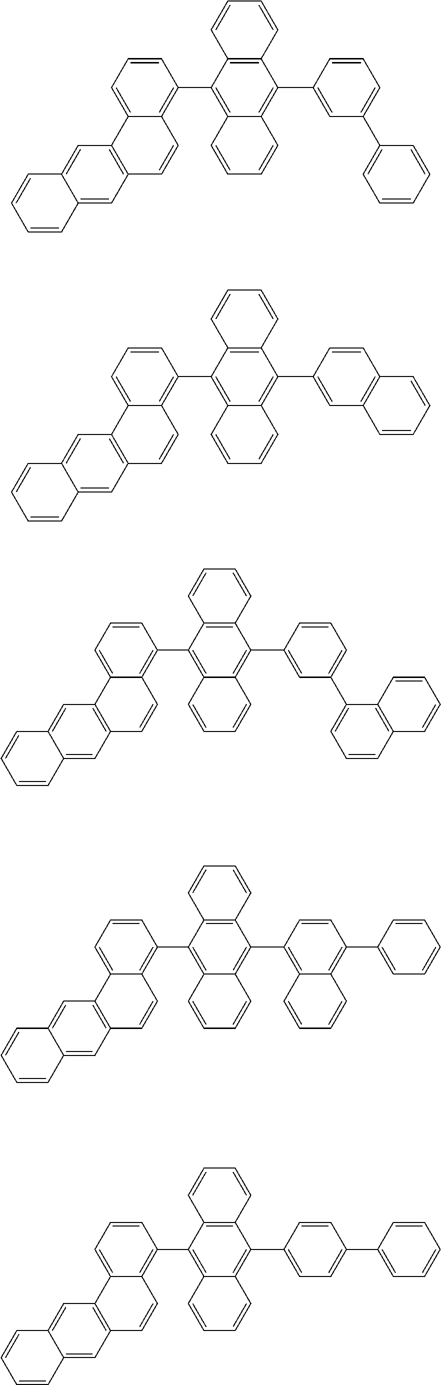

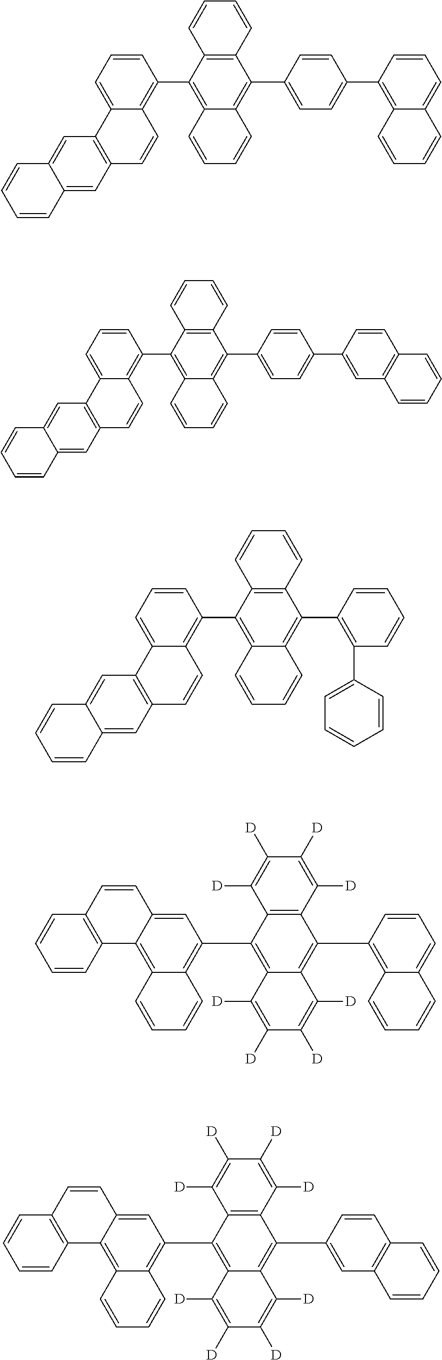

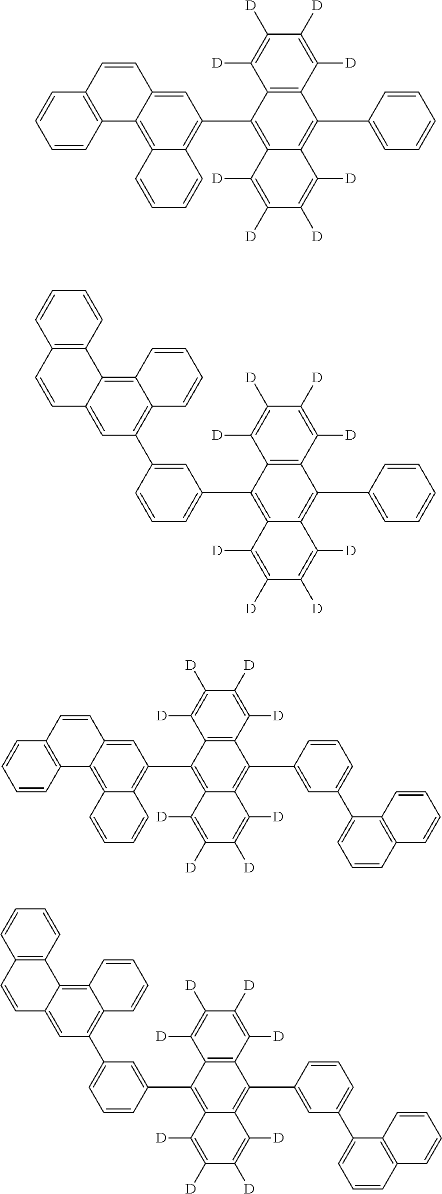 [SMILES: [2H]c1c([2H])c([2H])c2c(-c3cc4ccc5ccccc5c4c4ccccc34)c3c([2H])c([2H])c([2H])c([2H])c3c(-c3ccccc3)c2c1[2H] ; [2H]c1c([2H])c([2H])c2c(-c3cccc(-c4cc5ccc6ccccc6c5c5ccccc45)c3)c3c([2H])c([2H])c([2H])c([2H])c3c(-c3ccccc3)c2c1[2H] ; [2H]c1c([2H])c([2H])c2c(-c3cc4ccc5ccccc5c4c4ccccc34)c3c([2H])c([2H])c([2H])c([2H])c3c(-c3cccc(-c4cccc5ccccc45)c3)c2c1[2H] ; [2H]c1c([2H])c([2H])c2c(-c3cccc(-c4cc5ccc6ccccc6c5c5ccccc45)c3)c3c([2H])c([2H])c([2H])c([2H])c3c(-c3cccc(-c4cccc5ccccc45)c3)c2c1[2H]]

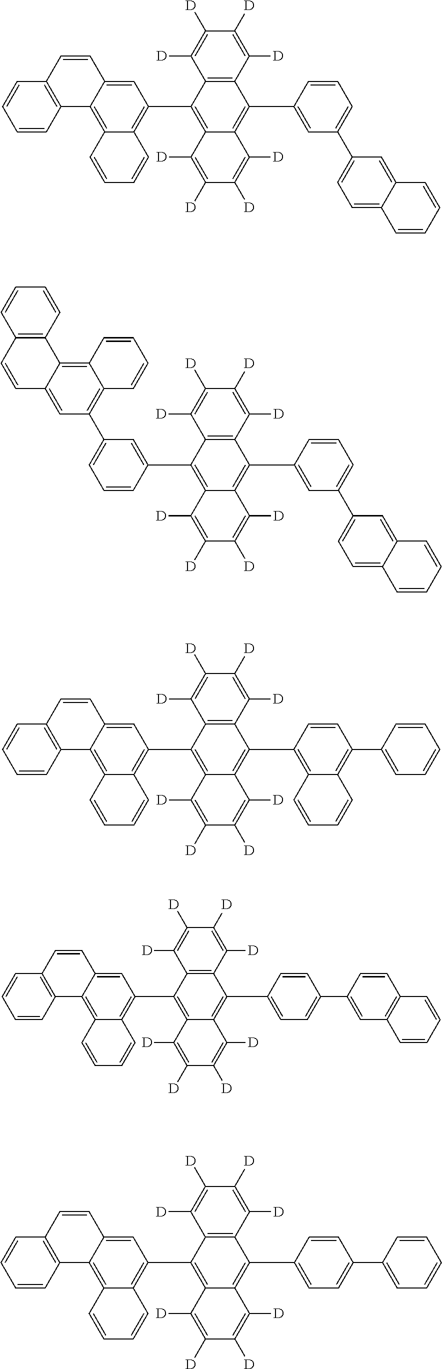

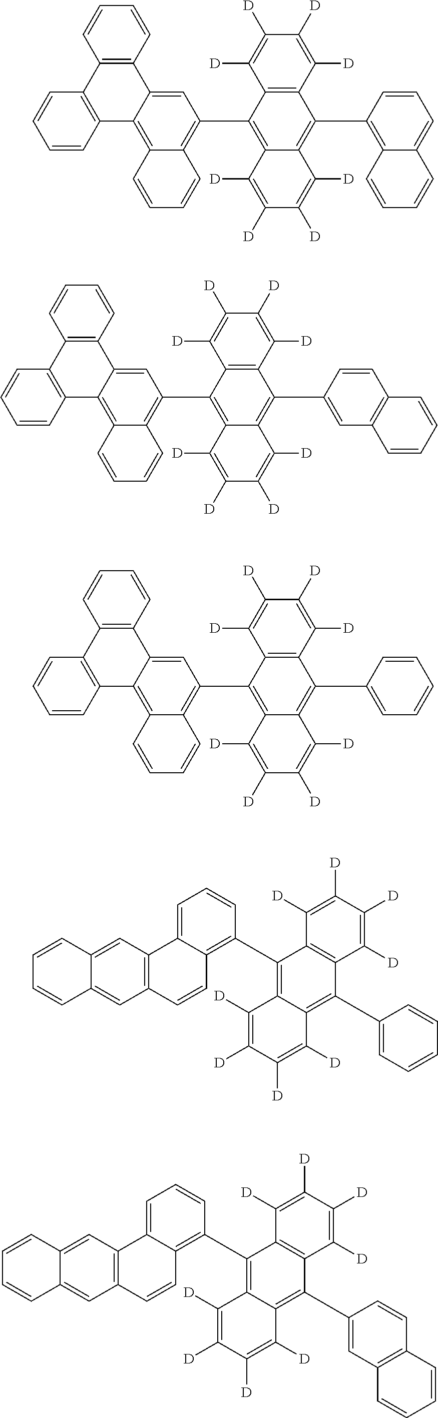

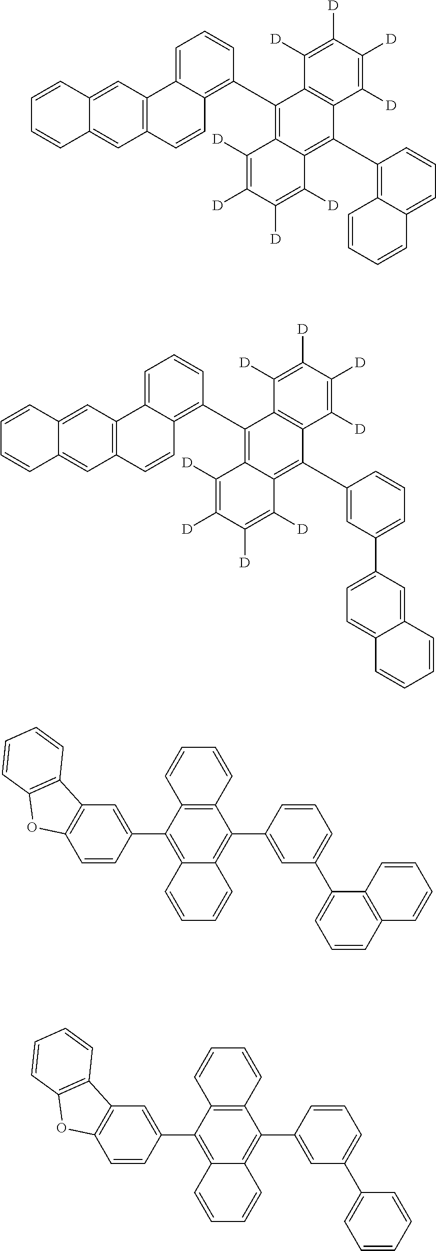 [SMILES: [2H]c1c([2H])c([2H])c2c(-c3cccc4c3ccc3cc5ccccc5cc34)c3c([2H])c([2H])c([2H])c([2H])c3c(-c3cccc4ccccc34)c2c1[2H] ; [2H]c1c([2H])c([2H])c2c(-c3cccc4c3ccc3cc5ccccc5cc34)c3c([2H])c([2H])c([2H])c([2H])c3c(-c3cccc(-c4ccc5ccccc5c4)c3)c2c1[2H] ; c1cc(-c2cccc3ccccc23)cc(-c2c3ccccc3c(-c3ccc4oc5ccccc5c4c3)c3ccccc23)c1 ; c1ccc(-c2cccc(-c3c4ccccc4c(-c4ccc5oc6ccccc6c5c4)c4ccccc34)c2)cc1]

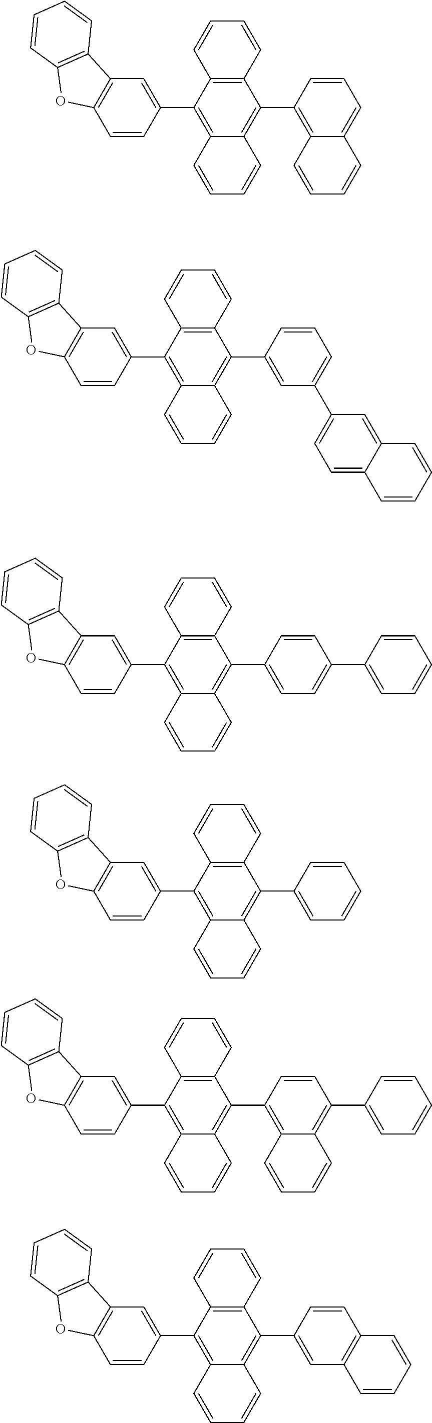

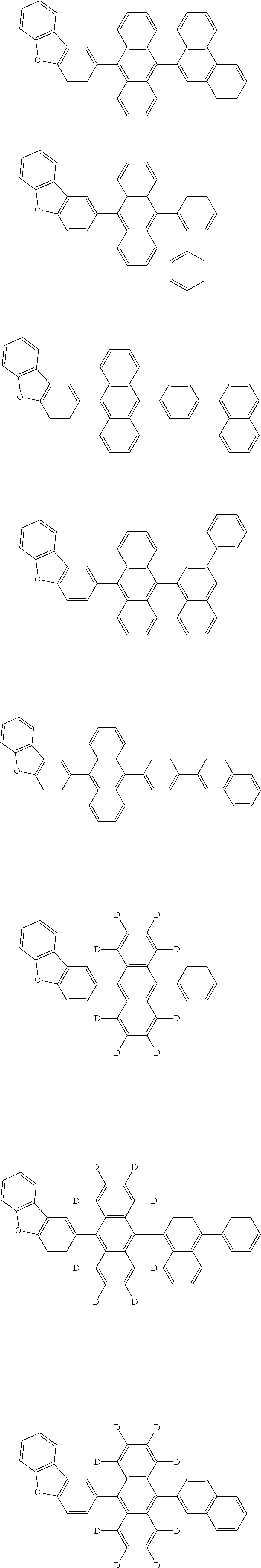

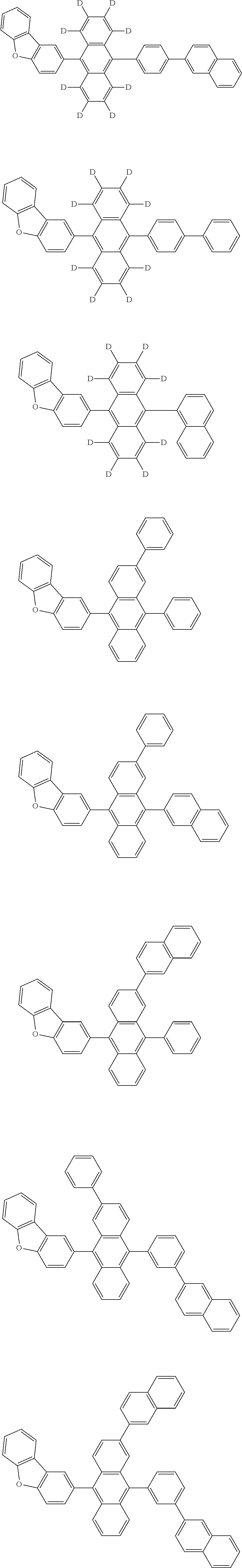

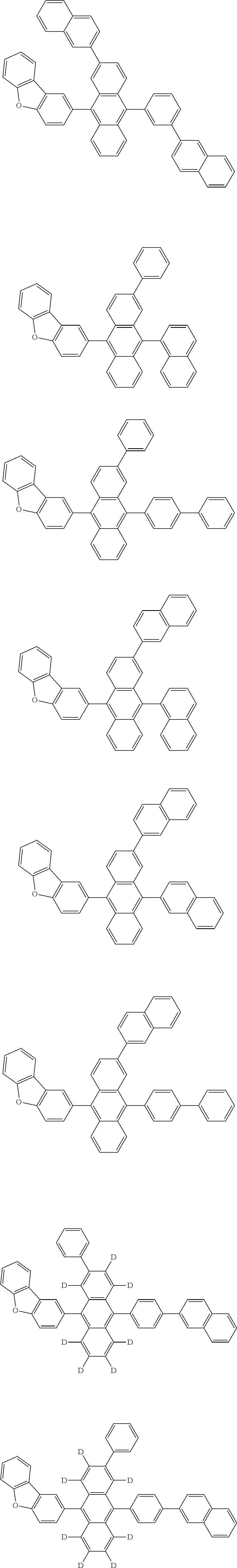

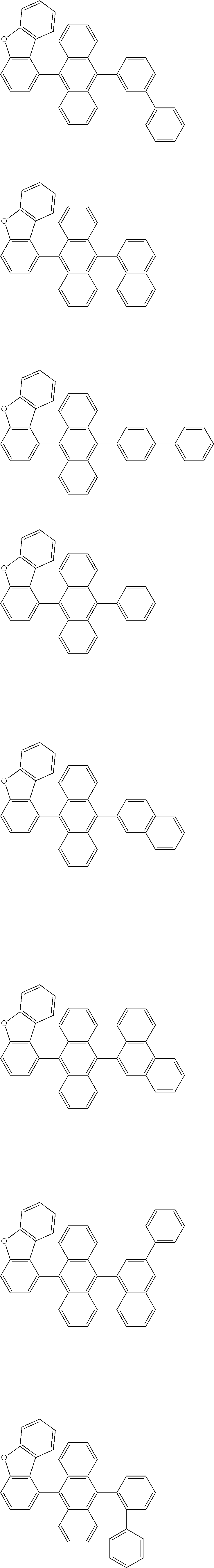

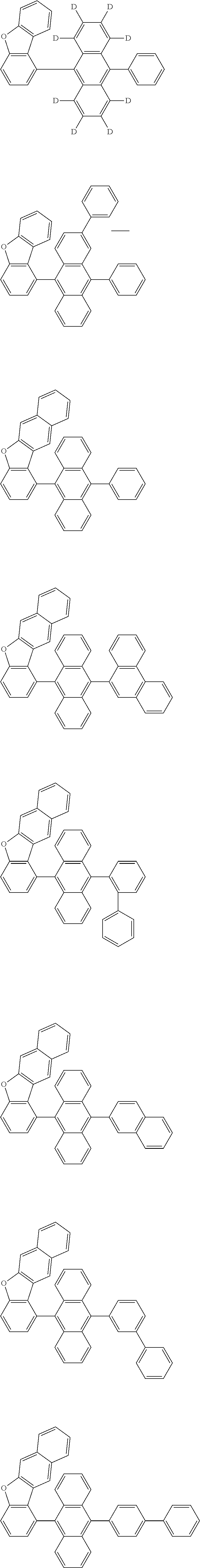

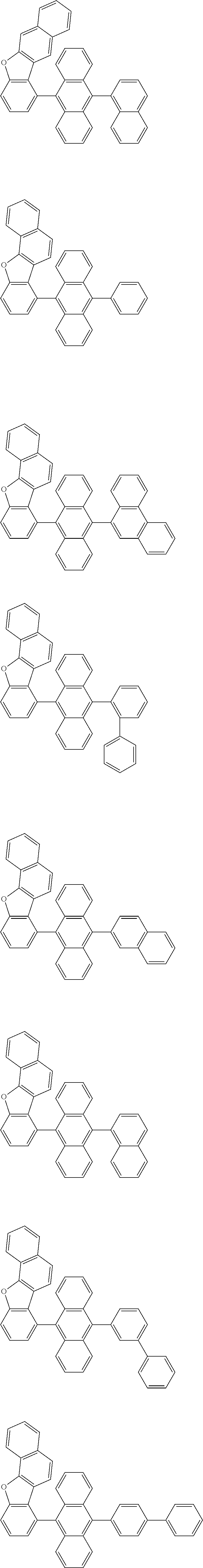

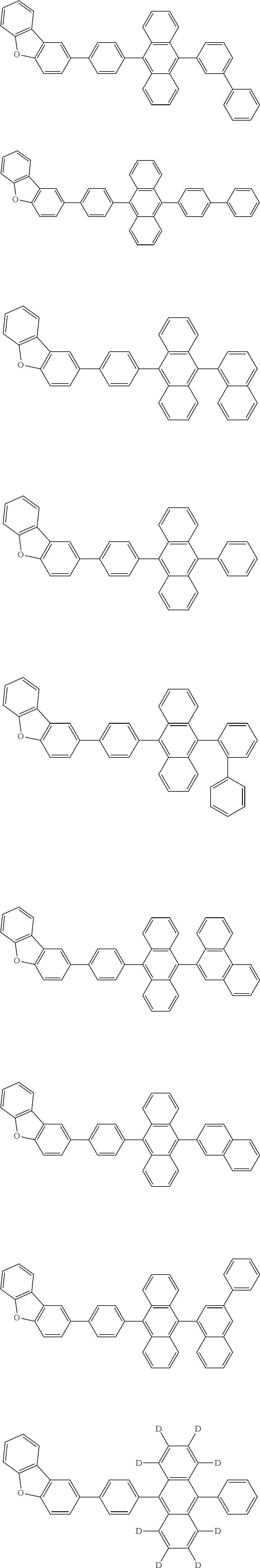

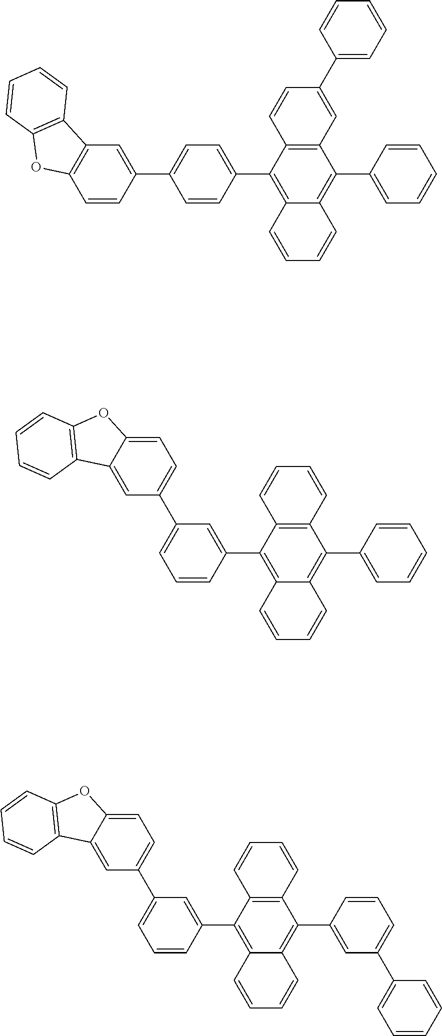 [SMILES: c1ccc(-c2ccc3c(-c4ccc(-c5ccc6oc7ccccc7c6c5)cc4)c4ccccc4c(-c4ccccc4)c3c2)cc1 ; c1ccc(-c2c3ccccc3c(-c3cccc(-c4ccc5oc6ccccc6c5c4)c3)c3ccccc23)cc1 ; c1ccc(-c2cccc(-c3c4ccccc4c(-c4cccc(-c5ccc6oc7ccccc7c6c5)c4)c4ccccc34)c2)cc1]

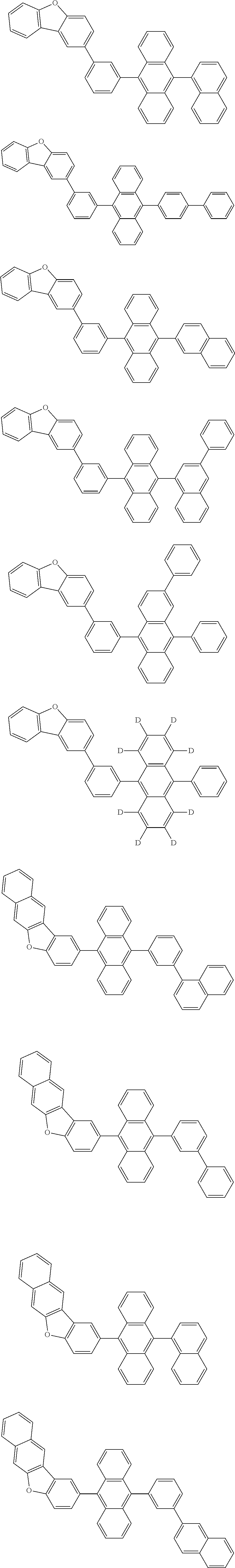

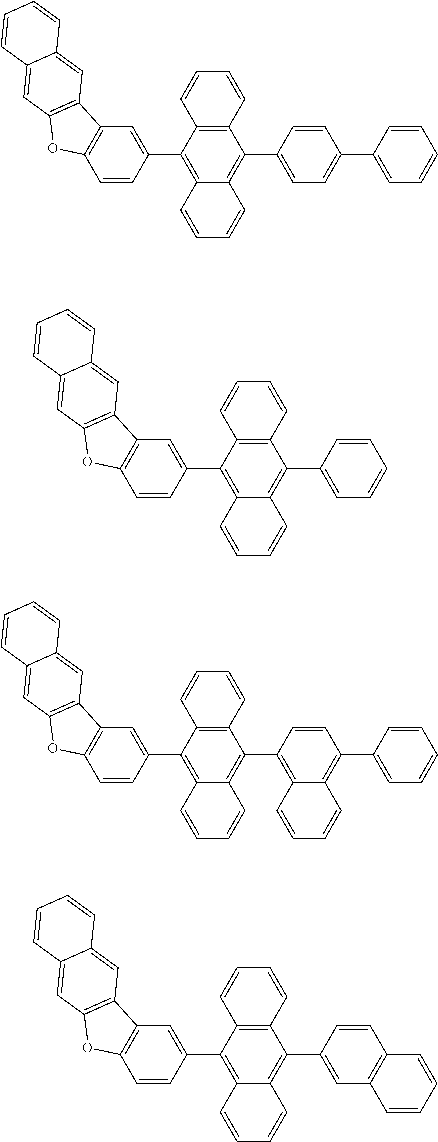 [SMILES: c1ccc(-c2ccc(-c3c4ccccc4c(-c4ccc5oc6cc7ccccc7cc6c5c4)c4ccccc34)cc2)cc1 ; c1ccc(-c2c3ccccc3c(-c3ccc4oc5cc6ccccc6cc5c4c3)c3ccccc23)cc1 ; c1ccc(-c2ccc(-c3c4ccccc4c(-c4ccc5oc6cc7ccccc7cc6c5c4)c4ccccc34)c3ccccc23)cc1 ; c1ccc2cc(-c3c4ccccc4c(-c4ccc5oc6cc7ccccc7cc6c5c4)c4ccccc34)ccc2c1]

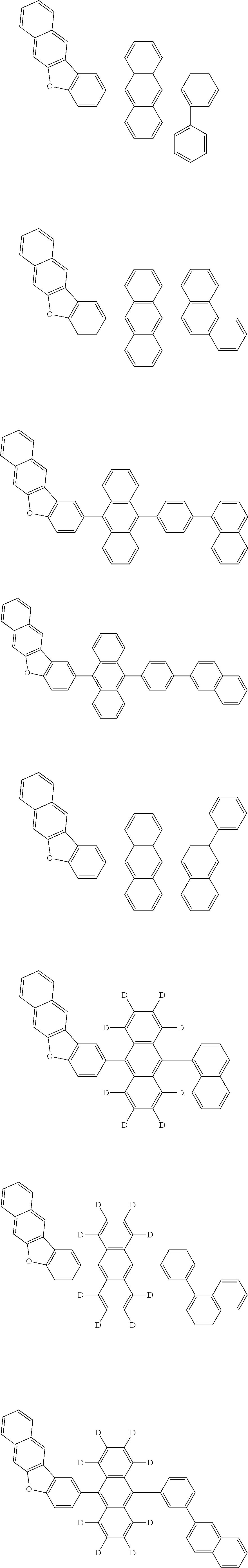

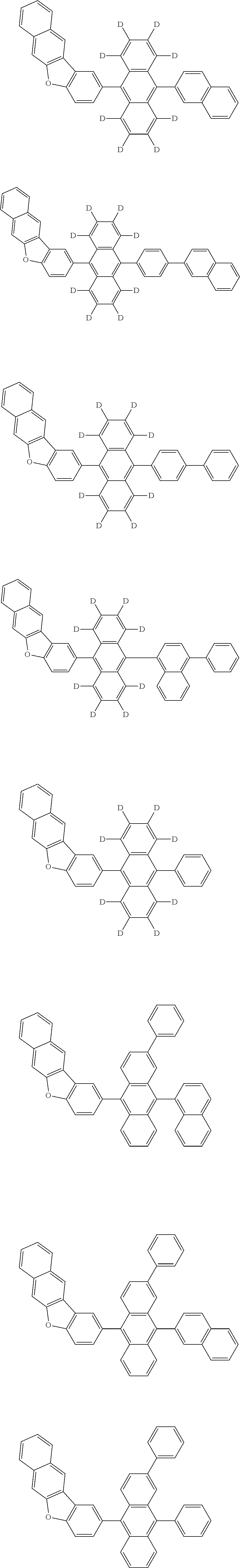

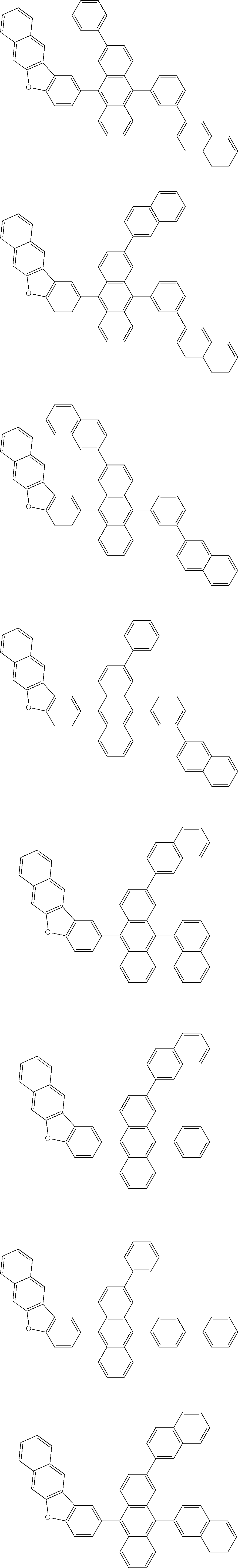

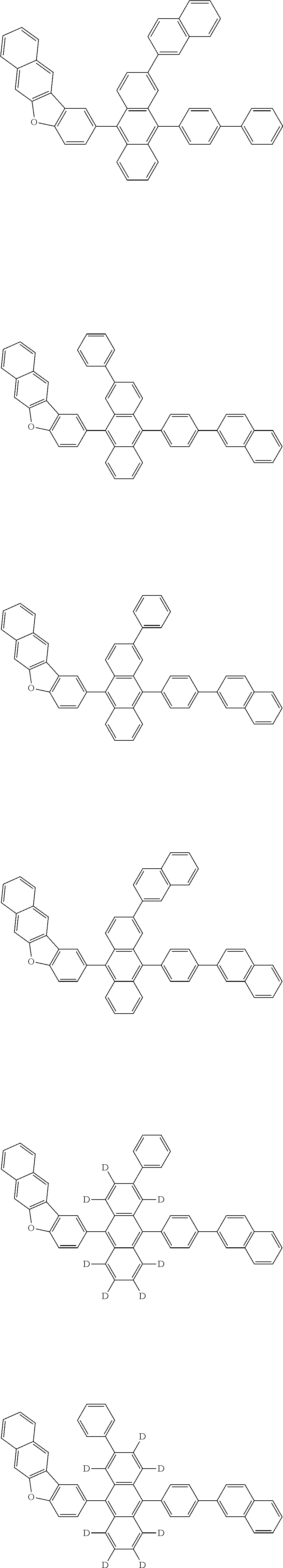

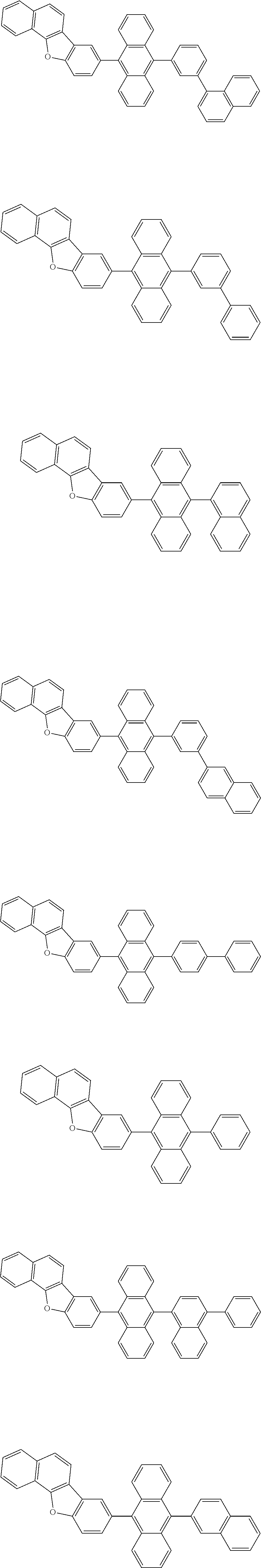

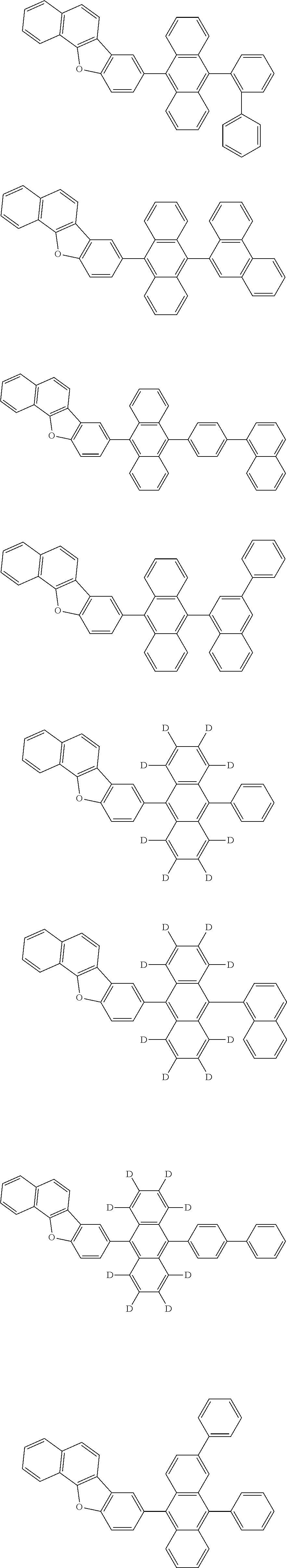

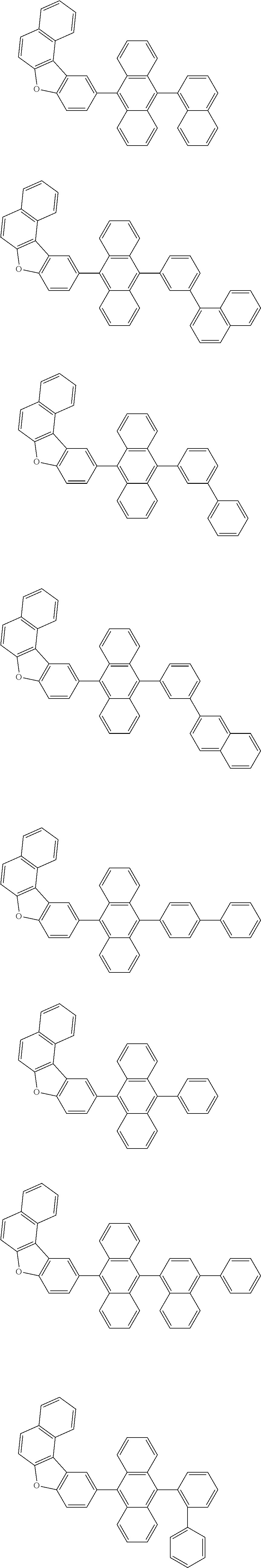

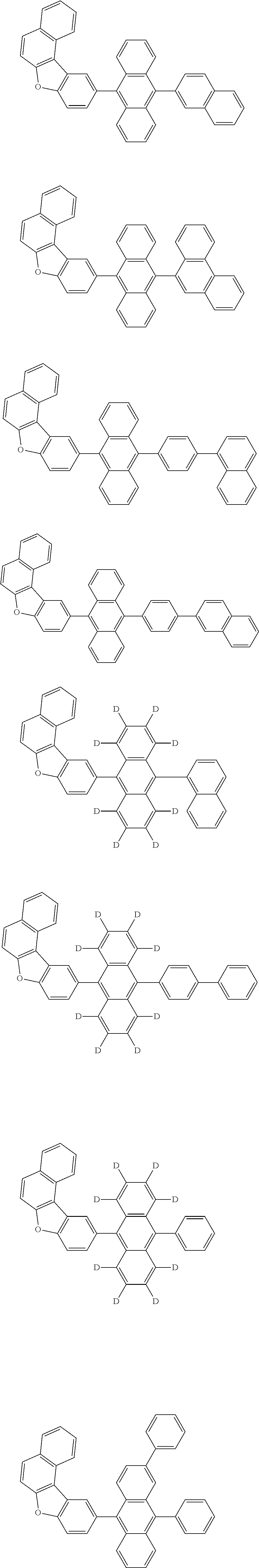

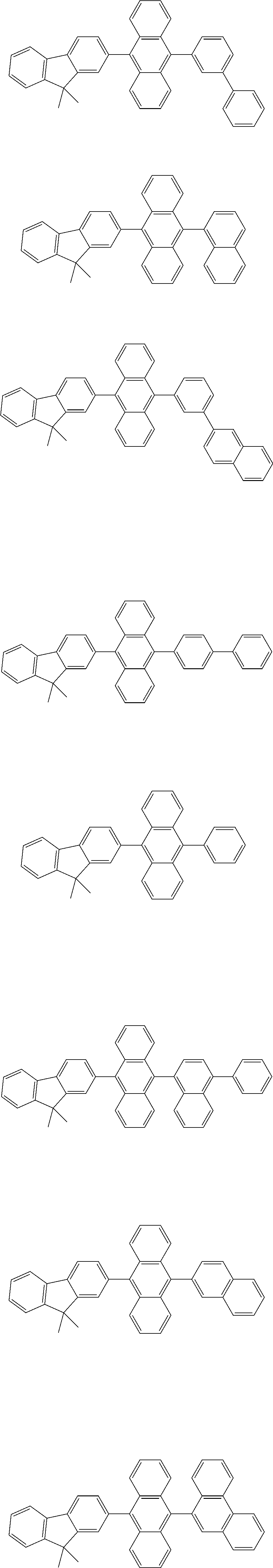

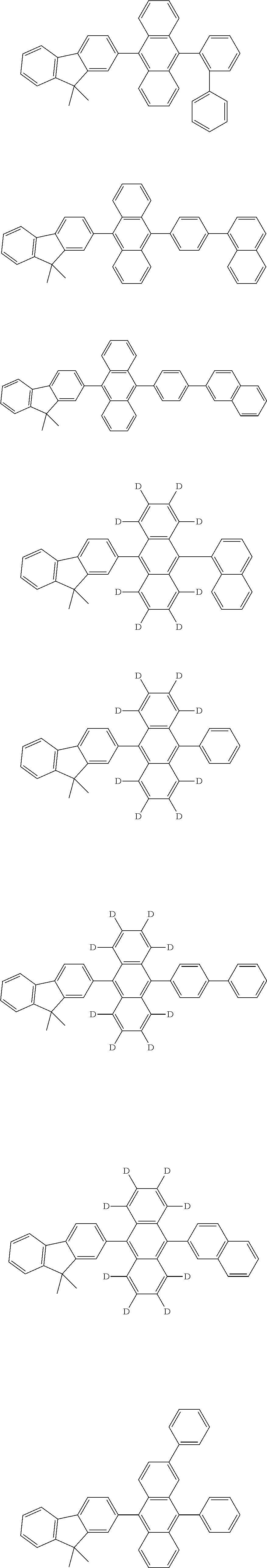

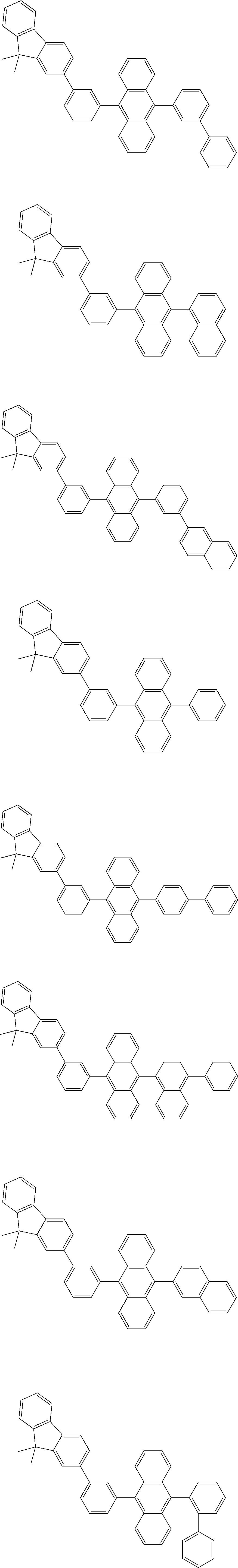

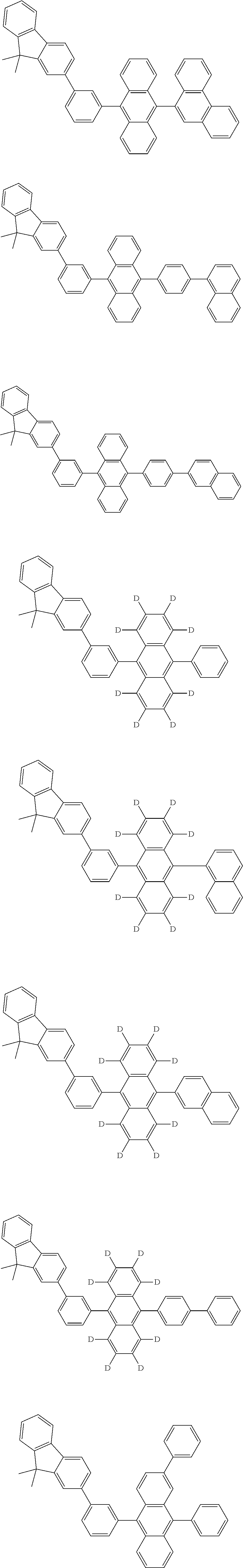

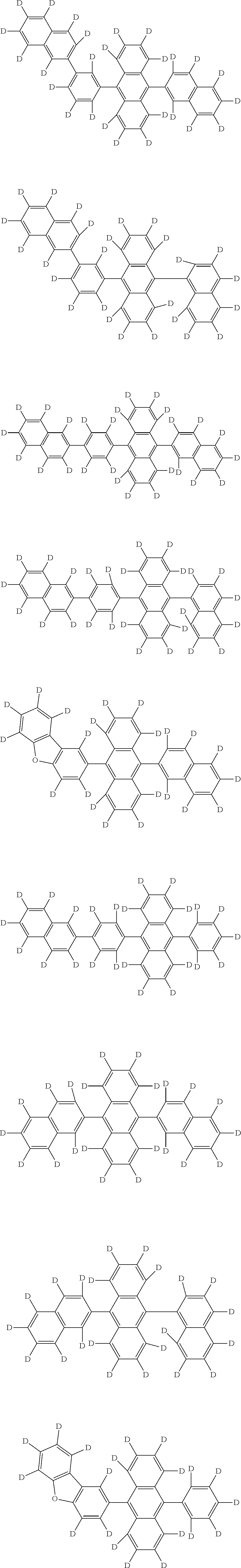

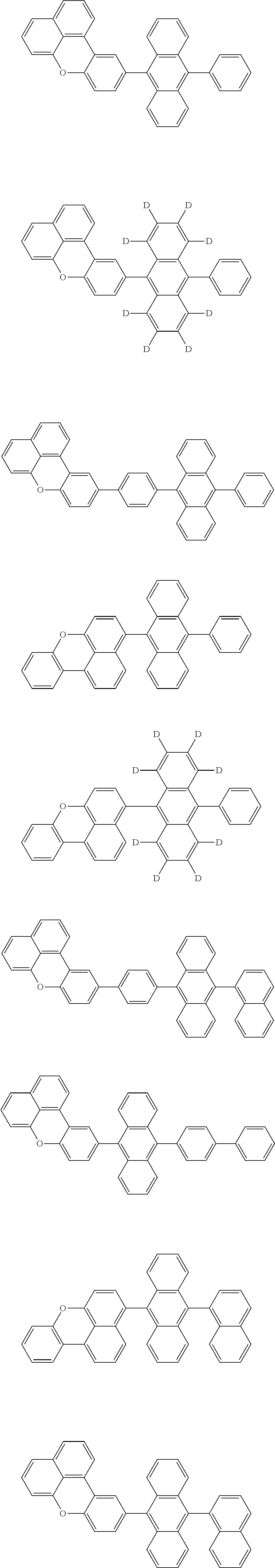

In one embodiment, the first compound is a compound represented by the following formula (1):

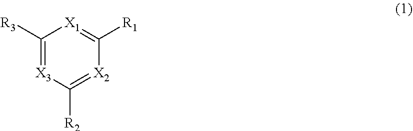

wherein in the formula (1),

X₁ to X₃ are independently CR₄ or N, wherein R₄ is a hydrogen atom or a substituent R;

at least one of X₁ to X₃ is N; when two or more R₄'s are present, the two or more R₄'s may be the same as or different from each other;

R₁ to R₃ are independently

a hydrogen atom, or
a substituent R;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituents R are present, the two or more of the substituents R may be the same as or different from each other;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other.

In one embodiment, the first compound is a compound represented by the following formula (11):

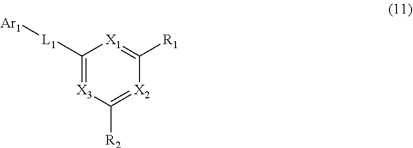

wherein in the formula (11),

X₁ to X₃, R₁ and R₂ are as defined in the formula (1);

L₁ is

a single bond,
a substituted or unsubstituted arylene group including 6 to 50 ring carbon atoms, or
a substituted or unsubstituted divalent heterocyclic group including 5 to 50 ring atoms; and

Ar₁ is

a substituted or unsubstituted aryl group including 6 to 50 ring carbon atoms, or
a substituted or unsubstituted monovalent heterocyclic group including 5 to 50 ring atoms.
In one embodiment, Ar₁ is a group represented by the following formula (12):

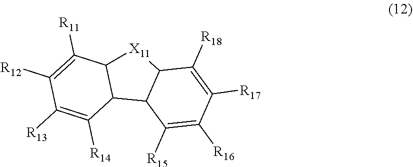

wherein in the formula (12),

X₁₁ is O, S, N(R₂₁), or C(R₂₂)(R₂₃);

one of R₁₁ to R₁₈ and R₂₁ to R₂₃ is a single bond bonding with Li;

one or more sets of adjacent two or more of R₁₁ to R₁₈ which are not single bonds bonding with L₁ form a substituted or unsubstituted, saturated or unsaturated ring by bonding with each other, or do not form the substituted or unsubstituted, saturated or unsaturated ring;

R₁₁ to R₁₈ which are not single bonds bonding with L₁ and which do not form the substituted or unsubstituted, saturated or unsaturated ring, and R₂₁ to R₂₃ which are not single bonds bonding with L₁ are independently

a hydrogen atom, or
a substituent R; and

the substituent R is as defined in the formula (1).

In one embodiment, X₁₁ is N(R₂₁).

In one embodiment, the first compound is a compound represented by the following formula (21):

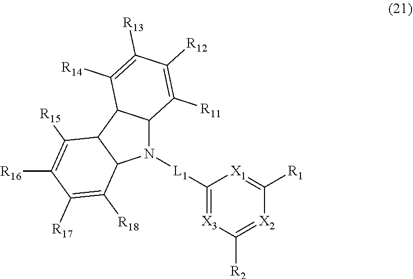

wherein in the formula (21),

X₁ to X₃, R₁ and R₂ are as defined in the formula (1);

L₁ is as defined in the formula (11); and

R₁₁ to R₁₈ are as defined in the formula (12).

In one embodiment, L₁ is a single bond, or a unsubstituted arylene group including 6 to 50 ring carbon atoms,

the substituent R is

an unsubstituted alkyl group including 1 to 50 carbon atoms,
an unsubstituted alkenyl group including 2 to 50 carbon atoms,
an unsubstituted alkynyl group including 2 to 50 carbon atoms,
an unsubstituted cycloalkyl group including 3 to 50 ring carbon atoms,
—Si(R₉₁₁)(R₉₁₂)(R₉₁₃),

### —O—(R₉₁₄),

### —S—(R₉₁₅),

—N(R₉₁₆)(R₉₁₇),
a halogen atom, a cyano group, a nitro group, or
an unsubstituted aryl group including 6 to 50 ring carbon atoms, and

R₉₁₁ to R₉₁₇ are independently

a hydrogen atom,
an unsubstituted alkyl group including 1 to 50 carbon atoms,
an unsubstituted cycloalkyl group including 3 to 50 ring carbon atoms, or
an unsubstituted aryl group including 6 to 50 ring carbon atoms.
In one embodiment, two of X₁ to X₃ are N.

The first compound can be synthesized by using known alternative reactions or raw materials tailored to the target product.

Specific examples of the first compound will be described below, but these are merely illustrative, and the first compound is not limited to the following specific examples.

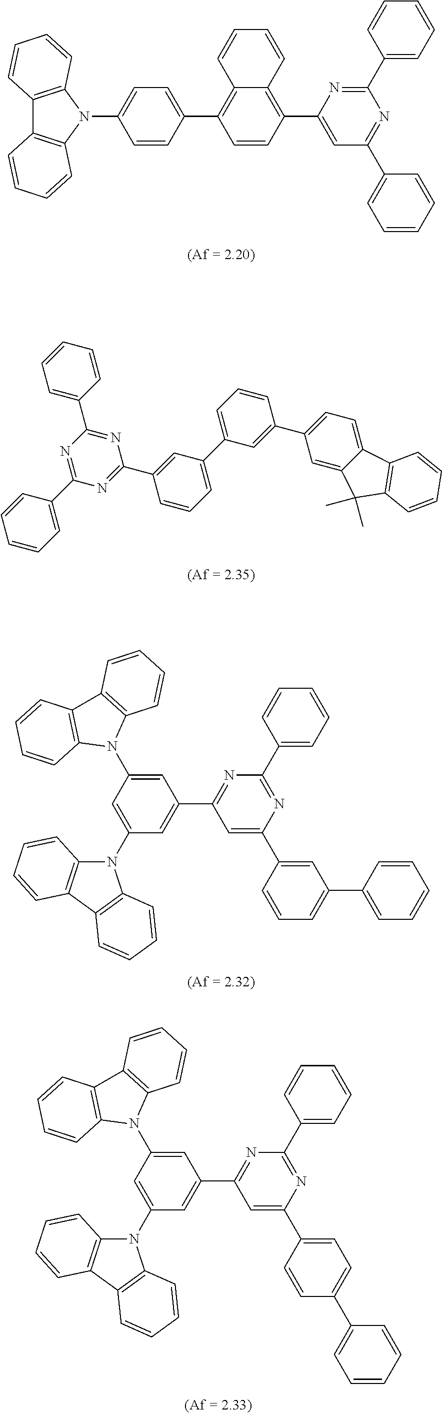 [SMILES: c1ccc(-c2cc(-c3ccc(-c4ccc(-n5c6ccccc6c6ccccc65)cc4)c4ccccc34)nc(-c3ccccc3)n2)cc1 ; CC1(C)c2ccccc2-c2ccc(-c3cccc(-c4cccc(-c5nc(-c6ccccc6)nc(-c6ccccc6)n5)c4)c3)cc21 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

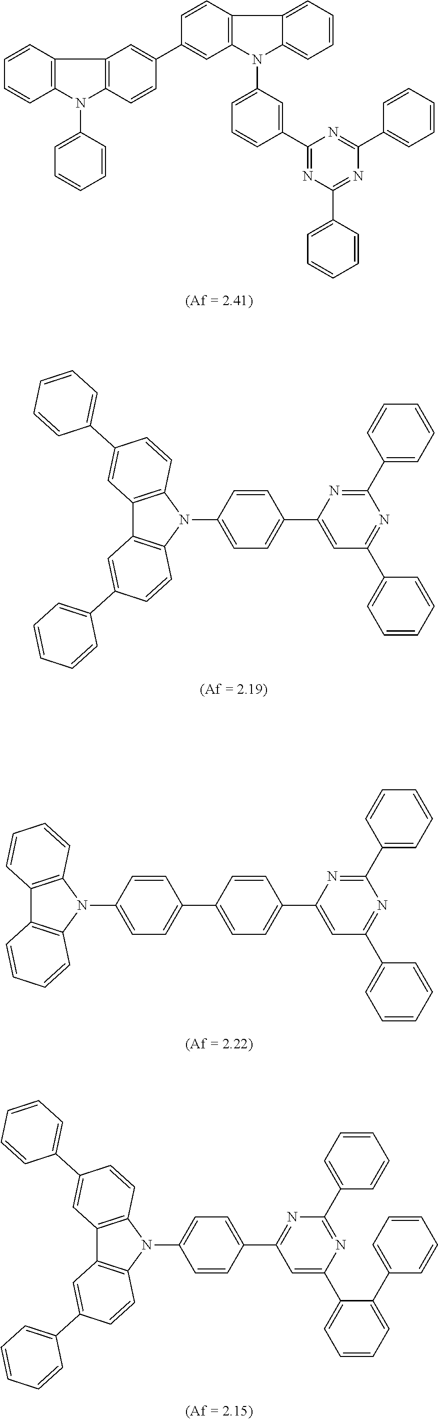 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2ccc3c(c2)c2cc(-c4ccccc4)ccc2n3-c2ccc(-c3cc(-c4ccccc4)nc(-c4ccccc4)n3)cc2)cc1 ; c1ccc(-c2cc(-c3ccc(-c4ccc(-n5c6ccccc6c6ccccc65)cc4)cc3)nc(-c3ccccc3)n2)cc1 ; c1ccc(-c2ccc3c(c2)c2cc(-c4ccccc4)ccc2n3-c2ccc(-c3cc(-c4ccccc4-c4ccccc4)nc(-c4ccccc4)n3)cc2)cc1]

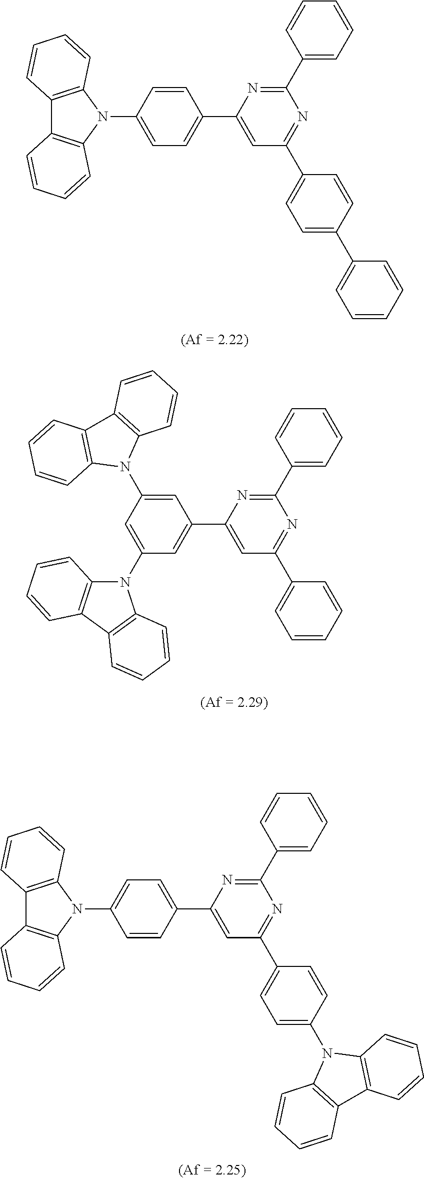 [SMILES: c1ccc(-c2ccc(-c3cc(-c4ccc(-n5c6ccccc6c6ccccc65)cc4)nc(-c4ccccc4)n3)cc2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2nc(-c3ccc(-n4c5ccccc5c5ccccc54)cc3)cc(-c3ccc(-n4c5ccccc5c5ccccc54)cc3)n2)cc1]

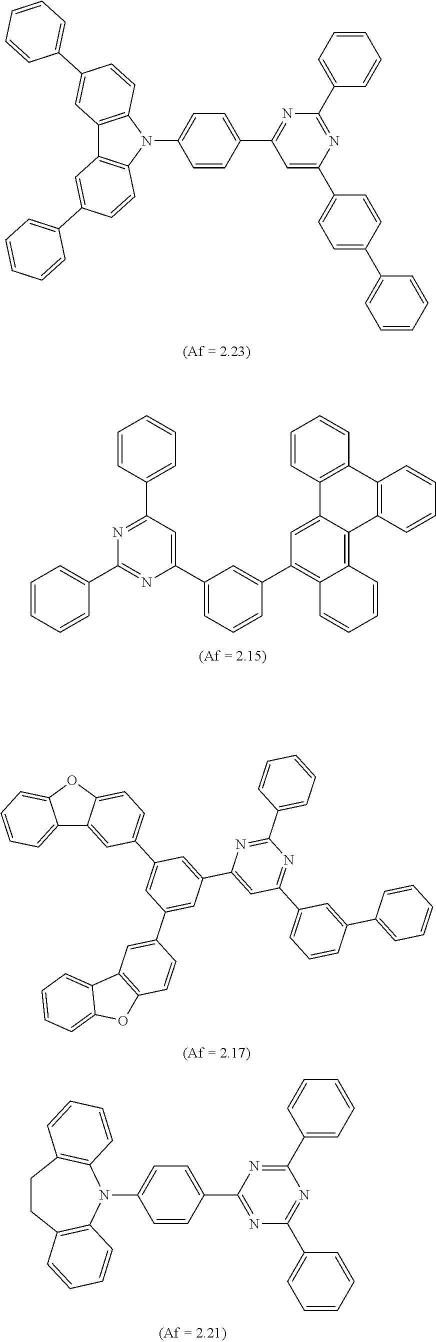 [SMILES: c1ccc(-c2ccc(-c3cc(-c4ccc(-n5c6ccc(-c7ccccc7)cc6c6cc(-c7ccccc7)ccc65)cc4)nc(-c4ccccc4)n3)cc2)cc1 ; c1ccc(-c2cc(-c3cccc(-c4cc5c6ccccc6c6ccccc6c5c5ccccc45)c3)nc(-c3ccccc3)n2)cc1 ; c1ccc(-c2cccc(-c3cc(-c4cc(-c5ccc6oc7ccccc7c6c5)cc(-c5ccc6oc7ccccc7c6c5)c4)nc(-c4ccccc4)n3)c2)cc1 ; c1ccc(-c2nc(-c3ccccc3)nc(-c3ccc(N4c5ccccc5CCc5ccccc54)cc3)n2)cc1]

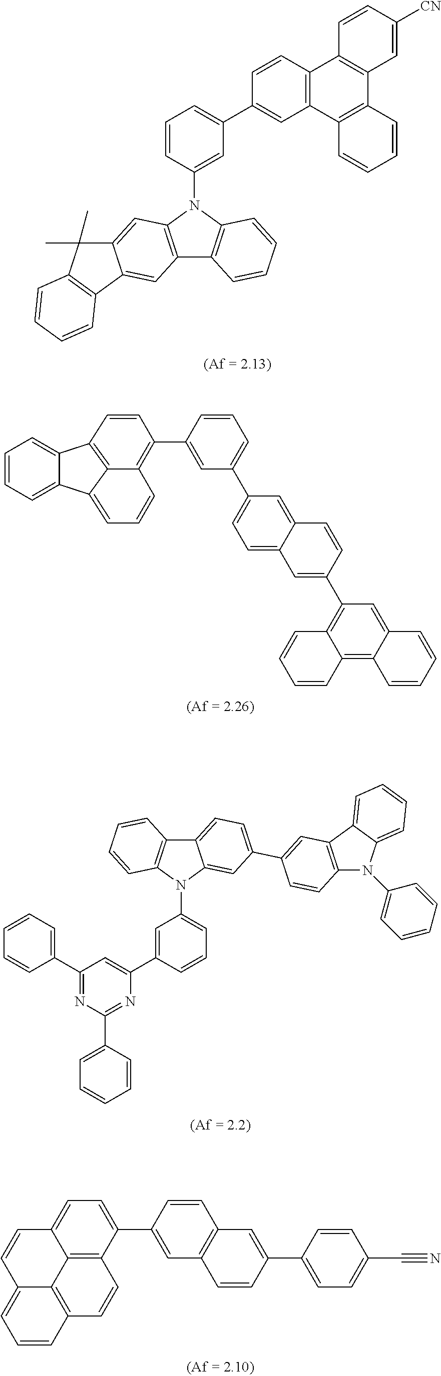

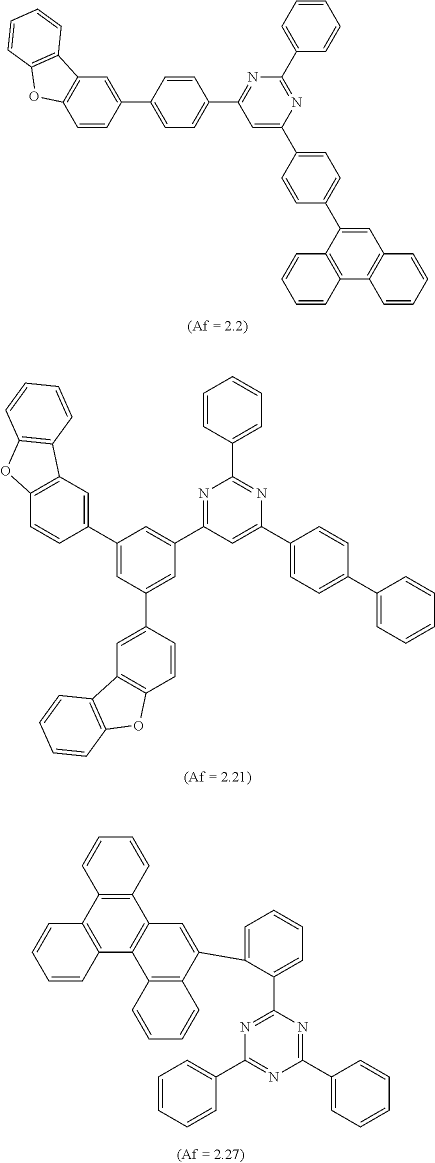 [SMILES: c1ccc(-c2nc(-c3ccc(-c4ccc5oc6ccccc6c5c4)cc3)cc(-c3ccc(-c4cc5ccccc5c5ccccc45)cc3)n2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1 ; c1ccc(-c2nc(-c3ccccc3)nc(-c3ccccc3-c3cc4c5ccccc5c5ccccc5c4c4ccccc34)n2)cc1]

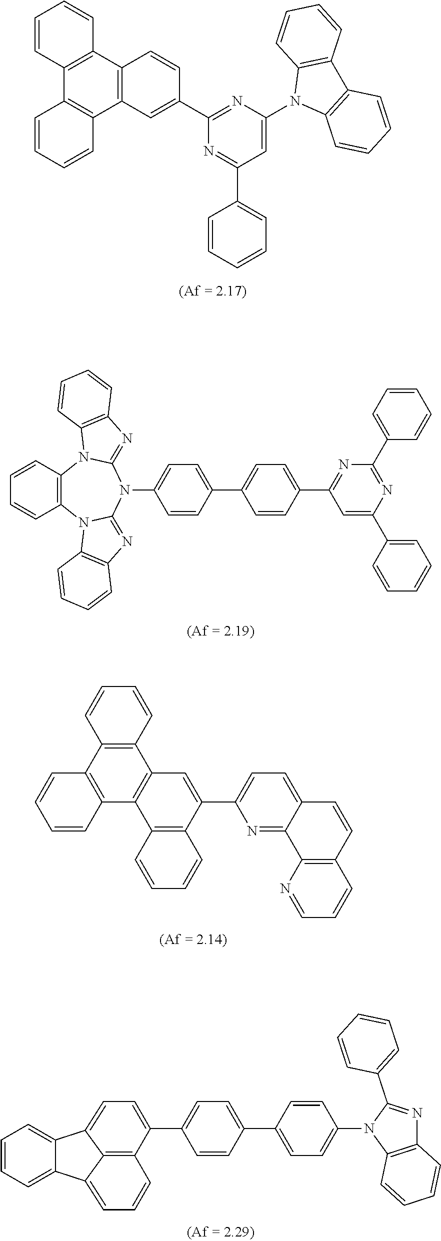 [SMILES: c1ccc(-c2cc(-n3c4ccccc4c4ccccc43)nc(-c3ccc4c5ccccc5c5ccccc5c4c3)n2)cc1 ; c1ccc(-c2cc(-c3ccc(-c4ccc(-n5c6nc7ccccc7n6c6ccccc6n6c7ccccc7nc56)cc4)cc3)nc(-c3ccccc3)n2)cc1 ; c1cnc2c(c1)ccc1ccc(-c3cc4c5ccccc5c5ccccc5c4c4ccccc34)nc12 ; c1ccc(-c2nc3ccccc3n2-c2ccc(-c3ccc(-c4ccc5c6c(cccc46)-c4ccccc4-5)cc3)cc2)cc1]

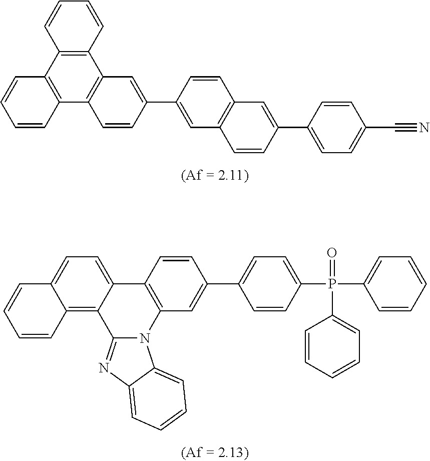 [SMILES: N#Cc1ccc(-c2ccc3cc(-c4ccc5c6ccccc6c6ccccc6c5c4)ccc3c2)cc1 ; O=P(c1ccccc1)(c1ccccc1)c1ccc(-c2ccc3c4ccc5ccccc5c4c4nc5ccccc5n4c3c2)cc1]

In one embodiment, the second compound is one or more selected from the group consisting of a compound represented by the following formula (200), a compound represented by the following formula (300), a compound represented by the following formula (400), a compound represented by the following formula (500), and a phosphine oxide compound.

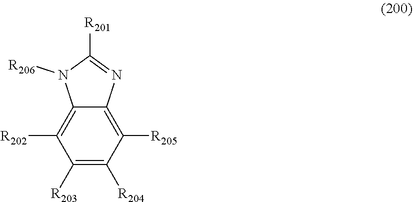

wherein in the formula (200),

one or more sets of the adjacent two or more of R₂₀₁ to R₂₀₆ form a substituted or unsubstituted, saturated or unsaturated ring by bonding with each other, or do not form the substituted or unsubstituted, saturated or unsaturated ring;

R₂₀₁ to R₂₀₆ which do not form the substituted or unsubstituted, saturated or unsaturated ring are independently

a hydrogen atom, or
a substituent R;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituents R are present, the two or more of the substituents R may be the same as or different from each other;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁₁ to R₉₀₇ are present, the two or more of each of R₉₀₁ to R₉₀₇ may be the same as or different from each other;

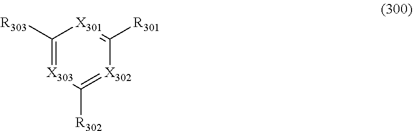

wherein in the formula (300),

X₃₀₁ to X₃₀₃ are independently CR₃₀₄ or N, wherein R₃₀₄ is a hydrogen atom or a substituent R; at least one of X₃₀₁ to X₃₀₃ is N; when two or more R₃₀₄'s are present, the two or more R₃₀₄'s may be the same as or different from each other;

R₃₀₁ to R₃₀₃ are independently

a hydrogen atom, or
a substituent R;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituents R are present, the two or more of the substituents R may be the same as or different from each other;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other;

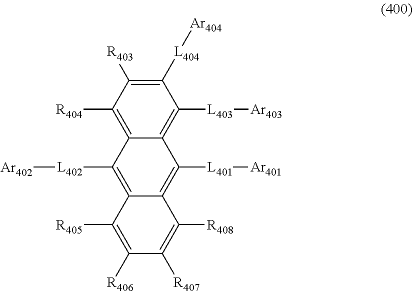

wherein in the formula (400),

one or more sets of the adjacent two or more of R₄₀₃ to R₄₀₈ form a substituted or unsubstituted, saturated or unsaturated ring by bonding with each other, or do not form the substituted or unsubstituted, saturated or unsaturated ring;

R₄₀₃ to R₄₀₈ which do not form the substituted or unsubstituted, saturated or unsaturated ring are independently

a hydrogen atom, or
a substituent R;

L₄₀₁ to L₄₀₄ are independently

a single bond,
a substituted or unsubstituted arylene group including 6 to 50 ring carbon atoms, or
a substituted or unsubstituted divalent heterocyclic group including 5 to 50 ring atoms;

Ar₄₀₁ to Ar₄₀₄ are independently

a hydrogen atom,
a substituted or unsubstituted aryl group including 6 to 50 ring carbon atoms, or
a substituted or unsubstituted monovalent heterocyclic group including 5 to 50 ring atoms;

at least one of Ar₄₀₁ to Ar₄₀₄ is a substituted or unsubstituted monovalent heterocyclic group including 5 to 50 ring atoms, and at least one of the monovalent heterocyclic group of Ar₄₀₁ to Ar₄₀₄ is a monovalent nitrogen-containing heterocyclic group;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituents R are present, the two or more of the substituents R may be the same as or different from each other;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other;

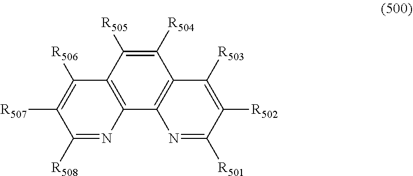

wherein in the formula (500),

one or more sets of the adjacent two or more of R₅₀₁ to R₅₀₈ form a substituted or unsubstituted, saturated or unsaturated ring by bonding with each other, or do not form the substituted or unsubstituted, saturated or unsaturated ring;

R₅₀₁ to R₅₀₈ which do not form the substituted or unsubstituted, saturated or unsaturated ring are independently

a hydrogen atom, or
a substituent R;

the substituent R is

a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),

### —O—(R₉₀₄),

### —S—(R₉₀₅),

—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;

when two or more of the substituents R are present, the two or more of the substituents R may be the same as or different from each other;

R₉₀₁ to R₉₀₇ are independently

a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and

when two or more of each of R₉₀₁ to R₉₀₇ are present, the two or more of each of R₉₀₁ to R₉₀₇ may be the same as or different from each other.

In one embodiment, the second compound is a compound represented by the following formula (201) and formula (202):

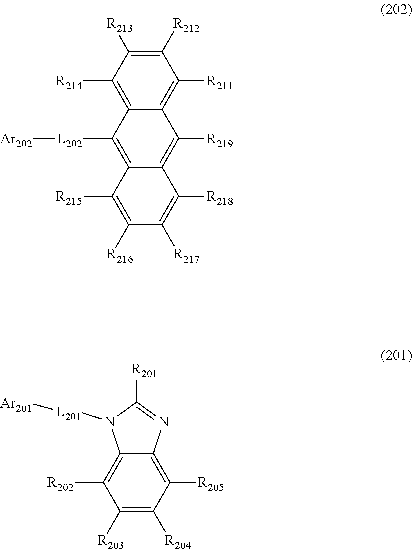

wherein in the formula (201),

R₂₀₁ to R₂₀₅ are as defined in the formula (200);

L₂₀₁ is

a single bond,
a substituted or unsubstituted arylene group including 6 to 50 ring carbon atoms, or
a substituted or unsubstituted divalent heterocyclic group including 5 to 50 ring atoms; and

Ar₂₀₁ is a group represented by the formula (202);

wherein in the formula (202),

one of R₂₁₁ to R₂₁₉ is a single bond bonding with L₂₀₁;

one or more sets of adjacent two or more of R₂₁₁ to R₂₁₉ which are not single bonds bonding with L₂₀₁ form a substituted or unsubstituted, saturated or unsaturated ring by bonding with each other, or do not form the substituted or unsubstituted, saturated or unsaturated ring;

R₂₁₁ to R₂₁₉ which are not a single bond bonding with L₁ and do not form the substituted or unsubstituted, saturated or unsaturated ring are independently

a hydrogen atom, or
a substituent R;

L₂₀₂ are independently

a single bond,
a substituted or unsubstituted arylene group including 6 to 50 ring carbon atoms, or
a substituted or unsubstituted divalent heterocyclic group including 5 to 50 ring atoms;

Ar₂₀₂ are independently

a substituted or unsubstituted aryl group including 6 to 50 ring carbon atoms, or
a substituted or unsubstituted monovalent heterocyclic group including 5 to 50 ring atoms; and

the substituent R is as defined in the formula (200).

In one embodiment, the second compound is a compound represented by the following formula (211):

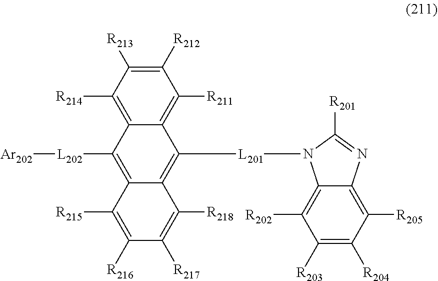

wherein in the formula (211), R₂₀₁ to R₂₀₅ are as defined in the formula (200); L₂₀₁ is as defined in the formula (201); and R₂₁₁ to R₂₁₈, L₂₀₂ and Ar₂₀₂ are as defined in the formula (202).

In one embodiment, the second compound is a compound represented by the following formula (301):

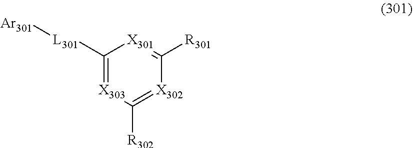

wherein in the formula (301),

X₃₀₁ to X₃₀₃, R₃₀₁ and R₃₀₂ are as defined in the formula (300);

L₃₀₁ is

a single bond,
a substituted or unsubstituted arylene group including 6 to 50 ring carbon atoms, or
a substituted or unsubstituted divalent heterocyclic group including 5 to 50 ring atoms; and

Ar₃₀₁ is

a substituted or unsubstituted aryl group including 6 to 50 ring carbon atoms, or
a substituted or unsubstituted monovalent heterocyclic group including 5 to 50 ring atoms.

In one embodiment, the second compound is a compound represented by the following formula (311) and formula (312):

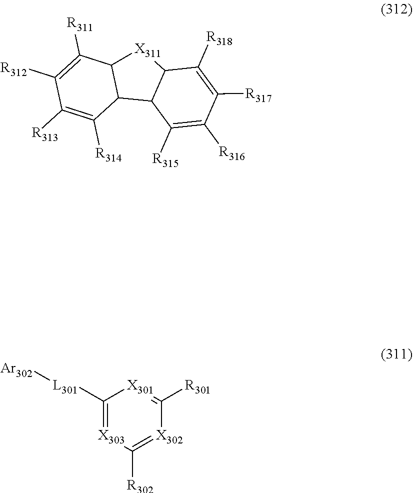

wherein in the formula (311),

X₃₀₁ to X₃₀₃, R₃₀₁ and R₃₀₂ are as defined in the formula (300);

L₃₀₁ is as defined in the formula (301); and

Ar₃₀₂ is a group represented by the formula (312);

wherein in the formula (312),

X₃₁₁ is O, S, N(R₃₂₁), or C(R₃₂₂)(R₃₂₃);

one of R₃₁₁ to R₃₁₈ and R₃₂₁ to R₃₂₃ is a single bond bonding with L₃₀₁;

one or more sets of adjacent two or more of R₃₁₁ to R₃₁₈ which are not single bonds bonding with L₃₀₁ form a substituted or unsubstituted, saturated or unsaturated ring by bonding with each other, or do not form the substituted or unsubstituted, saturated or unsaturated ring;

R₃₁₁ to R₃₁₈ which are not single bonds bonding with L₃₀₁ and which do not form the substituted or unsubstituted, saturated or unsaturated ring, and R₃₂₁ to R₃₂₃ which are not single bonds bonding with L₃₀₁ are independently

a hydrogen atom, or
a substituent R; and

the substituent R is as defined in the formula (300).

In one embodiment, the second compound is a compound represented by the following formula (401):

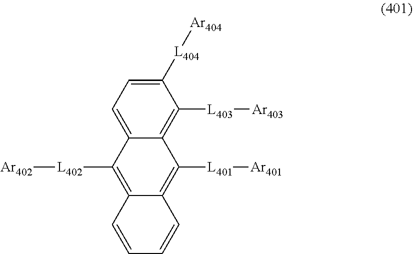

wherein in the formula (401), L₄₀₁ to L₄₀₄ and Ar₄₀₁ to Ar₄₀₄ are as defined in the formula (400).

In one embodiment, the second compound is a compound represented by the following formula (402):

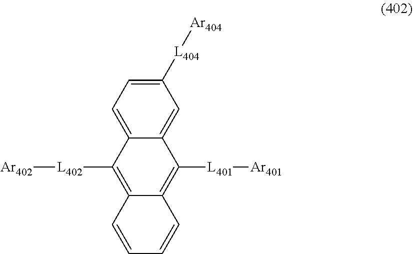

wherein in the formula (402), L₄₀₁, L₄₀₂, L₄₀₄, Ar₄₀₁, Ar₄₀₂ and Ar₄₀₄ are as defined in the formula (400).

In one embodiment, the second compound is a compound represented by the following formula (501):

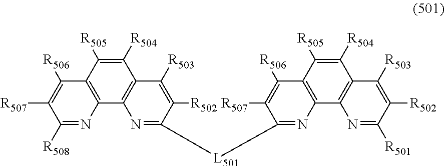

wherein in the formula (501),

R₅₀₁ to R₅₀₈ are as defined in the formula (500);

L₅₀₁ is

a single bond,
a substituted or unsubstituted arylene group including 6 to 50 ring carbon atoms, or
a substituted or unsubstituted divalent heterocyclic group including 5 to 50 ring atoms; and

each of the two R₅₀₂ to the two R₅₀₇ may be the same as or different from each other.

In one embodiment, the second compound is a compound represented by the following formula (502):

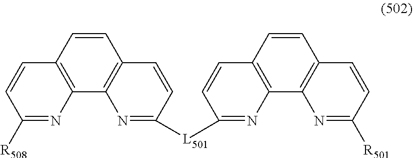

wherein in the formula (502), R₅₀₁ and R₅₀₈ are as defined in the formula (500); and L₅₀₁ is as defined in the formula (501).

In one embodiment, the second compound is a compound represented by the following formula (600):

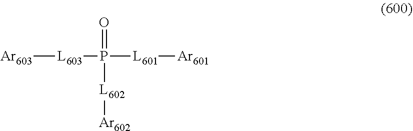

wherein in the formula (600),

L₆₀₁ to L₆₀₃ are independently

a single bond,
a substituted or unsubstituted arylene group including 6 to 50 ring carbon atoms, or
a substituted or unsubstituted divalent heterocyclic group including 5 to 50 ring atoms;

Ar₆₀₁ to Ar₆₀₃ are independently

a substituted or unsubstituted aryl group including 6 to 50 ring carbon atoms, or
a substituted or unsubstituted monovalent heterocyclic group including 5 to 50 ring atoms.

In one embodiment, the second compound is a compound represented by the following formula (601):

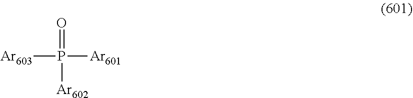

wherein in the formula (601), Ar₆₀₁ to Ar₆₀₃ are as defined in the formula (600).

The second compound can be synthesized by using known alternative reactions or raw materials tailored to the target product.

Specific examples of the second compound will be described below, but these are merely illustrative, and the second compound is not limited to the following specific examples.

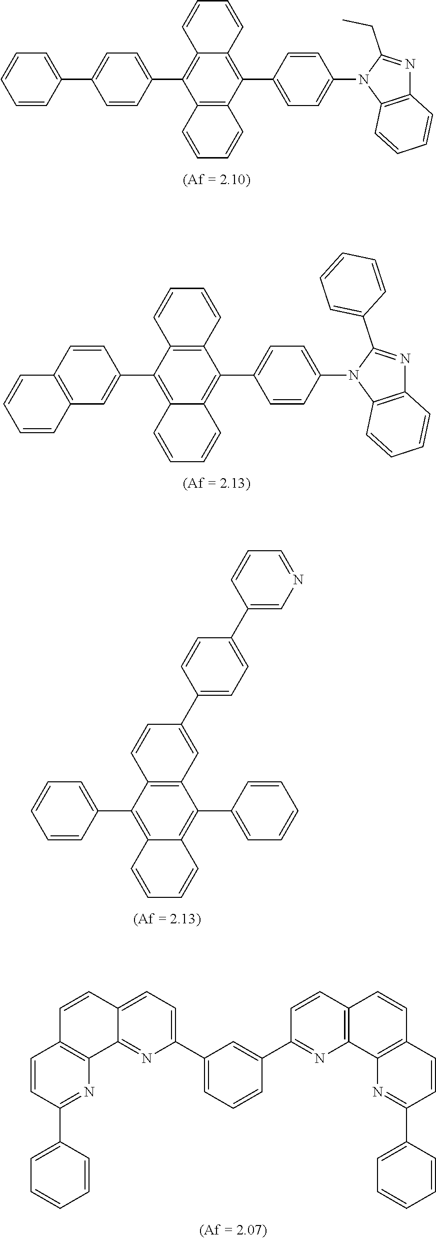 [SMILES: CCc1nc2ccccc2n1-c1ccc(-c2c3ccccc3c(-c3ccc(-c4ccccc4)cc3)c3ccccc23)cc1 ; c1ccc(-c2nc3ccccc3n2-c2ccc(-c3c4ccccc4c(-c4ccc5ccccc5c4)c4ccccc34)cc2)cc1 ; c1ccc(-c2c3ccccc3c(-c3ccccc3)c3cc(-c4ccc(-c5cccnc5)cc4)ccc23)cc1 ; c1ccc(-c2ccc3ccc4ccc(-c5cccc(-c6ccc7ccc8ccc(-c9ccccc9)nc8c7n6)c5)nc4c3n2)cc1]

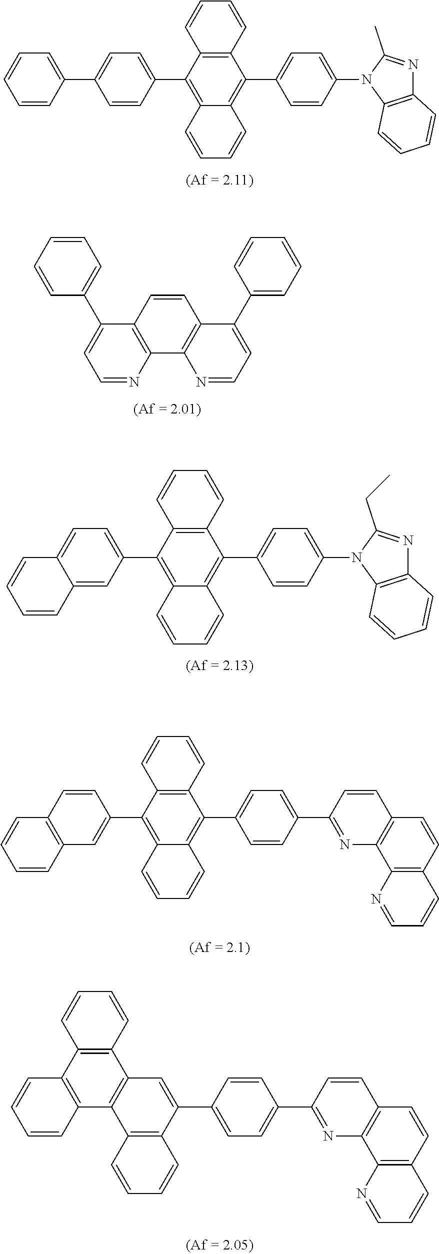 [SMILES: Cc1nc2ccccc2n1-c1ccc(-c2c3ccccc3c(-c3ccc(-c4ccccc4)cc3)c3ccccc23)cc1 ; c1ccc(-c2ccnc3c2ccc2c(-c4ccccc4)ccnc23)cc1 ; CCc1nc2ccccc2n1-c1ccc(-c2c3ccccc3c(-c3ccc4ccccc4c3)c3ccccc23)cc1 ; c1ccc2cc(-c3c4ccccc4c(-c4ccc(-c5ccc6ccc7cccnc7c6n5)cc4)c4ccccc34)ccc2c1 ; c1cnc2c(c1)ccc1ccc(-c3ccc(-c4cc5c6ccccc6c6ccccc6c5c5ccccc45)cc3)nc12]

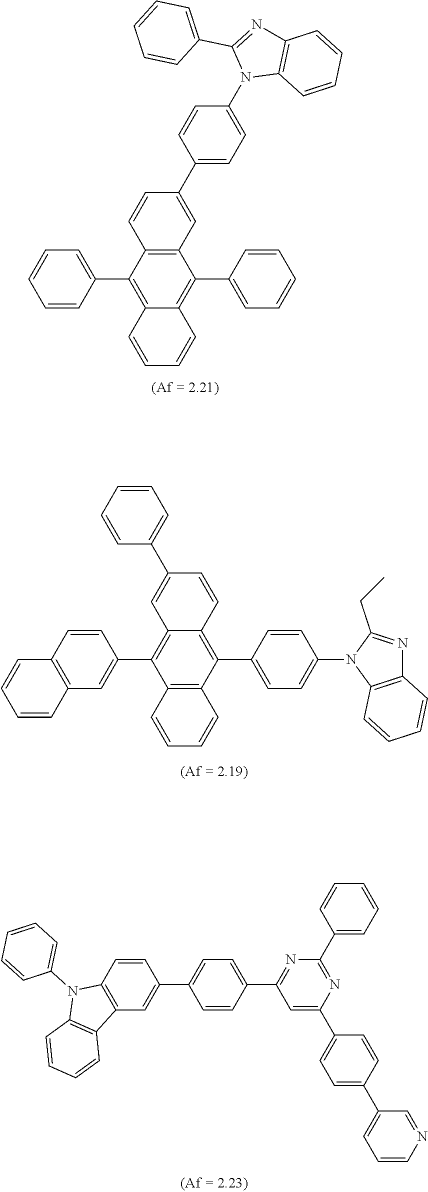 [SMILES: c1ccc(-c2c3ccccc3c(-c3ccccc3)c3cc(-c4ccc(-n5c(-c6ccccc6)nc6ccccc65)cc4)ccc23)cc1 ; CCc1nc2ccccc2n1-c1ccc(-c2c3ccccc3c(-c3ccc4ccccc4c3)c3cc(-c4ccccc4)ccc23)cc1 ; c1ccc(-c2nc(-c3ccc(-c4cccnc4)cc3)cc(-c3ccc(-c4ccc5c(c4)c4ccccc4n5-c4ccccc4)cc3)n2)cc1]

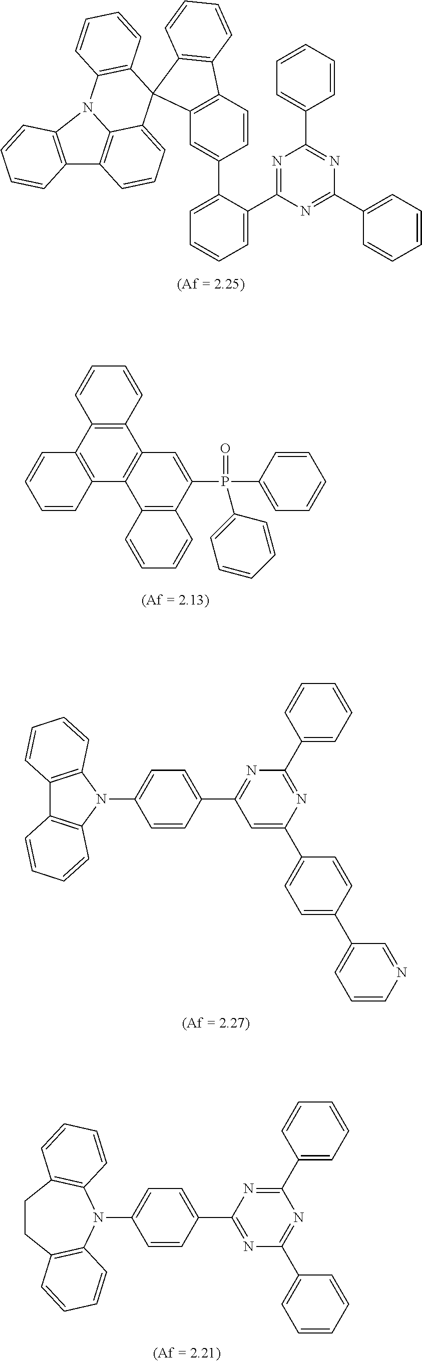 [SMILES: c1ccc(-c2nc(-c3ccccc3)nc(-c3ccccc3-c3ccc4c(c3)C3(c5ccccc5-4)c4ccccc4-n4c5ccccc5c5cccc3c54)n2)cc1 ; O=P(c1ccccc1)(c1ccccc1)c1cc2c3ccccc3c3ccccc3c2c2ccccc12 ; c1ccc(-c2nc(-c3ccc(-c4cccnc4)cc3)cc(-c3ccc(-n4c5ccccc5c5ccccc54)cc3)n2)cc1 ; c1ccc(-c2nc(-c3ccccc3)nc(-c3ccc(N4c5ccccc5CCc5ccccc54)cc3)n2)cc1]

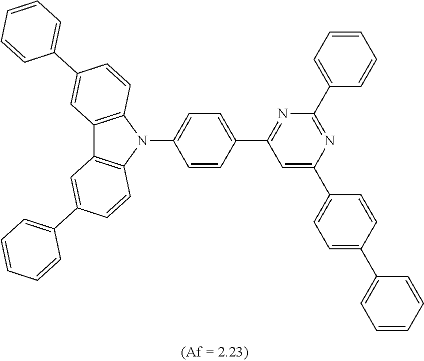 [SMILES: c1ccc(-c2ccc(-c3cc(-c4ccc(-n5c6ccc(-c7ccccc7)cc6c6cc(-c7ccccc7)ccc65)cc4)nc(-c4ccccc4)n3)cc2)cc1]

In one embodiment, a hole-transporting layer is provided between the anode and the emitting layer containing the host material.

In one embodiment, a hole-injecting layer is provided between the anode and the hole-transporting layer.

In an aspect of the organic EL device of the present invention, conventionally known materials and device configurations can be applied as long as the effect of the present invention is not impaired.

Parts which can be used in an aspect of the organic EL device of the present invention, materials for forming respective layers other than the above compounds, and the like, will be described below.

### (Substrate)

A substrate is used as a support of an emitting device. As the substrate, glass, quartz, plastic or the like can be used, for example. Further, a flexible substrate may be used. The “flexible substrate” means a bendable (flexible) substrate, and specific examples thereof include a plastic substrate formed of polycarbonate, polyvinyl chloride, or the like.

### (Anode)

For the anode formed on the substrate, metals, alloys, electrically conductive compounds, mixtures thereof, and the like, which have a large work function (specifically 4.0 eV or more) are preferably used. Specific examples thereof include indium oxide-tin oxide (ITO: Indium Tin Oxide), indium oxide-zinc oxide, indium oxide-tin oxide containing silicon or silicon oxide, indium oxide containing zinc oxide, tungsten oxide, graphene, and the like. In addition thereto, specific examples thereof include gold (Au), platinum (Pt), a nitride of a metallic material (for example, titanium nitride), and the like.

### (Hole-Injecting Layer)

The hole-injecting layer is a layer containing a substance having a high hole-injecting property. As such a substance having high hole-injecting property molybdenum oxide, titanium oxide, vanadium oxide, rhenium oxide, ruthenium oxide, chromium oxide, zirconium oxide, hafnium oxide, tantalum oxide, silver oxide, tungsten oxide, manganese oxide, an aromatic amine compound, a compound having an electron-withdrawing property (acceptor property), or a polymer compound (oligomers, dendrimers, polymers, etc.) can be given.

### (Hole-Transporting Layer)

The hole-transporting layer is a layer containing a substance having a high hole-transporting property. For the hole-transporting layer, an aromatic amine compound, a carbazole derivative, an anthracene derivative, or the like can be used. A polymer compound such as poly(N-vinylcarbazole) (abbreviation: PVK) and poly(4-vinyltriphenylamine) (abbreviation: PVTPA) can also be used. However, a substance other than the above-described substances may be used as long as the substance has a higher hole-transporting property in comparison with an electron-transporting property. It should be noted that the layer containing the substance having high hole-transporting property may be not only a single layer, but also a layer in which two or more layers formed of the above-described substances are stacked.

(Guest Material of Emitting Layer Containing the Host Material Described Above, and Guest Material of One or More Emitting Layers Other than the Emitting Layer Containing the Host Material Described Above)

The emitting layer is a layer containing a substance having a high emitting property, and can be formed by the use of various materials. For example, as the substance having a high emitting property, a fluorescent compound which emits fluorescence or a phosphorescent compound which emits phosphorescence can be used. The fluorescent compound is a compound which can emit from a singlet excited state, and the phosphorescent compound is a compound which can emit from a triplet excited state.

As a blue fluorescent emitting material which can be used for an emitting layer, pyrene derivatives, styrylamine derivatives, chrysene derivatives, fluoranthene derivatives, fluorene derivatives, diamine derivatives, triarylamine derivatives, and the like can be used. As a green fluorescent emitting material which can be used for an emitting layer, aromatic amine derivatives and the like can be used. As a red fluorescent emitting material which can be used for an emitting layer, tetracene derivatives, diamine derivatives and the like can be used.

As a blue phosphorescent emitting material which can be used for an emitting layer, metal complexes such as iridium complexes, osmium complexes, platinum complexes and the like are used. As a green phosphorescent emitting material which can be used for an emitting layer, iridium complexes and the like are used. As a red phosphorescent emitting material which can be used for an emitting layer, metal complexes such as iridium complexes, platinum complexes, terbium complexes, europium complexes and the like are used.

(Host Material of One or More Emitting Layers Other than the Emitting Layer Containing the Host Material Described Above)

The emitting layer may have a constitution in which the substance having a high emitting property (guest material) is dispersed in another substance (host material). As a substance for dispersing the substance having a high emitting property, a variety of substances can be used, and it is preferable to use a substance having a higher lowest unoccupied orbital level (LUMO level) and a lower highest occupied orbital level (HOMO level) than the substance having a high emitting property.

As a substance (host material) for dispersing the substance having a high emitting property, 1) a metal complex such as an aluminum complex, a beryllium complex, or a zinc complex, 2) a heterocyclic compound such as an oxadiazole derivative, a benzimidazole derivative, or a phenanthroline derivative, 3) a fused aromatic compound such as a carbazole derivative, an anthracene derivative, a phenanthrene derivative, a pyrene derivative, or a chrysene derivative, and 3) an aromatic amine compound such as a triarylamine derivative or a fused polycyclic aromatic amine derivative are used.

### (Electron-Injecting Layer)

An electron-injecting layer is a layer which contains a substance having a high electron-injecting property. For the electron-injecting layer, a compound which can be used in the electron-transporting layer described above, lithium (Li), ytterbium (Yb), lithium fluoride (LiF), cesium fluoride (CsF), calcium fluoride (CaF₂), metal complex compounds such as 8-hydroxyquinolinolato-lithium (Liq), alkali metals such as lithium oxide (LiOₓ); alkaline earth metals or compounds thereof can be used.

### (Cathode)

For the cathode, metals, alloys, electrically conductive compounds, mixtures thereof, and the like having a small work function (specifically, 3.8 eV or lower) are preferably used. Specific examples of such cathode materials include elements belonging to Group 1 and Group 2 of the Periodic Table of the Elements, i.e., alkali metals such as lithium (Li) and cesium (Cs); alkaline earth metals such as magnesium (Mg), calcium (Ca) and strontium (Sr); alloys containing these metals (e.g., MgAg and AlLi); rare earth metals such as europium (Eu) and ytterbium (Yb); aluminum (Al); and alloys containing these metals.

### (Hole-Blocking Layer, Exciton-Blocking Layer)

In one embodiment, the first electron-transporting layer described above serves as a hole-blocking layer or an exciton-blocking layer.

In an aspect of the organic EL device of the invention, a method for forming each layer is not limited. A conventionally-known method for forming each layer according to a vacuum deposition process, a spin coating process or the like can be used. Each layer such as the emitting layer can be formed by a known method such as a vacuum deposition process, a molecular beam deposition process (MBE process), or an application process such as a dipping process, a spin coating process, a casting process, a bar coating process and a roll coating process, using a solution prepared by dissolving the material in a solvent.

In an aspect of an organic EL device of the invention, the thickness of each layer is not particularly limited, but generally, the thickness of each layer is preferably several nanometers to 1 micrometer in order to suppress defects such as pinholes, suppress applied voltages to be low, and to increase luminous efficiency.

In order to form the second electron-transporting layer described above, a composition containing the second compound described above and the third compound described above may be used.

In one embodiment, the composition described above is a powder consisting of the above-described composition.

In addition, in order to form the second electron-transporting layer described above, a powder containing the second compound described above and the third compound described above may be used.

In one embodiment, the composition described above is deposited from the same deposition source, or the powder described above is deposited from the same deposition source to form a second electron-transporting layer.

In one embodiment of the composition, the blending ratio of the second compound described above and the third compound described above is not particularly limited, and the blending ratio of the material may be appropriately determined depending on the effect desired for the composition.

In one embodiment of the powder, the blending ratio of the second compound described above and the third compound described above is not particularly limited, and the blending ratio of the material may be appropriately determined depending on the effect desired for the powder.

In one embodiment, the content ratio of the second compound described above to the sum of the second compound described above and the third compound described above is 50% by mass or more and 99% by mass or less, preferably 80% by mass or more and 99% by mass or less, and more preferably 90% by mass or more and 99% by mass or less.

The form of the composition described above is not particularly limited, and examples thereof include a solid, a powder, a solution, a film (layer), and the like. Examples of the film (layer) include an organic layer constituting an organic EL device (e.g., a second electron-transporting layer). When the composition is a solid or a powder, the composition may be molded into a pellet shape.

In one embodiment, as a method of forming the second electron-transporting layer, a method in which the second compound described above and the third compound described above are simultaneously vapor-deposited (co-deposited) from different vapor deposition sources to form a second electron-transporting layer, or a method in which the second compound described above and the third compound described above are mixed in advance and then deposited from the same vapor deposition source to form a second electron-transporting layer may be employed. Examples of one embodiment of the latter method include a method in which a powder according to one embodiment of the present invention described later is used and is deposited from the same vapor deposition source to form a second electron-transporting layer.

The latter method has the advantage that the fabricating apparatus and the fabricating process can be simplified.

In one embodiment of the powder, the second compound described above and the third compound described above may be contained in one particle, or may be a mixture of the particle which consists of the second compound described above and the particle which consists of the third compound.

The blending ratio of the second compound and the third compound described above is not particularly limited, and is as described above for the composition.

In the method for fabricating a powder described above, a conventionally known method can be employed. For example, the second compound described above and the third compound may be pulverized and mixed using a mortar or the like, or the second compound described above and the third compound may be placed in a container or the like, heated in a chemically inert environment, cooled to an ambient temperature, and the obtained mixture may be pulverized by a mixer or the like to obtain a powder.

### <Electronic Apparatus>

An aspect of an electronic apparatus according to the present invention comprises the above-described organic electroluminescence device.

Thus, both efficiency and lifetime can be achieved.

Examples of the electronic apparatus include display parts such as an organic EL panel module; display devices of television sets, mobile phones, smart phones, personal computers, and the like; and emitting devices of a lighting device and a vehicle lighting device.

### EXAMPLES

Next, the invention will be described in more detail by referring to Examples and Comparative Examples, but the invention is not limited in any way to the description of these Examples.

### <Compound>

Host materials used for fabricating the organic EL devices of Examples 1 to 5, Example 11, Comparative Examples 1 to 5, and Comparative Example 11 are shown below. “Af” indicates the affinity value of the compound.

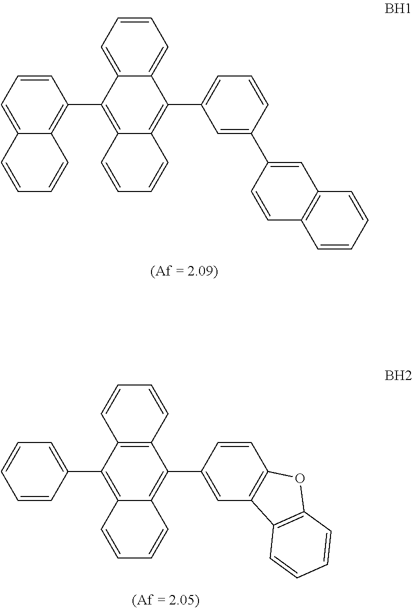

The compounds contained in the first electron-transporting layer and the compounds contained in the second electron-transporting layer used for fabricating the organic EL devices of Examples 1 to 5, Examples 11, Comparative Examples 1 to 5, and Comparative Example 11 are shown below. Liq is 8-hydroxyquinolinolato-lithium.

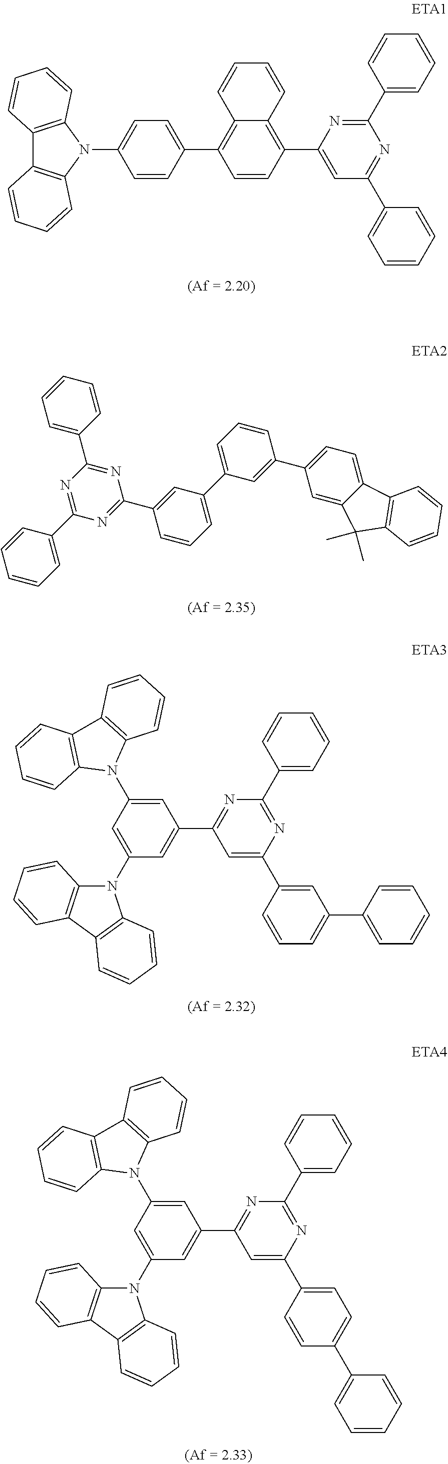 [SMILES: c1ccc(-c2cc(-c3ccc(-c4ccc(-n5c6ccccc6c6ccccc65)cc4)c4ccccc34)nc(-c3ccccc3)n2)cc1 ; CC1(C)c2ccccc2-c2ccc(-c3cccc(-c4cccc(-c5nc(-c6ccccc6)nc(-c6ccccc6)n5)c4)c3)cc21 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

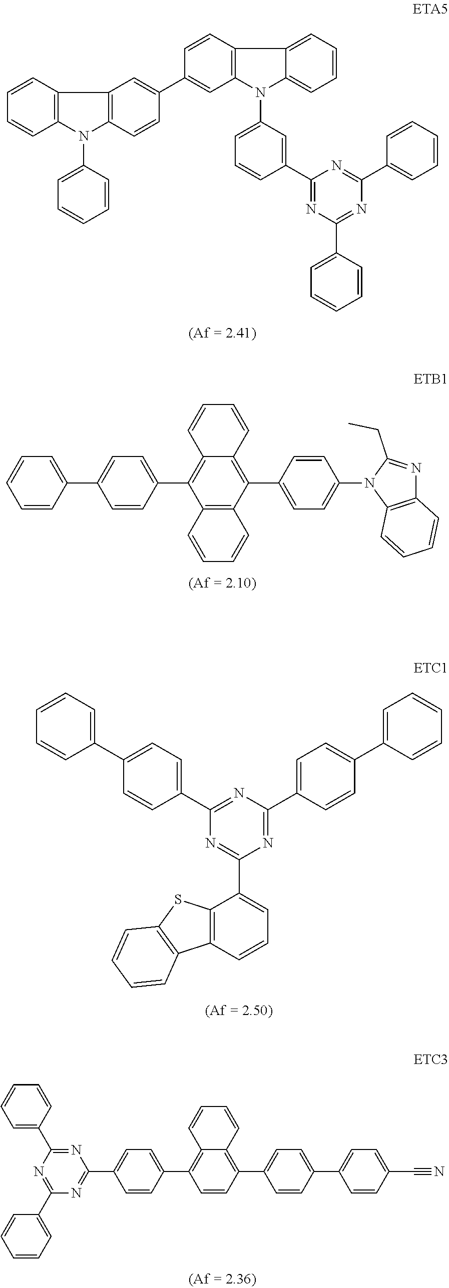 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; CCc1nc2ccccc2n1-c1ccc(-c2c3ccccc3c(-c3ccc(-c4ccccc4)cc3)c3ccccc23)cc1 ; c1ccc(-c2ccc(-c3nc(-c4ccc(-c5ccccc5)cc4)nc(-c4cccc5c4sc4ccccc45)n3)cc2)cc1 ; N#Cc1ccc(-c2ccc(-c3ccc(-c4ccc(-c5nc(-c6ccccc6)nc(-c6ccccc6)n5)cc4)c4ccccc34)cc2)cc1]

Other compounds used for fabricating the organic EL devices of Examples 1 to 5, Example 11, Comparative Examples 1 to 5, and Comparative Example 11 are shown below.

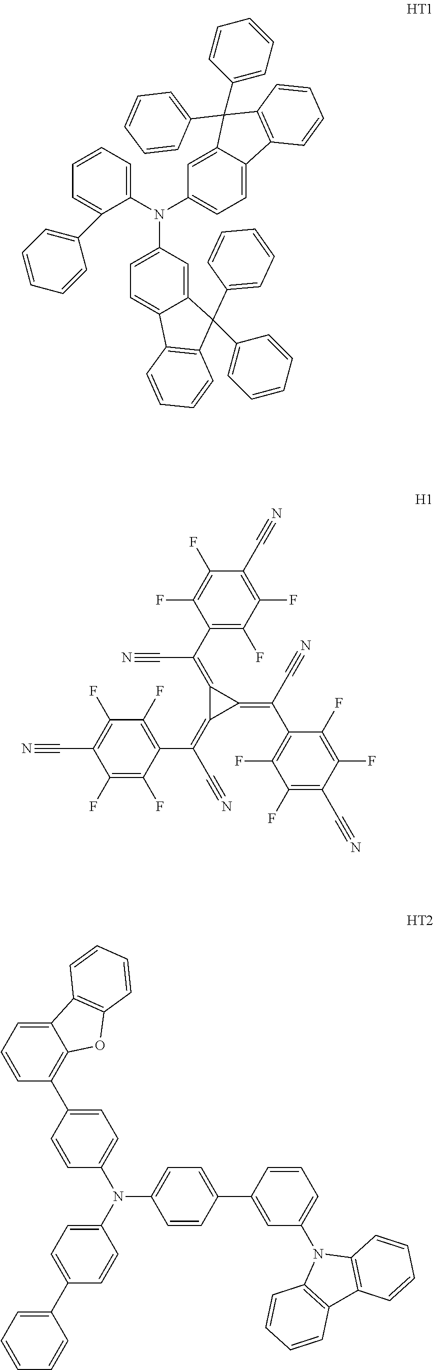 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

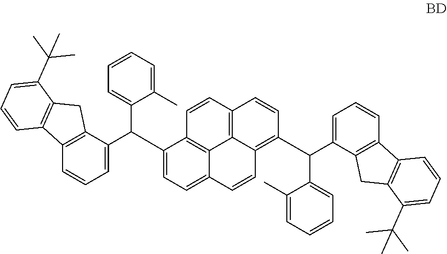 [SMILES: Cc1ccccc1C(c1cccc2c1Cc1c-2cccc1C(C)(C)C)c1ccc2ccc3c(C(c4ccccc4C)c4cccc5c4Cc4c-5cccc4C(C)(C)C)ccc4ccc1c2c43]

### <Measurement of Affinity Values>

For the compounds described above, the affinity values were determined as follows.

Affinity Af was calculated by the following formula and the formulas described later:

Af=−1.19×(Ere−Efc)−4.78 eV

wherein in the formula,

Ere: first reduction potential (DPV, Negative scan)

Efc: the first oxidation potential of ferrocene (DPV, Positive scan), (ca. +0.55 V vs Ag/AgCl).

The redox potential was measured by a differential pulse voltammetry (DPV) method using an electrochemical analyzer (manufactured byALS Co., Ltd: CHI630B).

N,N-dimethylformamide (DMF) was used as the solvent, and the sample concentration was set to 1.0 mmol/L. Tetrabuthylammmonium hexafluorophosphate (TBHP) (100 mmol/L) was used as the supporting electrolyte. Glassy carbon, Pt were used as the working electrode and the counter electrode, respectively.
(Reference document) M. E. Thompson, et. al., Organic Electronics, 6 (2005), p. 11-20, and Organic Electronics, 10 (2009), p. 515-520.

The values that could not be measured under the above conditions are indicated with

### <Fabrication of Organic EL Device>

An organic EL device was fabricated and evaluated as follows.

### Example 1

A25 mm×75 mm×1.1 mm-thick glass substrate with an ITO (Indium Tin Oxide) transparent electrode (anode) (manufactured by GEOMATEC Co., Ltd.) was subjected to ultrasonic cleaning in isopropyl alcohol for 5 minutes, and then subjected to UV-ozone cleaning for 30 minutes. The thickness of the ITO film was 130 nm.

The glass substrate with the transparent electrode after being cleaned was mounted onto a substrate holder in a vacuum vapor deposition apparatus. First, compound HT1 and compound HI were co-deposited on a surface on the side on which the transparent electrode was formed so as to cover the transparent electrode to form a hole-injecting layer having a thickness of 10 nm. The mass ratio of compound HT1 and compound HI was 97:3.

Next, compound HT1 was deposited on the hole-injecting layer to form a second hole-transporting layer having a film thickness of 80 nm.

Compound HT2 was deposited on this second hole-transporting layer to form a first hole-transporting layer having a film thickness of 10 nm.

Next, compound BH1 (host material) and compound BD (dopant material) were co-deposited on this first hole-transporting layer to form an emitting layer having a film thickness of 25 nm. The mass ratio of compound BH1 and compound BD was 96:4.

On this emitting layer, compound ETA1 was deposited to form a first electron-transporting layer having a film thickness of 10 nm.

On this first electron-transporting layer, compound ETB1 and compound ETC1 were co-deposited to form a second electron-transporting layer having a film thickness of 15 nm. The mass ratio of compound ETB1 and compound ETC1 was 91:9.

On this second electron-transporting layer, LiF was deposited to form an electron-injecting electrode having a film thickness of 1 nm.

Finally, metal Al was deposited on the electron-injecting electrode to form a metal cathode having a film thickness of 50 nm.

The layer configuration of the organic EL device of Example 1 is shown below. The numerical values in parentheses indicate the film thickness (nm), and the ratio indicates the mass ratio.

### ITO(130)/HT1:HI=97:3(10)/HT1(80)/

### HT2(10)/BH1:BD=96:4(25)/ETA1(10)/

### ETB1: ETC1=91:9(15)/LiF(1)/Al(50)

### <Evaluation of Organic EL Device>

### <Measurement of the Electronic Mobility of the Second Electron-Transporting Layer>

Impedance analyzer SI1260 (manufactured by TOYO Corporation) was used to measure the electronic mobility of the second electron-transporting layer.

The following single-carrier device was fabricated on Al substrate by deposition using the vacuum deposition apparatus described above. The numerical values in parentheses indicate the film thickness (nm).

Al/layer having the same composition as the second electron-transport layer described above(200)/ETB1(10)/LiF(1)/Al

The obtained single carrier device was measured complex modulus by applying a DC voltage with an AC voltage of 100 mV. When the frequency at which the imaginary part of the modulus is maximized is taken as fₘₐₓ (Hz), the response time T (sec) is calculated as T=½/π/fₘₐₓ, and this value is used to determine the electric field strength dependency of the mobility.

The mobility when the electric field strength is 500 (V/cm) was defined as μ. In addition, the result of the mobility μ is shown in Table 1.

### <Measurement of External Quantum Efficiency (EQE)>

The obtained organic EL device was driven with a DC constant current at a current density of 10 mA/cm² at room temperature. Luminance was measured using a luminance meter (CS-1000, manufactured by Minolta Co., Ltd.), from which the external quantum efficiency (%) was determined. The result is shown in Table 1.

<Measurement of 95% lifetime (LT95)>

The obtained organic EL device was driven with a DC constant current at a current density of 50 mA/cm², and the time until the luminance decreased to 95% of the initial luminance was measured, which was taken as 95% lifetime (LT95). The results are shown in Table 1.

### Examples 2 to 5 and Comparative Examples 1 to 5

Organic EL devices were fabricated and evaluated in the same manner as in Example 1, except that compounds shown in Table 1 below were used in % by mass shown in Table 1 below. The results are shown in Table 1.

### <Calculation of Coefficients for Compatibility Between External Quantum Efficiency and 95% Lifetime>

For Examples 1 to 5, the results of the external quantum efficiency were plotted on the vertical axis and the 95% lifetimes were plotted on the horizontal axis to obtain an approximate line A from the plot.

In addition, for Comparative Examples 1 to 5, the results of the external quantum efficiency were plotted on the vertical axis and the 95% lifetimes were plotted on the horizontal axis to obtain an approximate line B from the plot.

From the obtained approximate line A and the approximate line B, the intersection point was determined.

A difference between the external quantum efficiency of Example 1 and the value of the vertical axis of the above intersection point was determined. This difference was taken as the value C.

Further, a difference between the 95% lifetime of Example 1 and the value of the horizontal axis of the above intersection point was determined. This difference was taken as the value D.

The obtained value C was divided by the value D to calculate the value as a coefficient of compatibility between the external quantum efficiency and 95% lifetime. The result is shown in Table 1.

For Examples 2 to 5 and Comparative Examples 1 to 5, the value C and the value D were obtained in the same manner as Example 1 to calculate the coefficients of compatibility between the external quantum efficiency and 95% lifetime. The results are shown in Table 1.

### <Evaluation of Compatibility Between External Quantum Efficiency and 95% Lifetime>

For Examples 1 to 5 and Comparative Examples 1 to 5, the case when the obtained coefficients of compatibility between the external quantum efficiency and 95% lifetime were −5.00×10⁻³ or more was indicated as A. The case when the obtained coefficients were less than −5.00×10⁻³ and −8.00×10⁻³ or more was indicated as B. The case when the obtained coefficients were less than −8.00×10⁻³ and −1.00×10⁻² or more was indicated as C. The case when the obtained coefficients were less than −1.00×10⁻² was indicated as D. The results are shown in Table 1.

TABLE 1

| | Example 1 | Example 2 | Example 3 | Example 4 | Example 5 | Comp. Ex. 1 |
|---|---|---|---|---|---|---|
| Host material | BH1 | BH1 | BH1 | BH1 | BH1 | BH1 |
| Af of host material | 2.09 | 2.09 | 2.09 | 2.09 | 2.09 | 2.09 |
| First compound | ETA1 | ETA1 | ETA1 | ETA1 | ETA1 | ETA2 |
| Af of first compound | 2.20 | 2.20 | 2.20 | 2.20 | 2.20 | 2.35 |
| Second compound | ETB1 | ETB1 | ETB1 | ETB1 | ETB1 | ETB1 |
| Af of second compound | 2.10 | 2.10 | 2.10 | 2.10 | 2.10 | 2.10 |
| Third compound | ETC1 | ETA4 | ETA4 | ETA4 | ETC3 | — |
| Af of third compound | 2.50 | 2.33 | 2.33 | 2.33 | 2.36 | — |
| Content of third compound in | 9 | 9 | 12 | 15 | 9 | — |
| second electron−transporting | | | | | | |
| layer (% by mass) | | | | | | |
| Absolute value of difference | 0.11 | 0.11 | 0.11 | 0.11 | 0.11 | 0.26 |
| between Af of host material | | | | | | |
| and Af of first compound | | | | | | |
| Absolute value of difference | 0.10 | 0.10 | 0.10 | 0.10 | 0.10 | 0.25 |
| between Af of first compound | | | | | | |
| and Af of second compound | | | | | | |
| Value obtained by | 0.40 | 0.23 | 0.23 | 0.23 | 0.26 | — |
| subtracting Af of second | | | | | | |
| compound from Af of third | | | | | | |
| compound | | | | | | |
| Electronic mobility of second | 6.42 × 10⁻⁷ | 3.40 × 10⁻⁶ | 2.42 × 10⁻⁶ | 1.54 × 10⁻⁶ | 8.27 × 10⁻⁷ | 2.09 × 10⁻⁴ |
| electron−transporting layer | | | | | | |
| (cm²/Vs ) | | | | | | |
| External quantum efficiency | 9.92 | 10.1 | 10.0 | 9.83 | 10.0 | 9.52 |
| (%) | | | | | | |
| 95% lifetime (h) | 127.9 | 91.9 | 101.4 | 110.3 | 94.1 | 91.9 |
| Coefficient for compatibility | −3.69 × 10⁻³ | −1.39 × 10⁻³ | −4.28 × 10⁻³ | −7.67 × 10⁻³ | −5.65 × 10⁻³ | −2.96 × 10⁻² |
| between external quantum | | | | | | |
| efficiency and 95% lifetime | | | | | | |
| Compatibility between | A | A | A | B | B | D |
| external quantum efficiencyE | | | | | | |
| and 95% lifetime | | | | | | |

| | Comp. Ex. 2 | Comp. Ex. 3 | Comp. Ex. 4 | Comp.Ex. 5 |
|---|---|---|---|---|
| Host material | BH1 | BH1 | BH1 | BH1 |
| Af of host material | 2.09 | 2.09 | 2.09 | 2.09 |
| First compound | ETA3 | ETA4 | ETA5 | ETA1 |
| Af of first compound | 2.32 | 2.33 | 2.41 | 2.20 |
| Second compound | ETB1 | ETB1 | ETB1 | ETA5 |
| Af of second compound | 2.10 | 2.10 | 2.10 | 2.41 |
| Third compound | — | — | — | Liq |
| Af of third compound | — | — | — | — |
| Content of third compound in | — | — | — | 50 |
| second electron−transporting | | | | |
| layer (% by mass) | | | | |
| Absolute value of difference | 0.23 | 0.24 | 0.32 | 0.11 |
| between Af of host material | | | | |
| and Af of first compound | | | | |
| Absolute value of difference | 0.22 | 0.23 | 0.31 | 0.21 |
| between Af of first compound | | | | |
| and Af of second compound | | | | |
| Value obtained by | — | — | — | — |
| subtracting Af of second | | | | |
| compound from Af of third | | | | |
| compound | | | | |
| Electronic mobility of second | 2.09 × 10⁻⁴ | 2.09 × 10⁻⁴ | 2.09 × 10⁻⁴ | 3.29 × 10⁻⁶ |
| electron−transporting layer | | | | |
| (cm²/Vs ) | | | | |
| External quantum efficiency | 8.51 | 7.60 | 7.40 | 8.81 |
| (%) | | | | |
| 95% lifetime (h) | 151.4 | 195.5 | 196.2 | 152.9 |
| Coefficient for compatibility | −2.02 × 10⁻² | −2.03 × 10⁻² | −2.19 × 10⁻² | −1.62 × 10⁻² |
| between external quantum | | | | |
| efficiency and 95% lifetime | | | | |
| Compatibility between | D | D | D | D |
| external quantum efficiencyE | | | | |
| and 95% lifetime | | | | |

From the results shown in Table 1, it can be seen that the organic EL devices of Examples 1 to 5 in which the relationship between the affinity value of the host material, the affinity value of the first compound, and the affinity value of the second compound was set to have a specific relationship or the like exhibited a higher degree of compatibility between the external quantum efficiency and the 95% lifetime compared with the organic EL devices of Comparative Examples 1 to 5.

### Example 11 and Comparative Example 11

An organic EL device was fabricated in the same manner as in Example 1, except that the compounds shown in Table 2 below was used in % by mass shown in Table 2 below, and the electronic mobility of the second electron-transporting layer was measured to evaluate the external quantum efficiency and the 95% lifetime in the same manner as in Example 1. The results are shown in Table 1.

TABLE 2

| | Example 11 | Comp. Ex. 11 |
|---|---|---|
| Host material | BH2 | BH2 |
| Af of host material | 2.05 | 2.05 |
| First compound | ETA1 | ETA2 |
| Af of first compound | 2.20 | 2.35 |
| Second compound | ETB1 | ETB1 |
| Af of second compound | 2.10 | 2.10 |
| Third compound | ETC1 | — |
| Af of third compound | 2.50 | — |
| Content of third compound in | 12 | — |
| second electron-transporting | | |
| layer (% by mass) | | |
| Absolute value of difference | 0.15 | 0.30 |
| between Af of host material | | |
| and Af of first compound | | |
| Absolute value of difference | 0.10 | 0.25 |
| between Af of first compound | | |
| and Af of second compound | | |
| Value obtained by subtracting | 0.40 | — |
| Af of second compound from | | |
| Af of third compound | | |
| Electronic mobility of second | 5.56 × 10⁻⁷ | 2.09 × 10⁻⁴ |
| electron-transporting layer | | |
| (cm²/Vs) | | |
| External quantum efficiency | 8.75 | 8.47 |
| (% ) | | |
| 95% lifetime (h) | 158.2 | 99.4 |

From the results shown in Table 2, it can be seen that the organic EL device of Example 11 in which the relationship between the affinity value of the host material, the affinity value of the first compound, and the affinity value of the second compound was set to have a specific relationship or the like exhibited a higher external quantum efficiency and a higher 95% lifetime compared with the organic EL device of Comparative Example 11.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1. An organic electroluminescence device, comprising: an anode;
an emitting layer comprising a host material;
a first electron-transporting layer comprising a first compound;
a second electron-transporting layer comprising a second compound; and
a cathode
in this order, wherein
the absolute value of the difference between the affinity value of the host material and the affinity value of the first compound is 0.20 or less,
the absolute value of the difference between the affinity value of the first compound and the affinity value of the second compound is 0.20 or less,
the first compound and the second compound are different compounds, the electronic mobility of the second electron-transporting layer is less than 1.00×10⁻⁴ cm²/Vs, and
the second electron-transporting layer does not comprise Li, and the second electron-transporting layer does not comprise a quinolate complex of Li.

2. An organic electroluminescence device, comprising: an anode;
an emitting layer comprising a host material;
a first electron-transporting layer comprising a first compound;
a second electron-transporting layer comprising a second compound and a third compound,
a cathode
in this order, wherein
the absolute value of the difference between the affinity value of the host material and the affinity value of the first compound is 0.20 or less,
the absolute value of the difference between the affinity value of the first compound and the affinity value of the second compound is 0.20 or less,
the affinity value of the third compound is larger than the affinity value of the second compound,
the first compound and the second compound are different compounds,
the second compound and the third compound are different compounds, and
the second electron-transporting layer does not comprise Li, and the second electron-transporting layer does not comprise a quinolate complex of Li.

3. The organic electroluminescence device according to claim 2, wherein the electronic mobility of the second electron-transporting layer is less than 1.00×10⁻⁴ cm²/Vs.

4. The organic electroluminescence device according to claim 2, wherein the third compound is a compound represented by the following formula (800): 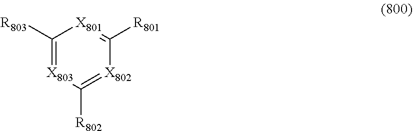
wherein in the formula (800),
X₈₀₁ to X₈₀₃ are independently CR₈₀₄ or N, wherein R₈₀₄ is a hydrogen atom or a substituent R; at least one of X₈₀₁ to X₈₀₃ is N; when two or more R₈₀₄'s are present, the two or more R₈₀₄'s may be the same as or different from each other;
R₈₀₁ to R₈₀₃ are independently
a hydrogen atom, or
a substituent R;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituents R are present, the two or more of the substituents R may be the same as or different from each other;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other.

5. The organic electroluminescence device according to claim 4, wherein the third compound is a compound represented by the following formula (801) and formula (802): 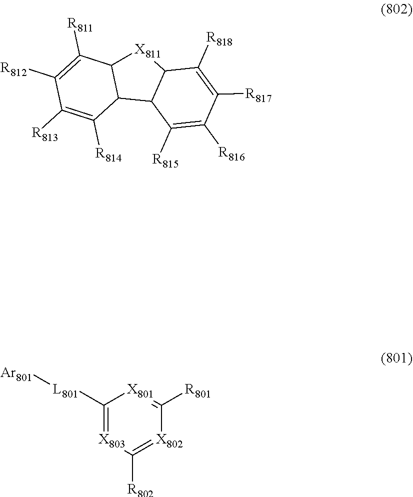
wherein in the formula (801),
X₈₀₁ to X₈₀₃, R₈₀₁ and R₈₀₂ are as defined in the formula (800);
L₈₀₁ is
a single bond,
a substituted or unsubstituted arylene group including 6 to 50 ring carbon atoms, or
a substituted or unsubstituted divalent heterocyclic group including 5 to 50 ring atoms;
Ar₈₀₁ is a group represented by the formula (802);
wherein in the formula (802),
X₈₁₁ is O, S, N(R₈₂₁), or C(R₈₂₂)(R₈₂₃);
one of R₈₁₁ to R₈₁₈ and R₈₂₁ to R₈₂₃ is a single bond bonding with L₈₀₁;
one or more sets of adjacent two or more of R₈₁₁ to R₈₁₈ which are not single bonds bonding with L₈₀₁ form a substituted or unsubstituted, saturated or unsaturated ring by bonding with each other, or do not form the substituted or unsubstituted, saturated or unsaturated ring;
R₈₁₁ to R₈₁₈ which are not single bonds bonding with L₈₀₁ and which do not form the substituted or unsubstituted, saturated or unsaturated ring, and R₈₂₁ to R₈₂₃ which are not single bonds bonding with L₈₀₁ are independently
a hydrogen atom, or
a substituent R; and
the substituent R is as defined in the formula (800).

6. The organic electroluminescence device according to claim 5, wherein the third compound is a compound represented by the following formula (811): 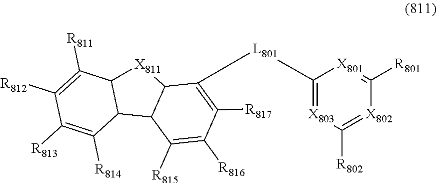
wherein in the formula (811), X₈₀₁ to X₈₀₃, R₈₀₁ and R₈₀₂ are as defined in the formula (800);
L₈₀₁ is as defined in the formula (801); and X₈₁₁ and R₈₁₁ to R₈₁₇ are as defined in the formula (802).

7. The organic electroluminescence device according to claim 1, further comprising one or more emitting layers other than the emitting layer comprising the host material between the anode and the emitting layer comprising the host material.

8. The organic electroluminescence device according to claim 1, wherein the host material is an anthracene derivative.

9. The organic electroluminescence device according to claim 1, wherein the host material is a compound represented by the following formula (100): 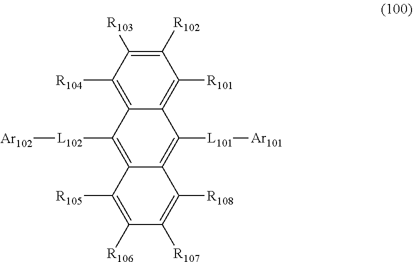
wherein in the formula (100),
one or more sets of the adjacent two or more of R₁₀₁ to R₁₀₈ form a substituted or unsubstituted, saturated or unsaturated ring by bonding with each other, or do not form the substituted or unsubstituted, saturated or unsaturated ring;
R₁₀₁ to R₁₀₈ which do not form the substituted or unsubstituted, saturated or unsaturated ring are independently
a hydrogen atom, or
a substituent R;
L₁₀₁ and L₁₀₂ are independently
a single bond,
a substituted or unsubstituted arylene group including 6 to 50 ring carbon atoms, or
a substituted or unsubstituted divalent heterocyclic group including 5 to 50 ring atoms;
Ar₁₀₁ and Ar₁₀₂ are independently
a substituted or unsubstituted aryl group including 6 to 50 ring carbon atoms, or
a substituted or unsubstituted monovalent heterocyclic group including 5 to 50 ring atoms;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituents R are present, the two or more of the substituents R may be the same as or different from each other;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other.

10. The organic electroluminescence device according to claim 9, wherein one or more of
hydrogen atoms possessed by the substituted or unsubstituted, saturated or unsaturated ring formed by bonding one or more sets of adjacent two or more of R₁₀₁ to R₁₀₈,
R₁₀₁ to R₁₀₈ which are hydrogen atoms,
hydrogen atoms possessed by R₁₀₁ to R₁₀₈ which are substituents R,
hydrogen atoms possessed by L₁₀₁,
hydrogen atoms possessed by L₁₀₂,
hydrogen atoms possessed by Ar₁₀₁, and
hydrogen atoms possessed by Ar₁₀₂
are deuterium atoms.

11. The organic electroluminescence device according to claim 9, wherein the host material is a compound represented by the following formula (101): 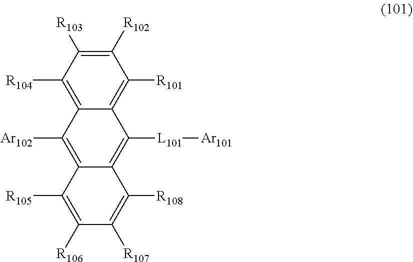
wherein in the formula (101), R₁₀₁ to R₁₀₈, L₁₀₁, Ar₁₀₁ and Ar₁₀₂ are as defined in the formula (100).

12. The organic electroluminescence device according to claim 9, wherein the host material is a compound represented by the following formula (102): 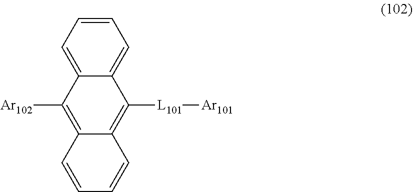
wherein in the formula (102), L₁₀₁, Ar₁₀₁ and Ar₁₀₂ are as defined in the formula (100).

13. The organic electroluminescence device according to claim 1, wherein the first compound is a compound represented by the following formula (1): 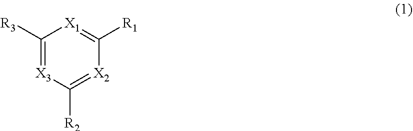
wherein in the formula (1),
X₁ to X₃ are independently CR₄ or N, wherein R₄ is a hydrogen atom or a substituent R; at least one of X₁ to X₃ is N; when two or more R₄'s are present, the two or more R₄'s may be the same as or different from each other;
R₁ to R₃ are independently
a hydrogen atom, or
a substituent R;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituents R are present, the two or more of the substituents R may be the same as or different from each other;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other.

14. The organic electroluminescence device according to claim 13, wherein the first compound is a compound represented by the following formula (11): 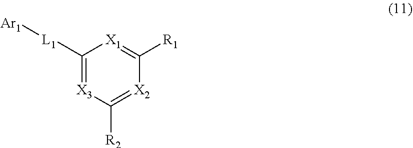
wherein in the formula (11),
X₁ to X₃, R₁ and R₂ are as defined in the formula (1);
L₁ is
a single bond,
a substituted or unsubstituted arylene group including 6 to 50 ring carbon atoms, or a substituted or unsubstituted divalent heterocyclic group including 5 to 50 ring atoms; and
Ar₁ is
a substituted or unsubstituted aryl group including 6 to 50 ring carbon atoms, or
a substituted or unsubstituted monovalent heterocyclic group including 5 to 50 ring atoms.

15. The organic electroluminescence device according to claim 14, wherein Ar₁ is a group represented by the following formula (12): 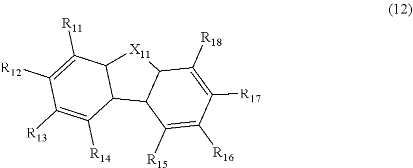
wherein in the formula (12),
X₁₁ is O, S, N(R₂₁), or C(R₂₂)(R₂₃);
one of R₁₁ to R₁₈ and R₂₁ to R₂₃ is a single bond bonding with Li;
one or more sets of adjacent two or more of R₁₁ to R₁₈ which are not single bonds bonding with L₁ form a substituted or unsubstituted, saturated or unsaturated ring by bonding with each other, or do not form the substituted or unsubstituted, saturated or unsaturated ring;
R₁₁ to R₁₈ which are not single bonds bonding with L₁ and which do not form the substituted or unsubstituted, saturated or unsaturated ring, and R₂₁ to R₂₃ which are not single bonds bonding with L₁ are independently
a hydrogen atom, or
a substituent R; and
the substituent R is as defined in the formula (1).

16. The organic electroluminescence device according to claim 15, wherein X₁₁ is N(R₂₁).

17. The organic electroluminescence device according to claim 15, wherein the first compound is a compound represented by the following formula (21): 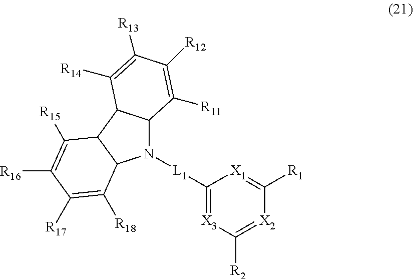
wherein in the formula (21),
X₁ to X₃, R₁ and R₂ are as defined in the formula (1);
L₁ is as defined in the formula (11); and
R₁₁ to R₁₈ are as defined in the formula (12).

18. The organic electroluminescence device according to claim 17, wherein L₁ is a single bond, or an unsubstituted arylene group including 6 to 50 ring carbon atoms;
the substituent R is
an unsubstituted alkyl group including 1 to 50 carbon atoms,
an unsubstituted alkenyl group including 2 to 50 carbon atoms,
an unsubstituted alkynyl group including 2 to 50 carbon atoms,
an unsubstituted cycloalkyl group including 3 to 50 ring carbon atoms,
—Si(R₉₁₁)(R₉₁₂)(R₉₁₃),
—O—(R₉₁₄),
—S—(R₉₁₅),
—N(R₉₁₆)(R₉₁₇),
a halogen atom, a cyano group, a nitro group, or
an unsubstituted aryl group including 6 to 50 ring carbon atoms, and
R₉₁₁ to R₉₁₇ are independently
a hydrogen atom,
an unsubstituted alkyl group including 1 to 50 carbon atoms,
an unsubstituted cycloalkyl group including 3 to 50 ring carbon atoms, or
an unsubstituted aryl group including 6 to 50 ring carbon atoms.

19. The organic electroluminescence device according to claim 13, wherein two of X₁ to X₃ are N.

20. The organic electroluminescence device according to claim 1, wherein the second compound is one or more selected from the group consisting of a compound represented by the following formula (200), a compound represented by the following formula (300), a compound represented by the following formula (400), a compound represented by the following formula (500), and a phosphine oxide compound: 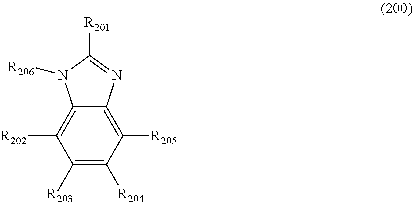
wherein in the formula (200),
one or more sets of the adjacent two or more of R₂₀₁ to R₂₀₆ form a substituted or unsubstituted, saturated or unsaturated ring by bonding with each other, or do not form the substituted or unsubstituted, saturated or unsaturated ring;
R₂₀₁ to R₂₀₆ which do not form the substituted or unsubstituted, saturated or unsaturated ring are independently
a hydrogen atom, or
a substituent R;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituents R are present, the two or more of the substituents R may be the same as or different from each other;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other; 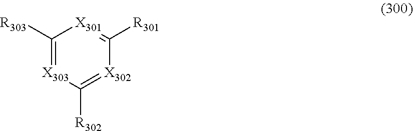
wherein in the formula (300),
X₃₀₁ to X₃₀₃ are independently CR₃₀₄ or N, wherein R₃₀₄ is a hydrogen atom or a substituent R; at least one of X₃₀₁ to X₃₀₃ is N; when two or more R₃₀₄'s are present, the two or more R₃₀₄'s may be the same as or different from each other;
R₃₀₁ to R₃₀₃ are independently
a hydrogen atom, or
a substituent R;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituents R are present, the two or more of the substituents R may be the same as or different from each other;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other; 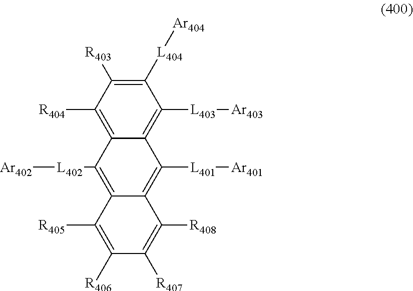
wherein in the formula (400),
one or more sets of the adjacent two or more of R₄₀₃ to R₄₀₈ form a substituted or unsubstituted, saturated or unsaturated ring by bonding with each other, or do not form the substituted or unsubstituted, saturated or unsaturated ring;
R₄₀₃ to R₄₀₈ which do not form the substituted or unsubstituted, saturated or unsaturated ring are independently
a hydrogen atom, or
a substituent R;
L₄₀₁ to L₄₀₄ are independently
a single bond,
a substituted or unsubstituted arylene group including 6 to 50 ring carbon atoms, or
a substituted or unsubstituted divalent heterocyclic group including 5 to 50 ring atoms;
Ar₄₀₁ to Ar₄₀₄ are independently
a hydrogen atom,
a substituted or unsubstituted aryl group including 6 to 50 ring carbon atoms, or
a substituted or unsubstituted monovalent heterocyclic group including 5 to 50 ring atoms;
at least one of Ar₄₀₁ to Ar₄₀₄ is a substituted or unsubstituted monovalent heterocyclic group including 5 to 50 ring atoms, and at least one of the monovalent heterocyclic group of Ar₄₀₁ to Ar₄₀₄ is a monovalent nitrogen-containing heterocyclic group;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituents R are present, the two or more of the substituents R may be the same as or different from each other;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms;
when two or more of each of R₉₀₁ to R₉₀₇ are present, the two or more of each of R₉₀₁ to R₉₀₇ may be the same as or different from each other; 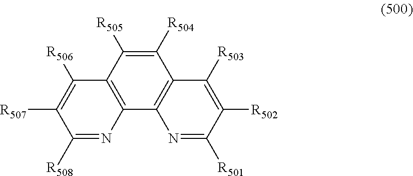
wherein in the formula (500),
one or more sets of the adjacent two or more of R₅₀₁ to R₅₀₈ form a substituted or unsubstituted, saturated or unsaturated ring by bonding with each other, or do not form the substituted or unsubstituted, saturated or unsaturated ring;
R₅₀₁ to R₅₀₈ which do not form the substituted or unsubstituted, saturated or unsaturated ring are independently
a hydrogen atom, or
a substituent R;
the substituent R is
a substituted or unsubstituted alkyl group including 1 to 50 carbon atoms,
a substituted or unsubstituted alkenyl group including 2 to 50 carbon atoms,
a substituted or unsubstituted alkynyl group including 2 to 50 carbon atoms,
a substituted or unsubstituted cycloalkyl group including 3 to 50 ring carbon atoms,
—Si(R₉₀₁)(R₉₀₂)(R₉₀₃),
—O—(R₉₀₄),
—S—(R₉₀₅),
—N(R₉₀₆)(R₉₀₇),
a halogen atom, a cyano group, a nitro group,
a substituted or unsubstituted aryl group including 6 to 50 ring carbon atoms, or
a substituted or unsubstituted monovalent heterocyclic group including 5 to 50 ring atoms;
when two or more of the substituents R are present, the two or more of the substituents R may be the same as or different from each other;
R₉₀₁ to R₉₀₇ are independently
a hydrogen atom,
a substituted or unsubstituted alkyl group including 1 to 50 carbon atoms,
a substituted or unsubstituted cycloalkyl group including 3 to 50 ring carbon atoms,
a substituted or unsubstituted aryl group including 6 to 50 ring carbon atoms, or
a substituted or unsubstituted monovalent heterocyclic group including 5 to 50 ring atoms; and
when two or more of each of R₉₀₁ to R₉₀₇ are present, the two or more of each of R₉₀₁ to R₉₀₇ may be the same as or different from each other.

21. The organic electroluminescence device according to claim 20, wherein the second compound is a compound represented by the following formula (201) and formula (202): 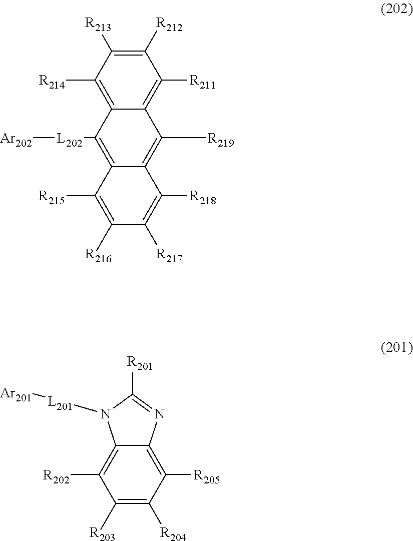
wherein in the formula (201),
R₂₀₁ to R₂₀₅ are as defined in the formula (200);
L₂₀₁ is
a single bond,
a substituted or unsubstituted arylene group including 6 to 50 ring carbon atoms, or
a substituted or unsubstituted divalent heterocyclic group including 5 to 50 ring atoms;
Ar₂₀₁ is a group represented by the formula (202);
wherein in the formula (202),
one of R₂₁₁ to R₂₁₉ is a single bond bonding with L₂₀₁;
one or more sets of adjacent two or more of R₂₁₁ to R₂₁₉ which are not single bonds bonding with L₂₀₁ form a substituted or unsubstituted, saturated or unsaturated ring by bonding with each other, or do not form the substituted or unsubstituted, saturated or unsaturated ring;
R₂₁₁ to R₂₁₉ which are not a single bond bonding with L₁ and do not form the substituted or unsubstituted, saturated or unsaturated ring are independently
a hydrogen atom, or
a substituent R;
L₂₀₂ are independently
a single bond,
a substituted or unsubstituted arylene group including 6 to 50 ring carbon atoms, or
a substituted or unsubstituted divalent heterocyclic group including 5 to 50 ring atoms;
Ar₂₀₂ are independently
a substituted or unsubstituted aryl group including 6 to 50 ring carbon atoms, or
a substituted or unsubstituted monovalent heterocyclic group including 5 to 50 ring atoms; and
the substituent R is as defined in the formula (200).

22. The organic electroluminescence device according to claim 21, wherein the second compound is a compound represented by the following formula (211): 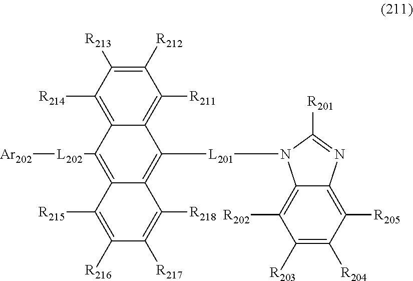
wherein in the formula (211), R₂₀₁ to R₂₀₅ are as defined in the formula (200); L₂₀₁ is as defined in the formula (201); and R₂₁₁ to R₂₁₈, L₂₀₂ and Ar₂₀₂ are as defined in the formula (202).

23. The organic electroluminescence device according to claim 20, wherein the second compound is a compound represented by the following formula (301): 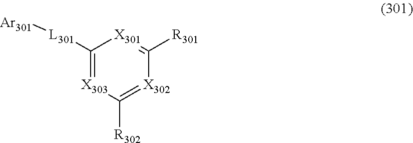
wherein in the formula (301),
X₃₀₁ to X₃₀₃, R₃₀₁ and R₃₀₂ are as defined in the formula (300);
L₃₀₁ is
a single bond,
a substituted or unsubstituted arylene group including 6 to 50 ring carbon atoms, or
a substituted or unsubstituted divalent heterocyclic group including 5 to 50 ring atoms; and
Ar₃₀₁ is
a substituted or unsubstituted aryl group including 6 to 50 ring carbon atoms, or
a substituted or unsubstituted monovalent heterocyclic group including 5 to 50 ring atoms.

24. The organic electroluminescence device according to claim 23, wherein the second compound is a compound represented by the following formula (311) and formula (312): 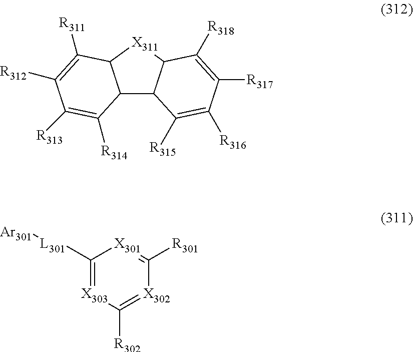
wherein in the formula (311),
X₃₀₁ to X₃₀₃, R₃₀₁ and R₃₀₂ are as defined in the formula (300);
L₃₀₁ is as defined in the formula (301); and
Ar₃₀₂ is a group represented by the formula (312);
wherein in the formula (312),
X₃₁₁ is O, S, N(R₃₂₁), or C(R₃₂₂)(R₃₂₃);
one of R₃₁₁ to R₃₁₈ and R₃₂₁ to R₃₂₃ is a single bond bonding with L₃₀₁;
one or more sets of adjacent two or more of R₃₁₁ to R₃₁₈ which are not single bonds bonding with L₃₀₁ form a substituted or unsubstituted, saturated or unsaturated ring by bonding with each other, or do not form the substituted or unsubstituted, saturated or unsaturated ring;
R₃₁₁ to R₃₁₈ which are not single bonds bonding with L₃₀₁ and which do not form the substituted or unsubstituted, saturated or unsaturated ring, and R₃₂₁ to R₃₂₃ which are not single bonds bonding with L₃₀₁ are independently
a hydrogen atom, or
a substituent R; and
the substituent R is as defined in the formula (300).

25. The organic electroluminescence device according to claim 20, wherein the second compound is a compound represented by the following formula (401): 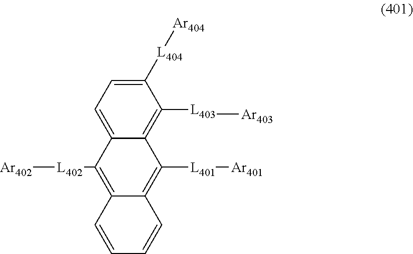
wherein in the formula (401), L₄₀₁ to L₄₀₄ and Ar₄₀₁ to Ar₄₀₄ are as defined in the formula (400).

26. The organic electroluminescence device according to claim 20, wherein the second compound is a compound represented by the following formula (402): 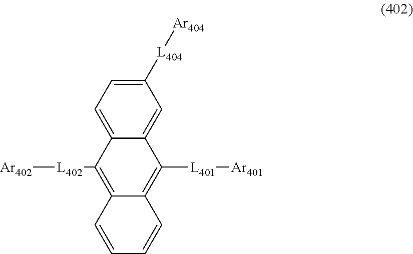
wherein in the formula (402), L₄₀₁, L₄₀₂, L₄₀₄, Ar₄₀₁, Ar₄₀₂ and Ar₄₀₄ are as defined in the formula (400).

27. The organic electroluminescence device according to claim 20, wherein the second compound is a compound represented by the following formula (501): 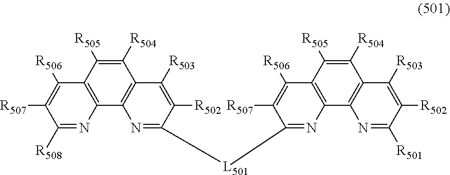
wherein in the formula (501),
R₅₀₁ to R₅₀₈ are as defined in the formula (500);
L₅₀₁ is
a single bond,
a substituted or unsubstituted arylene group including 6 to 50 ring carbon atoms, or
a substituted or unsubstituted divalent heterocyclic group including 5 to 50 ring atoms; and
each of the two R₅₀₂ to the two R₅₀₇ may be the same as or different from each other.

28. The organic electroluminescence device according to claim 27, wherein the second compound is a compound represented by the following formula (502): 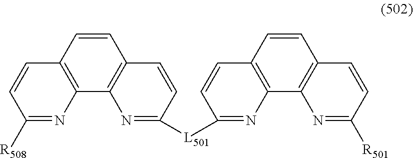
wherein in the formula (502), R₅₀₁ and R₅₀₈ are as defined in the formula (500); and L₅₀₁ is as defined in the formula (501).

29. The organic electroluminescence device according to claim 20, wherein the second compound is a compound represented by the following formula (600): 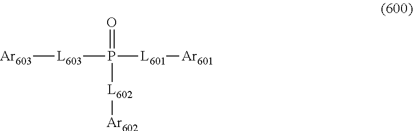
wherein in the formula (600),
L₆₀₁ to L₆₀₃ are independently
a single bond,
a substituted or unsubstituted arylene group including 6 to 50 ring carbon atoms, or
a substituted or unsubstituted divalent heterocyclic group including 5 to 50 ring atoms; and
Ar₆₀₁ to Ar₆₀₃ are independently
a substituted or unsubstituted aryl group including 6 to 50 ring carbon atoms, or
a substituted or unsubstituted monovalent heterocyclic group including 5 to 50 ring atoms.

30. The organic electroluminescence device according to claim 29, wherein the second compound is a compound represented by the following formula (601): 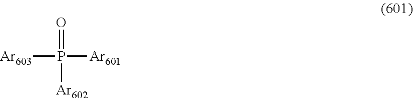
wherein in the formula (601), Ar₆₀₁ to Ar₆₀₃ are as defined in the formula (600).

31. The organic electroluminescence device according to claim 1, wherein a hole-transporting layer is provided between the anode and an emitting layer containing the host material.

32. The organic electroluminescence device according to claim 31, wherein a hole-injecting layer is provided between the anode and the hole-transporting layer.

33. An electronic apparatus, comprising the organic electroluminescence device according to claim 1.
